(19) United States
(12) Patent Application Publication
(10) Pub. No.: US 2026/0096408 A1
(43) Pub. Date: Apr. 2, 2026

(54) SEMICONDUCTOR APPARATUS AND METHOD OF MANUFACTURING SEMICONDUCTOR APPARATUS

(71) Applicant: SONY SEMICONDUCTOR SOLUTIONS CORPORATION, Kanagawa (JP)

(72) Inventors: Takushi SHIGETOSHI, Kanagawa (JP); Masaki OKAMOTO, Kanagawa (JP); Tatsumasa HIRATSUKA, Kanagawa (JP); Takaaki HIRANO, Kanagawa (JP); Katsuhisa KUGIMIYA, Kanagawa (JP); Shun MATSUMOTO, Kanagawa (JP)

(73) Assignee: SONY SEMICONDUCTOR SOLUTIONS CORPORATION, Kanagawa (JP)

(21) Appl. No.: 19/110,395

(22) PCT Filed: Aug. 10, 2023
(86) PCT No.: PCT/JP2023/029301

§ 371 Date: Mar. 10, 2025

(30) Foreign Application Priority Data
Sep. 22, 2022 (JP) 2022-150857
Dec. 2, 2022 (JP) 2022-193233
Mar. 22, 2023 (JP) 2023-045171

(51) Int. Cl. H01L 23/48; H01L 21/768; H01L 23/528; H10F 39/00

(52) U.S. Cl. CPC H10W 20/20; H10W 20/023; H10W 20/435; H10F 39/8063; H10F 39/811

(57) ABSTRACT

Provided is a semiconductor apparatus including a semiconductor substrate having a front surface on which a wiring layer is formed, a through hole that penetrates the semiconductor substrate, a through wire formed along a side surface of the through hole, and an annular trench that surrounds a circumference of the through hole when seen in a direction perpendicular to a rear surface of the semiconductor substrate which is on a side opposite to the front surface and that has formed therein a cavity when seen in a direction parallel to a rear surface.

### TECHNICAL FIELD

The present technology relates to a semiconductor apparatus. Specifically, the present technology relates to a semiconductor apparatus in which through vias are formed and a method of manufacturing the semiconductor apparatus.

### BACKGROUND ART

In recent years, research and development of three-dimensional integration technologies using through vias are underway for the purpose of attaining higher degrees of integration of various semiconductor apparatuses. In a case where such through vias are formed in a semiconductor substrate including silicon or the like, parasitic capacitance is formed between the through vias and the semiconductor substrate, and there is a possibility that the signal transfer performance deteriorates. In view of this, there have been proposed semiconductor apparatuses (e.g., refer to PTL 1) in which annular trenches are formed around the circumference of through holes in through vias and conductors in the through holes are isolated from elements surrounding the conductors.

### Citation List

### Patent Literature

PTL 1: JP 2013-251539A

### SUMMARY

### Technical Problem

The existing technology described above aims to reduce the parasitic capacitance and enhance reliability of the through vias by isolating the conductors in the through holes by the annular trenches. However, it is difficult for the semiconductor apparatus described above to further enhance reliability represented by yield or the like.

The present technology has been made in view of such a situation, and it is desirable to enhance reliability of a semiconductor apparatus in which annular trenches are formed around the circumference of through holes.

### Solution to Problem

According to a first mode of an embodiment of the present technology, there is provided a semiconductor apparatus and a manufacturing method therefore. The semiconductor apparatus includes a semiconductor substrate having a front surface on which a wiring layer is formed, a through hole that penetrates the semiconductor substrate, a through wire formed along a side surface of the through hole, and an annular trench that surrounds a circumference of the through hole when seen in a direction perpendicular to a rear surface of the semiconductor substrate which is on a side opposite to the front surface and that has formed therein a cavity when seen in a direction parallel to the rear surface. This produces the effect of enhancing reliability.

In addition, in this first mode, the semiconductor apparatus may further include a rear-surface insulating film that covers the rear surface of the semiconductor substrate which is on the side opposite to the front surface. The rear-surface insulating film may include first and second rear-surface insulating films that are stacked one on another, and the second rear-surface insulating film may cover the rear surface and a side wall of at least one of the through hole and the annular trench. This produces the effect of enhancing the insulation property and durability against mechanical stress.

In addition, in this first mode, the semiconductor apparatus may further include a first element isolation region formed around a circumference of a bottom of the through hole. This produces the effect of suppressing formation of notches or a flaring shape.

In addition, in this first mode, the second rear-surface insulating film may include a fixed electric charge film. This produces the effect of reducing the influence of defects at an interface or the front surface.

In addition, in this first mode, the through hole may include first and second through holes, the annular trench may be formed around a circumference of the first through hole, and the annular trench may not be formed around a circumference of the second through hole. This produces the effect of realizing both signal transfer performance and integration performance.

In addition, in this first mode, the through hole may include first and second through holes that are arrayed adjacent to each other in the direction parallel to the rear surface, the annular trench may include a first annular trench formed around a circumference of the first through hole and a second annular trench formed around a circumference of the second through hole, and the first annular trench may share a part thereof with the second annular trench. This produces the effect of reducing the pitches between through vias.

In addition, in this first mode, a width of the portion shared by the first and second annular trenches may be substantially the same as a width of unshared portions. This produces the effect of reducing variations of the entrance amount of the rear-surface insulating film into the annular trenches.

In addition, in this first mode, the semiconductor apparatus may further include a rear-surface insulating film that covers the rear surface of the semiconductor substrate which is on the side opposite to the front surface, and a rear-surface redistribution wire formed along the circumference of the through hole on the rear surface and the rear-surface insulating film. This produces the effect of electrically connecting through vias via the rear-surface redistribution wire.

In addition, in this first mode, an outer circumference of the rear-surface redistribution wire formed around the circumference of the through hole may be larger than an outer circumference of the annular trench. This produces the effect of enhancing wiring reliability.

In addition, in this first mode, a width of a portion of the rear-surface redistribution wire that traverses the annular trench may be wider than a width of other portions of the rear-surface redistribution wire. This produces the effect of enhancing the wiring reliability.

In addition, in this first mode, an opening whose outer circumference is larger than the through hole may be formed on the rear-surface insulating film, and the rear-surface redistribution wire around the circumference of the through hole may cover the rear surface positioned on an inner side of the opening. This produces the effect of reducing stress and enhancing the yield.

In addition, in this first mode, the semiconductor apparatus may further include an on-chip lens, a photoelectric converting section, and an external terminal. This produces the effect of causing the semiconductor apparatus to function as a solid-state imaging apparatus.

In addition, in this first mode, the semiconductor apparatus may further include a rear-surface insulating film that covers the rear surface of the semiconductor substrate which is on the side opposite to the front surface. An end of the rear-surface insulating film may have a tapered shape. This produces the effect of enhancing reliability.

In addition, in this first mode, a diameter of the through hole may be 1.5 to 4.0 times a width of the annular trench. This produces the effect of reducing manufacturing costs.

In addition, in this first mode, the diameter of the through hole may be 2.0 to 3.0 times the width of the annular trench. This produces the effect of reducing manufacturing costs.

In addition, in this first mode, the semiconductor apparatus may further include a solder mask that covers the insulating film and the through hole. A cavity closed by the solder mask may be formed inside the through hole when seen in the direction parallel to the rear surface. This produces the effect of enhancing reliability.

In addition, in this first mode, the semiconductor apparatus may further include a low-k material that is formed between the through hole and the annular trench and has a dielectric constant lower than a dielectric constant of the semiconductor substrate. This produces the effect of making it easier to attain a high degree of integration.

In addition, in this first mode, the semiconductor apparatus may further include a rear-surface insulating film that covers the annular trench and the rear surface of the semiconductor substrate which is on the side opposite to the front surface. The solder mask may further cover the rear-surface insulating film. This produces the effect of making it easier to attain a high degree of integration.

In addition, in this first mode, the low-k material may cover the rear surface of the semiconductor substrate which is on the side opposite to the front surface, and the solder mask may further cover the low-k material and the annular trench. This produces the effect of making the rear-surface insulating film unnecessary.

In addition, in this first mode, the semiconductor apparatus may further include an element isolation region formed between the wiring layer and the annular trench. This produces the effect of enhancing the degree of freedom of layout of the wiring layer and enhancing the degree of integration of semiconductor elements.

In addition, in this first mode, the wiring layer may include a dummy gate formed between the through hole and the annular trench. This produces the effect of making a keep-out zone of a gate electrode smaller.

In addition, in this first mode, the semiconductor apparatus may further include a rear-surface insulating film that covers the rear surface of the semiconductor substrate which is on the side opposite to the front surface, and an insulating reinforcement film that is adjacent to the wiring layer and covers the circumference of the through hole. This produces the effect of suppressing peeling of the semiconductor substrate.

In addition, in this first mode, the through hole may have a step at a predetermined depth position when seen in the direction parallel to the rear surface, the rear-surface insulating film may cover the circumference of the through hole in an area from the rear surface to the depth position, the reinforcement film may cover the circumference of the through hole in an area from the depth position to the wiring layer, and the reinforcement film may be formed between a base material of the semiconductor substrate and the through hole when seen in the perpendicular direction. This produces the effect of suppressing peeling of the semiconductor substrate.

In addition, in this first mode, a cross-sectional shape of each of the through hole and the reinforcement film seen in the parallel direction may have a curved tapered shape. This produces the effect of making it easier to adjust the cross-sectional shape at a time of etch-back.

In addition, in this first mode, the through hole may have a step at a predetermined depth position when seen in the direction parallel to the rear surface, the reinforcement film may cover the circumference of the through hole in an area from the depth position to the wiring layer, and the rear-surface insulating film may cover the circumference of the through hole and a circumference of the reinforcement film. This produces the effect of suppressing peeling of the semiconductor substrate.

In addition, in this first mode, a shape of the through hole may be a circular or polygonal shape when seen in the perpendicular direction. This produces the effect of suppressing peeling of the semiconductor substrate.

In addition, in this first mode, the through hole may cover an entire circumference of the through hole when seen in the perpendicular direction. This produces the effect of suppressing peeling of the semiconductor substrate.

In addition, in this first mode, the reinforcement film may cover a part of the circumference of the through hole when seen in the perpendicular direction. This produces the effect of reducing the parasitic capacitance.

In addition, in this first mode, a base material of the semiconductor substrate may have a step at a predetermined depth position when seen in the direction parallel to the rear surface, the rear-surface insulating film may cover the circumference of the through hole in an area from the rear surface to the depth position, and the reinforcement film may cover the circumference of the through hole in an area from the depth position to the wiring layer. This produces the effect of making it unnecessary to provide a step to the through hole.

In addition, in this first mode, the semiconductor apparatus may further include a first protective member arranged adjacent to the wiring layer in the annular trench. This produces the effect of suppressing peeling of the semiconductor substrate.

In addition, in this first mode, the first protective member may be an insulating resin or an inorganic film. This produces the effect of suppressing peeling of the semiconductor substrate.

In addition, in this first mode, a shape of the first protective member may be recessed toward the wiring layer when seen in the direction parallel to the rear surface. This produces the effect of attaining an advantage in high-speed transfer.

In addition, in this first mode, the first protective member may cover both an inner-circumference-side corner and an outer-circumference-side corner of the annular trench. This produces the effect of suppressing peeling of the semiconductor substrate.

In addition, in this first mode, the first protective member may cover only an inner-circumference-side corner of the annular trench. This produces the effect of attaining an advantage in high-speed transfer.

In addition, in this first mode, the semiconductor apparatus may further include a second protective member arranged adjacent to the wiring layer in the through hole. This produces the effect of suppressing peeling of the semiconductor substrate.

In addition, in this first mode, the semiconductor apparatus may further include a rear-surface insulating film that covers the rear surface of the semiconductor substrate which is on the side opposite to the front surface. A width of the annular trench on a side of the wiring layer may be narrower than a width of the annular trench on a side of the rear-surface insulating film. This produces the effect of making the protective members unnecessary.

In addition, in this first mode, a cross-sectional shape of the annular trench when seen in the direction parallel to the rear surface may have a tapered shape. This produces the effect of making the protective members unnecessary.

In addition, in this first mode, a corner of the annular trench when seen in the direction parallel to the rear surface may be rounded. This produces the effect of making the protective members unnecessary.

In addition, in this first mode, the corner may be positioned in the wiring layer. This produces the effect of suppressing peeling of the semiconductor substrate.

In addition, in this first mode, the corner may straddle a boundary between the semiconductor substrate and the wiring layer. This produces the effect of suppressing peeling of the semiconductor substrate.

In addition, in this first mode, of an inner-circumference-side corner and an outer-circumference-side corner of the annular trench, only the inner-circumference-side corner may be rounded. This produces the effect of suppressing peeling of the semiconductor substrate.

In addition, in this first mode, the semiconductor apparatus may further include an insulating film formed between the annular trench and the through hole, and an annular depletion layer formed in the insulating film. This produces the effect of enhancing device reliability.

In addition, in this first mode, the insulating film may have a predetermined number of openings formed at an end of the depletion layer. This produces the effect of removing ring-shaped silicon.

In addition, in this first mode, holes as the openings may be formed at the end. This produces the effect of removing ring-shaped silicon.

In addition, in this first mode, slits as the openings may be formed at the end. This produces the effect of removing ring-shaped silicon.

### Advantageous Effects of Invention

It is possible to enhance reliability of a semiconductor apparatus in which annular trenches are formed around the circumference of through holes.

### BRIEF DESCRIPTION OF DRAWINGS

FIG. 1 is a cross-sectional view depicting a configuration example of a semiconductor apparatus in a first embodiment of the present technology.

FIG. 2 is an example of a cross-sectional view and a top view of the semiconductor apparatus in the first embodiment of the present technology.

FIG. 3 is a view for explaining a manufacturing method until completion of etching in the first embodiment of the present technology.

FIG. 4 is a view for explaining the manufacturing method until formation of a solder mask in the first embodiment of the present technology.

FIG. 5 is a flowchart depicting a method of manufacturing the semiconductor apparatus in the first embodiment of the present technology.

FIG. 6 is an example of a cross-sectional view of the semiconductor apparatus in which a tapered shape is formed at an end of a rear-surface insulating film in the first embodiment of the present technology.

FIG. 7 is an example of a cross-sectional view of the semiconductor apparatus in the first embodiment of the present technology in which an annular trench is filled with the rear-surface insulating film.

FIG. 8 is a cross-sectional view depicting a configuration example of the semiconductor apparatus in a second embodiment of the present technology.

FIG. 9 is a cross-sectional view depicting a configuration example of the semiconductor apparatus in a third embodiment of the present technology.

FIG. 10 is a view for explaining a manufacturing method in the third embodiment of the present technology.

FIG. 11 is an example of a cross-sectional view of the semiconductor apparatus 100 in a fourth embodiment of the present technology.

FIG. 12 is a cross-sectional view depicting a configuration example of the semiconductor apparatus in a fifth embodiment of the present technology.

FIG. 13 is an example of a top view of the semiconductor apparatus in the fifth embodiment of the present technology.

FIG. 14 is an example of a top view of the semiconductor apparatus in a sixth embodiment of the present technology.

FIG. 15 is a cross-sectional view depicting a configuration example of the semiconductor apparatus in a seventh embodiment of the present technology.

FIG. 16 is an example of a top view of the semiconductor apparatus in the seventh embodiment of the present technology.

FIG. 17 is a cross-sectional view depicting a configuration example of the semiconductor apparatus in an eighth embodiment of the present technology.

FIG. 18 is a cross-sectional view depicting a configuration example of the semiconductor apparatus in a ninth embodiment of the present technology.

FIG. 19 depicts cross-sectional views of the semiconductor apparatus in the ninth embodiment of the present technology seen in another direction.

FIG. 20 is a view for explaining a manufacturing method until formation of an opening in a semiconductor substrate in the ninth embodiment of the present technology.

FIG. 21 is a view for explaining the manufacturing method until etch-back in the ninth embodiment of the present technology.

FIG. 22 is a view for explaining the manufacturing method until formation of an opening in the rear-surface insulating film in the ninth embodiment of the present technology.

FIG. 23 is a view for explaining the manufacturing method until formation of the solder mask in the ninth embodiment of the present technology.

FIG. 24 is a view for explaining the manufacturing method until formation of the trench in the ninth embodiment of the present technology.

FIG. 25 is a view for explaining the manufacturing method until formation of a wiring layer in the ninth embodiment of the present technology.

FIG. 26 is a view for explaining the manufacturing method until formation of the rear-surface insulating film in the ninth embodiment of the present technology.

FIG. 27 is a view for explaining the manufacturing method until formation of a redistribution wire in the ninth embodiment of the present technology.

FIG. 28 is a cross-sectional view of the semiconductor apparatus in the ninth embodiment of the present technology in a case where the annular trench is arranged.

FIG. 29 is a cross-sectional view depicting a configuration example of the semiconductor apparatus in a first modification example of the ninth embodiment of the present technology.

FIG. 30 is a cross-sectional view depicting a configuration example of the semiconductor apparatus in a second modification example of the ninth embodiment of the present technology.

FIG. 31 is a cross-sectional view depicting a configuration example of the semiconductor apparatus in a third modification example of the ninth embodiment of the present technology.

FIG. 32 is a view for explaining a manufacturing method until formation of an opening in the semiconductor substrate in the third modification example of the ninth embodiment of the present technology.

FIG. 33 is a view for explaining the manufacturing method until formation of a reinforcement film in the third modification example of the ninth embodiment of the present technology.

FIG. 34 is a view for explaining the manufacturing method until formation of an opening in the rear-surface insulating film in the third modification example of the ninth embodiment of the present technology.

FIG. 35 is a view for explaining the manufacturing method until formation of the solder mask in the third modification example of the ninth embodiment of the present technology.

FIG. 36 depicts cross-sectional views, each depicting a configuration example of the semiconductor apparatus in a fourth modification example of the ninth embodiment of the present technology.

FIG. 37 depicts cross-sectional views, each depicting a configuration example of the semiconductor apparatus in a fifth modification example of the ninth embodiment of the present technology.

FIG. 38 is a cross-sectional view depicting a configuration example of the semiconductor apparatus in a tenth embodiment of the present technology.

FIG. 39 is a view for explaining advantages of the semiconductor apparatus in the tenth embodiment of the present technology.

FIG. 40 is a view for explaining a manufacturing method until completion of etching in the tenth embodiment of the present technology.

FIG. 41 is a view for explaining the manufacturing method until formation of resin in the tenth embodiment of the present technology.

FIG. 42 is a view for explaining the manufacturing method until formation of the redistribution wire in the tenth embodiment of the present technology.

FIG. 43 depicts cross-sectional views, each depicting an arrangement example of the resin in the tenth embodiment of the present technology.

FIG. 44 depicts examples of cross-sectional views of the semiconductor apparatus in the tenth embodiment of the present technology in which an inorganic film is arranged.

FIG. 45 is a cross-sectional view depicting a configuration example of the semiconductor apparatus in a first modification example of the tenth embodiment of the present technology.

FIG. 46 depicts examples of enlarged views of the semiconductor apparatus in the first modification example of the tenth embodiment of the present technology.

FIG. 47 is a cross-sectional view depicting a configuration example of the semiconductor apparatus in a second modification example of the tenth embodiment of the present technology.

FIG. 48 depicts examples of enlarged views of the semiconductor apparatus in the second modification example of the tenth embodiment of the present technology.

FIG. 49 depicts examples of enlarged views of a semiconductor apparatus in a comparative example.

FIG. 50 depicts other examples of the enlarged views of the semiconductor apparatus in the second modification example of the tenth embodiment of the present technology.

FIG. 51 is a cross-sectional view depicting a configuration example of the semiconductor apparatus in an eleventh embodiment of the present technology.

FIG. 52 depicts examples of cross-sectional views of the semiconductor apparatus in the eleventh embodiment of the present technology seen in another direction.

FIG. 53 is a view for explaining a manufacturing method until formation of an opening in the semiconductor substrate in the eleventh embodiment of the present technology.

FIG. 54 is a view for explaining the manufacturing method until formation of an opening in an insulating film in the eleventh embodiment of the present technology.

FIG. 55 is a view for explaining the manufacturing method until application and exposure of a coating of the rear-surface insulating film in the eleventh embodiment of the present technology.

FIG. 56 is a view for explaining the manufacturing method until formation of the redistribution wire in the eleventh embodiment of the present technology.

FIG. 57 is an example of a cross-sectional view of the semiconductor apparatus in a first modification example of the eleventh embodiment of the present technology.

FIG. 58 is an example of a cross-sectional view of the semiconductor apparatus in a second modification example of the eleventh embodiment of the present technology.

FIG. 59 is a view depicting an example of the second embodiment of the present technology in which an ideal through hole is formed.

FIG. 60 is a view depicting an example of the second embodiment of the present technology in which notches occur.

FIG. 61 is a view depicting an example of the second embodiment of the present technology in which a flaring shape of silicon is formed.

FIG. 62 depicts examples of cross-sectional views of the semiconductor apparatus in a twelfth embodiment of the present technology in which a through hole has not yet been formed.

FIG. 63 is a view for explaining a method of manufacturing the semiconductor apparatus until etch-back in the twelfth embodiment of the present technology.

FIG. 64 depicts enlarged views of a portion near an element isolation region in the twelfth embodiment of the present technology.

FIG. 65 is an example of a cross-sectional view of the semiconductor apparatus in a first modification example of the twelfth embodiment of the present technology.

FIG. 66 is an example of a cross-sectional view of the semiconductor apparatus in a second modification example of the twelfth embodiment of the present technology.

FIG. 67 is a cross-sectional view depicting a configuration example of the semiconductor apparatus in a thirteenth embodiment of the present technology.

FIG. 68 is a view for explaining a manufacturing method until exposure in the thirteenth embodiment of the present technology.

FIG. 69 is a view for explaining the manufacturing method until ion implantation in the thirteenth embodiment of the present technology.

FIG. 70 is a view for explaining the manufacturing method until formation of the solder mask in the thirteenth embodiment of the present technology.

FIG. 71 is a cross-sectional view depicting a configuration example of the semiconductor apparatus in a modification example of the thirteenth embodiment of the present technology.

FIG. 72 is a view for explaining a manufacturing method until a coating of a low-k material is applied in the modification example of the thirteenth embodiment of the present technology.

FIG. 73 is a view for explaining the manufacturing method until formation of an opening for a pad in the modification example of the thirteenth embodiment of the present technology.

FIG. 74 is a view for explaining the manufacturing method until formation of the solder mask in the modification example of the thirteenth embodiment of the present technology.

FIG. 75 is a block diagram depicting an example of schematic configuration of a vehicle control system.

FIG. 76 is a diagram of assistance in explaining an example of installation positions of an outside-vehicle information detecting section and an imaging section.

### DESCRIPTION OF EMBODIMENTS Hereinbelow, modes for carrying out the present technology (hereinafter, referred to as embodiments) are explained. The explanation will be given in the following order.

1. First Embodiment (Example in Which Cavity Is Provided in Annular Trench)
2. Second Embodiment (Example in Which Cavity Is Provided in Annular Trench and Rear-Surface Insulating Film Includes Two Layers)
3. Third Embodiment (Example in Which Through Via Provided with Cavity in Annular Trench and Through Vias without Annular Trenches Are Arranged)
4. Fourth Embodiment (Example in Which Cavities Are Provided in Annular Trenches and Adjacent Through Vias Share Parts of Cavities)
5. Fifth Embodiment (Example in Which Cavity Is Provided in Annular Trench and Annular Trench Is Covered with Rear-Surface Redistribution Wire)
6. Sixth Embodiment (Example in Which Cavity Is Provided in Annular Trench and Part of Rear-Surface Redistribution Wire Is Made Thicker)
7. Seventh Embodiment (Example in Which Cavity Is Provided in Annular Trench and Inner Side Of Rear-Surface Insulating Film Is Covered with Rear-Surface Redistribution Wire)
8. Eighth Embodiment (Example in Which Structure in Which Cavities Are Provided in Annular Trenches Is Applied to Solid-State Imaging Apparatus)
9. Ninth Embodiment (Example in Which Cavity Is Provided in Annular Trench and Through Hole Is Covered with Reinforcement Film)
10. Tenth Embodiment (Example in Which Cavity Is Provided in Annular Trench and Resin Is Arranged in Annular Trench)
11. Eleventh Embodiment (Example in Which Cavity Is Provided in Annular Trench and Depletion Layer Is Formed in Insulating Film)
12. Twelfth Embodiment (Example in Which Cavity Is Provided in Annular Trench and Ring-Shaped Element Isolation Region Is Arranged)
13. Thirteenth Embodiment (Example in Which Cavity Is Provided in Annular Trench and Ring-Shaped low-k Material Is Arranged)
14. Example of Application to Mobile Body

### 1. First Embodiment

### Configuration Example of Semiconductor Apparatus

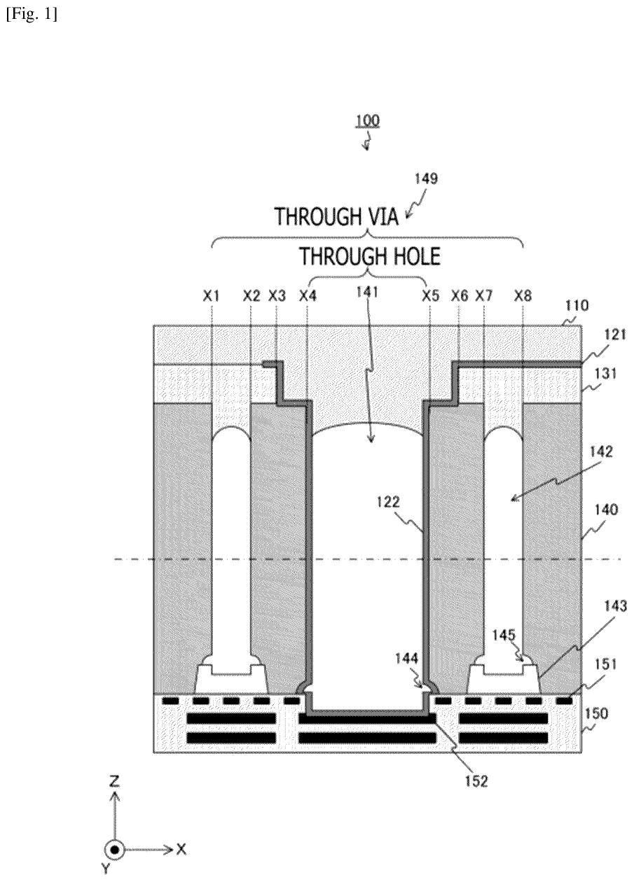

FIG. 1 is a cross-sectional view depicting a configuration example of a semiconductor apparatus 100 in an embodiment according to the present technology. This cross-sectional view is an enlarged view of a portion near a through via 149 in the semiconductor apparatus 100. The semiconductor apparatus 100 includes a semiconductor substrate 140. A semiconductor element (not depicted) and a wiring layer 150 are formed on one of two surfaces of the semiconductor substrate 140. Hereinbelow, the surface of the two surfaces of the semiconductor substrate 140 on which the wiring layer 150 is formed is defined as a “front surface,” and the other surface is defined as a “rear surface.” A direction from the front surface to the rear surface is defined as an “upward” direction. In addition, the semiconductor apparatus 100 functions as a signal processing circuit, a memory, an image sensor, or the like, and can be of any type.

Hereinbelow, an axis perpendicular to a substrate plane (the front surface or the rear surface) of the semiconductor substrate 140 is defined as a “Z axis,” and a predetermined axis parallel to the plane is defined as an “X axis.” An axis perpendicular to the X axis and the Z axis is defined as a “Y axis.” FIG. 1 is a cross-sectional view seen in a Y-axis direction.

In addition, the through via 149 is formed through the semiconductor substrate 140. The through via 149 includes a through hole 141 that penetrates the semiconductor substrate 140, a through wire 122 formed along a side surface of the through hole 141, and an annular trench 142 surrounding the circumference of the through hole when seen in a Z-axis direction. An area from a coordinate X1 to a coordinate X8 in an X-axis direction corresponds to the outer diameter of the annular trench 142, that is, the diameter of the through via 149. In addition, an area from the coordinate X2 to the coordinate X7 corresponds to the internal diameter of the annular trench 142. An area from the coordinate X4 to the coordinate X5 corresponds to the diameter of the through hole 141.

In addition, the through wire 122 is connected to a pad 152 formed in the wiring layer 150 on the front-surface side and a rear-surface redistribution wire 121 placed on the rear surface. As the material of the through wire 122, Cu (copper), Ti (titanium), Ta (tantalum), Al (aluminum), W (tungsten), Ni (nickel), Ru (ruthenium), Co (cobalt), TiN (titanium nitride), TaN (tantalum nitride), WN (tungsten nitride), or the like is used. Note that the through wire 122 may have a structure in which a plurality of materials are stacked one on another.

In terms of reliability and ease of manufacturing, the annular trench 142 preferably has a depth/width aspect ratio of approximately 3 to 20 when seen in the X-axis direction or the Y-axis direction. In addition, the diameter of the through hole 141 is preferably 1.5 to 4.0 times the width of the annular trench 142, and optimally 2.0 to 3.0 times the width of the annular trench 142. With this, it becomes possible to process the through hole 141 and the annular trench 142 at approximately the same speeds when dry etching is performed, and accordingly it becomes possible to form them in the same step.

In addition, the annular trench 142 and the through hole 141 may not have identical sizes in the semiconductor apparatus 100. The width of the annular trench 142 can be increased in a signal wire whose parasitic capacitance is desired to be minimized. On the other hand, the width of the annular trench 142 can be reduced at a portion where it is desirable to increase the degree of integration of the through via 149. Hence, the performance and degree of integration of the through via 149 can be pursued at the same time.

In addition, when ends on the front-surface side of the through hole 141 and the annular trench 142 are defined as bottoms, a notch 144 is formed at the bottom of the through hole 141, and a notch 145 is formed at the bottom of the annular trench 142.

The processing shapes, for example, the processing angles or the sizes of notching of the bottoms, may be different between the through hole 141 and the annular trench 142. In a case where the degree of forward tapering of the through hole 141 is higher or the degree of notching of the through hole 141 is lower, this is advantageous in terms of formation of the through wire 122. On the other hand, when the degree of forward tapering of the annular trench 142 is higher or the degree of notching of the annular trench 142 is lower, this is advantageous in terms of mechanical stress applied to the annular trench 142. In addition, the processing angles may change at middle portions of the annular trench 142 and the through hole 141.

A rear-surface insulating film 131 is formed in such a manner as to cover the entire rear surface of the semiconductor substrate 140 and a part of the through via 149. A cavity closed by the rear-surface insulating film 131 is formed inside the annular trench 142 when seen in the Y-axis direction.

As the rear-surface insulating film 131, a photosensitive insulating film including an organic material having a framework including polyimide, acryl, silicone, and an epoxy group can be formed by lithography. Thus, a manufacturing process can be simplified as explained later. The rear-surface insulating film 131 may include a single material or may include a plurality of materials that are stacked one on another as described later. In addition, the rear-surface insulating film 131 may have a stacked structure including an inorganic film. The area size of a portion of the through via 149 covered with the rear-surface insulating film 131 when seen in the Z-axis direction preferably is approximately 20 to 80 percent (%), and desirably 30 to 65 percent (%), of the through via 149.

In order to adjust the area size of the portion of the through via 149 covered with the rear-surface insulating film 131, an opening slightly larger than the diameter of the through hole 141 when seen in the Z-axis direction is formed in the rear-surface insulating film 131 at a portion corresponding to the through hole 141. Due to this structure, a step occurs on the rear-surface insulating film 131 when seen in the Y-axis direction. In FIG. 1, a step is present at the coordinate X3 and the coordinate X6.

In addition, a part of the rear-surface insulating film 131 may enter the inside of the annular trench 142. In addition, the entering part of the rear-surface insulating film 131 may have a dome-like shape when seen in the X-axis direction or the Y-axis direction. As an example, the entrance depth of approximately 5 to 40 percent (%) of the trench is suitable in terms of yield, reliability, and parasitic capacitance.

The rear-surface redistribution wire 121 is formed along the circumference of the through hole 141 and a side surface and an upper surface of the rear-surface insulating film 131. Since the rear-surface insulating film 131 has the step, a step occurs also on the rear-surface redistribution wire 121. The through wire 122 and the rear-surface redistribution wire 121 may be formed by the same process. Since there will not be a junction surface between the through wire 122 and the rear-surface redistribution wire 121 in a case where they are formed by the same process, this is advantageous in terms of resistance or reliability. As the material of the rear-surface redistribution wire 121, Cu (copper), Ti (titanium), Ta (tantalum), Al (aluminum), W (tungsten), Ni (nickel), Ru (ruthenium), Co (cobalt), TiN (titanium nitride), TaN (tantalum nitride), WN (tungsten nitride), or the like is used. Note that the rear-surface redistribution wire 121 may have a structure in which a plurality of materials are stacked one on another.

In addition, a solder mask 110 is formed as a protective film on the upper surfaces of the rear-surface redistribution wire 121 and the rear-surface insulating film 131. A part of the solder mask 110 penetrates into the through hole 141, and a cavity closed by the solder mask 110 is formed inside the through hole 141. As illustrated in FIG. 1, it is preferable that, in terms of yield and reliability, the part of the through hole 141 have an entrance depth which is suitably 5 to 40 percent (%), approximately.

In addition, on the front-surface side of the semiconductor substrate 140, an element isolation region 143 (STI: Shallow Trench Isolation) is formed between the annular trench 142 and the wiring layer 150, as necessary. Note that the element isolation region 143 is an example of a second element isolation region described in the claims. Whereas the STI is arranged only in an area immediately below the annular trench 142 in FIG. 1, this configuration is not the sole example. For example, STI may further be arranged between the annular trench 142 and the through hole 141 (an area from the coordinate X2 to the coordinate X4 and from the coordinate X5 to the coordinate X7). Thus, the through hole 141 can be formed by self-alignment. STI can also be formed between the annular trench 142 and the through hole 141. In addition, in the wiring layer 150, a dummy gate 151 is formed near the annular trench 142 as necessary. For example, the dummy gate 151 is formed at a portion below the annular trench 142 and between the through hole 141 and the annular trench 142. When the STI is arranged at the bottom of the annular trench 142, it serves as an etching stopper. Accordingly, the degree of freedom of layout of the wiring layer 150 is enhanced, and the degree of integration of the semiconductor element is enhanced.

In addition, the pad 152 in the wiring layer 150 may be formed only on the inner side of the annular trench 142. Hence, the parasitic capacitance between the pad 152 and the semiconductor substrate 140 can be reduced.

In addition, by arranging the dummy gate 151 between the through hole 141 and the annular trench 142, it becomes possible to make a keep-out zone of a gate electrode smaller. As a result, the degree of flatness at a time of formation of the wiring layer 150 on the front surface is improved, and particularly in the entire process, it becomes possible to arrange micro wires near the through via 149. The dummy gate 151 may include polycrystalline silicon or amorphous silicon or may include another material.

In summary, the through hole 141 penetrates the semiconductor substrate 140 having the front surface on which the wiring layer 150 is formed, and the through wire 122 is formed along the side surface of the through hole 141. The annular trench 142 is formed in such a manner as to surround the circumference of the through hole 141 when seen in the Z-axis direction, which is perpendicular to the rear surface. The rear-surface insulating film 131 covers the rear surface of the semiconductor substrate 140, and the cavity closed by the rear-surface insulating film 131 when seen in the X-axis direction or the Y-axis direction, which are parallel to the rear surface, is formed inside the annular trench 142.

Supposed here is a structure as a comparative example which does not have cavities and in which the through hole 141 and the annular trench 142 are filled with the solder mask 110 and the rear-surface insulating film 131. In the comparative example, the parasitic capacitance increases, and, since the solder mask 110 and the rear-surface insulating film 131 flow into the through hole 141 and the annular trench 142, there is a possibility that the flatness of the upper surfaces deteriorates. In addition, the rear-surface insulating film 131 temporarily enters the through hole 141 during manufacturing, and it is necessary to remove the rear-surface insulating film 131 by lithography. However, it is difficult to remove it completely. Due to these factors, there is a possibility that the yield lowers. In addition, the KOZ (Keep Out Zone), which is a region excluded from designing, around a through via for ensuring device characteristics becomes larger, and there is a possibility of an increase of stress or manufacturing costs.

In contrast to this, since the cavities are left inside the through hole 141 and the annular trench 142 in FIG. 1, it is possible to increase the yield and enhance the reliability as compared to the comparative example. Further, it is possible to make the KOZ smaller and reduce stress or manufacturing costs.

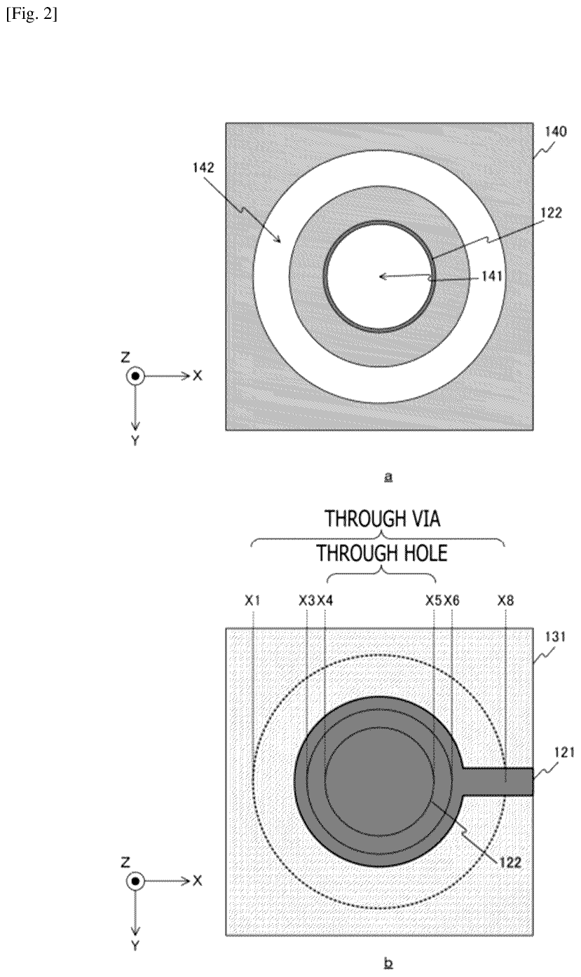

FIG. 2 is an example of a cross-sectional view and a top view of the semiconductor apparatus 100 in the first embodiment of the present technology. “a” in FIG. 2 depicts a cross-sectional view when seen in the Z-axis direction, taken along a dash-dotted line through the semiconductor apparatus 100 in FIG. 1. “b” in FIG. 2 depicts a top view of the semiconductor apparatus 100 in a state in which the semiconductor apparatus 100 has not yet been covered with the solder mask 110.

As illustrated in “a” in FIG. 2, the cross-sectional shape of the through hole 141 is circular, and the annular trench 142 around the circumference of the through hole 141 is ring-shaped.

A circular dotted line in “b” in FIG. 2 represents the outer circumference of the through via 149, that is, the outer circumference of the annular trench 142. As illustrated in “b” in FIG. 2, the rear-surface insulating film 131 covers the circumference of a circular opening having an outer diameter which is larger than that of the through hole 141. In addition, the through wire 122 is formed in the through hole 141, and the rear-surface redistribution wire 121 is formed along the circumference of the through hole 141 and the upper surface of the rear-surface insulating film 131. In addition, the rear-surface redistribution wire 121 on the upper surface of the rear-surface insulating film 131 is formed along a linear path.

The inside of a circle whose diameter corresponds to the area from the coordinate X4 to the coordinate X5 represents the region of the through wire 122, and a circle whose diameter corresponds to an area from the coordinate X3 to the coordinate X6 represents the step of the rear-surface redistribution wire 121, the step occurring due to the step of the rear-surface insulating film 131.

### Method of Manufacturing Semiconductor Apparatus

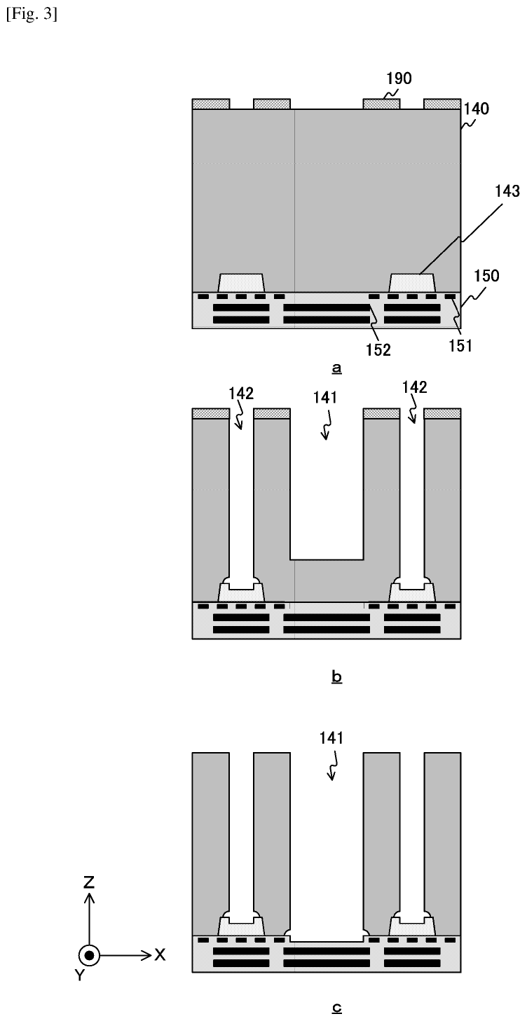

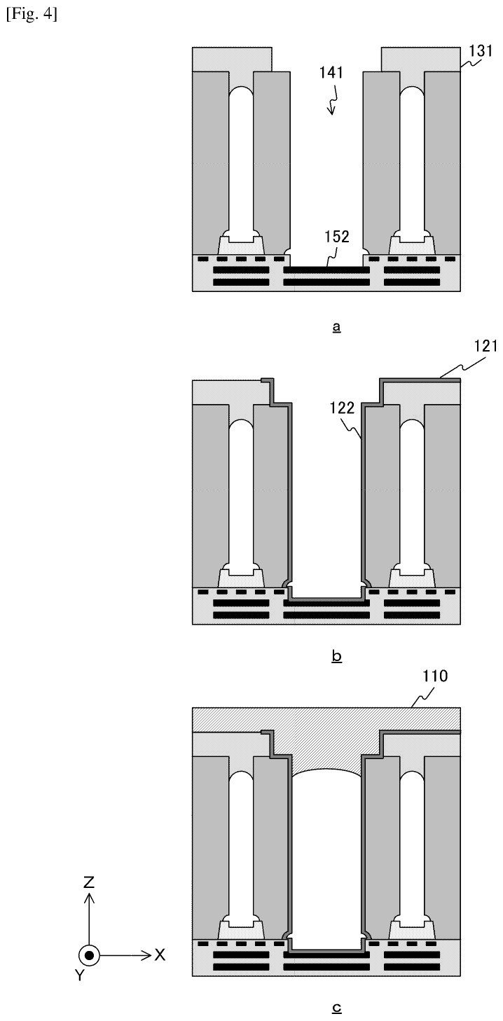

A manufacturing method for the semiconductor apparatus 100 in the first embodiment of the present technology is depicted in FIG. 3 and FIG. 4.

First, as illustrated in “a” in FIG. 3, on the front-surface side of the semiconductor substrate 140, the pad 152 is formed at a position corresponding to the through wire 122 to be formed later, and the element isolation region 143 is formed at a position corresponding to the annular trench 142. In addition, the dummy gate 151 is formed at the position corresponding to the annular trench 142. Further, by lithography, a resist mask 190 is formed on the semiconductor substrate 140 except for positions where processing is performed to reduce the film thickness from the rear surface side and form the through hole 141 and the annular trench 142.

Next, as illustrated in “b” in FIG. 3, the through hole 141 and the annular trench 142 are formed by dry etching. “b” in FIG. 3 depicts a state in the middle of the processing, and, in the depicted example, the processing speed, which is the etching rate, on the trench side is faster than that of the through hole 141. The etching rates of the through hole 141 and the annular trench 142 depend on the aspect ratios and processing conditions.

Next, as illustrated in “c” in FIG. 3, the dry etching continues until the through hole 141 penetrates the semiconductor substrate 140. Thereafter, the resist mask 190 is removed by ashing or the like. When the through hole 141 has penetrated the semiconductor substrate 140, the endpoint of the etching can be detected on the basis of a change of the plasma light-emission state or the like. For example, the endpoint can be detected at a timing when the through hole 141 has penetrated, and the plasma etching conditions can be changed to conditions with which notching is more unlikely to occur or to conditions with which processing is performed to attain a higher degree of forward tapering. Specific examples of the manufacturing method that lowers the degree of notching include increasing a side-wall protecting component, reducing the processing amount per cycle in a case where processing is performed by a Bosch process, and so on. Since this enables stabler and more precise control of the processing shape of the bottom of the through hole 141, formation of the through wire 122 in a later step becomes easier. In addition, it is also possible to optimize the shape of each of the annular trench 142 and the through hole 141.

Next, as illustrated in “a” in FIG. 4, a film of a photosensitive insulating resin is formed as the rear-surface insulating film 131 over the entire surface, the photosensitive resin at a part, on the side of the through hole 141, of the through via 149 and at the through hole 141 is thereafter removed by lithography, and annealing is performed to form permanent resin. Further, the entire surface is etched back, and the through hole 141 is connected to the pad 152 on the front-surface side. Lamination or coating can be used as a method to form the rear-surface insulating film 131. For example, when coating is used, the depth of entrance into the annular trench 142 can be controlled by optimizing the viscosity of the resin.

Next, as illustrated in “b” in FIG. 4, the rear-surface redistribution wire 121 and the through wire 122 are formed simultaneously by a semi-additive method. As an example of the semi-additive method to be used, a barrier metal film and a seed metal film are formed, a resist mask is thereafter formed by lithography, and the wires are formed by electroplating at portions where the resist mask is not arranged. Thereafter, the resist mask is removed, and the rear-surface redistribution wire 121 is formed by removing the barrier metal film and the seed metal film by etch-back over the entire surface.

Next, as illustrated in “c” in FIG. 4, the solder mask 110 is formed. Although not depicted, a part of the solder mask 110 may be removed such that the rear-surface redistribution wire 121 is exposed, and an external connection terminal may be connected to the rear-surface redistribution wire 121.

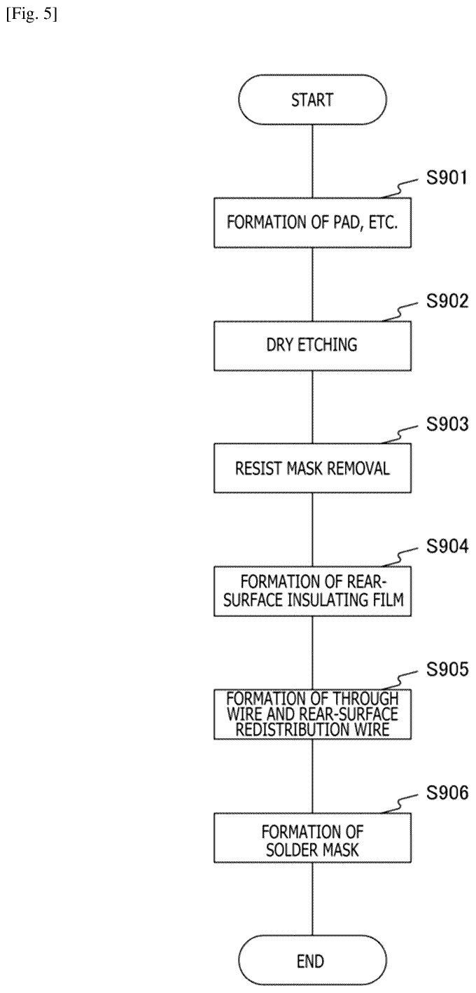

FIG. 5 is a flowchart depicting a manufacturing method for the semiconductor apparatus 100 in the first embodiment of the present technology. A manufacturing system for the semiconductor apparatus 100 forms the pad 152 and the like (Step S901), and forms the annular trench 142 along with the through hole 141 by dry etching (Step S902). At the end of the dry etching, the manufacturing system removes the resist mask (Step S903), and forms the rear-surface insulating film 131 (Step S904). Then, the manufacturing system forms the rear-surface redistribution wire 121 along with the through wire 122 (Step S905), and forms the solder mask 110 (Step S906). After Step S906, the manufacturing system performs other necessary steps, and ends the manufacturing steps.

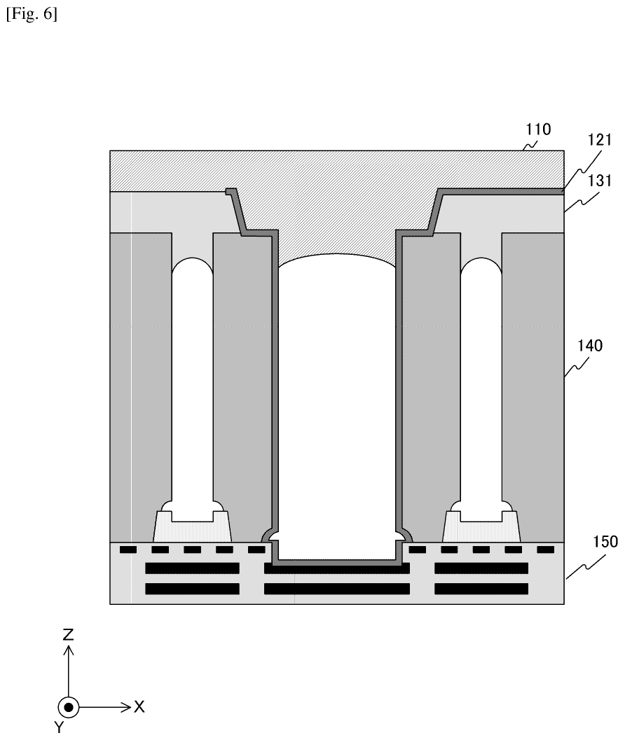

Note that, as illustrated in FIG. 6, an end of the rear-surface insulating film 131 may have a forward tapered shape. At this time, in terms of yield and reliability, it is preferable that the upper end (on the side of the solder mask 110) and the lower end (on the side of the semiconductor substrate 140) of the rear-surface insulating film 131 be within the width of the annular trench 142.

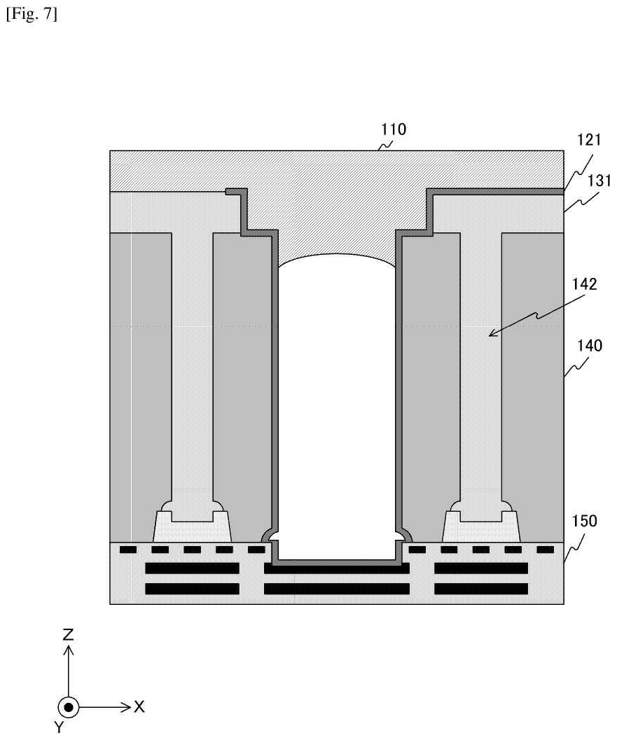

In addition, as illustrated in FIG. 7, the annular trench 142 can also be filled with the rear-surface insulating film 131. Hence, the manufacturing becomes easier depending on dimensions, and the insulation property also is enhanced. In addition, the durability against mechanical stress can be increased in some cases.

In the manner described above, since the cavity is left inside the annular trench 142 according to the first embodiment of the present technology, the yield can be enhanced. In addition, it is possible to reduce stress or manufacturing costs.

### 2. Second Embodiment

Whereas the rear-surface insulating film is a single layer in the first embodiment described above, it is difficult in this configuration to further enhance the insulation property and durability against mechanical stress of the annular trench 142. The semiconductor apparatus 100 in this second embodiment is different from that in the first embodiment in that there are two layers of rear-surface insulating films.

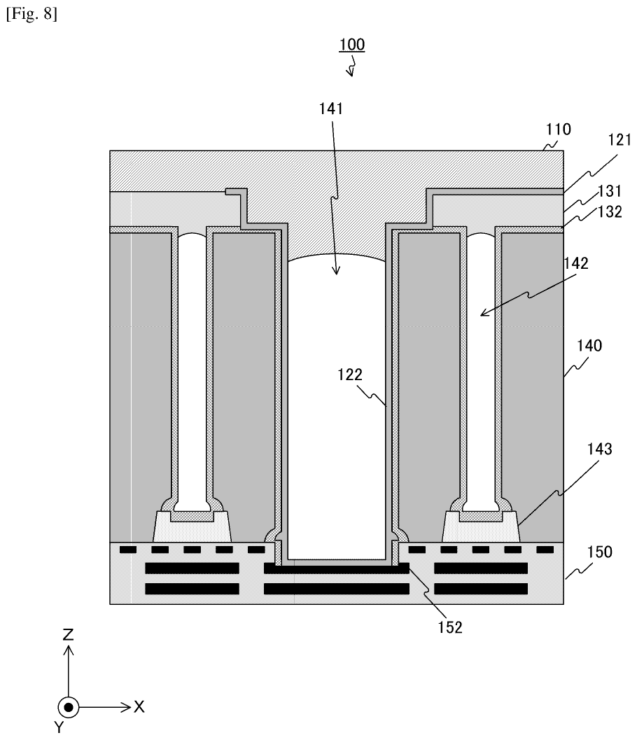

FIG. 8 is a cross-sectional view depicting a configuration example of the semiconductor apparatus 100 in the second embodiment of the present technology. A feature of the second embodiment is that a plurality of rear-surface insulating films are stacked one on another. For example, a rear-surface insulating film 132 is stacked on the rear-surface insulating film 131.

Preferably, the rear-surface insulating film 132 is formed on the rear surface of the semiconductor substrate 140 and the inside of the annular trench 142 and/or the through hole 141. The rear-surface insulating film 131 is formed in a region similar to the region where the rear-surface insulating film 131 is formed in the first embodiment. Each of the rear-surface insulating films 131 and 132 may be one formed by stacking a plurality of materials one on another. Note that the rear-surface insulating film 131 is an example of the first rear-surface insulating film described in the claims and that the rear-surface insulating film 132 is an example of the second rear-surface insulating film described in the claims.

As the rear-surface insulating film 132, SiO2 (silicon dioxide), SiN (silicon nitride), SiON (silicon oxynitride), or a fixed electric charge film is used. As the fixed electric charge film, HfO2 (hafnium oxide), Al2O3 (aluminum oxide), ZrO (zirconium oxide), Ta2O5 (tantalum oxide), titanium oxide (TiO2 (titanium oxide), LaO3 (lanthanum oxide), Pr6O11 (praseodymium oxide), CeO2 (cerium oxide), Nd2O3 (neodymium oxide), Pm2O3 (promethium oxide), Sm2O3 (samarium oxide), Eu2O3 (europium oxide), GdO3 (gadolinium oxide), Tb2O3 (terbium oxide), Dy2O3 (dysprosium oxide), Ho2O3 (holmium oxide), Tm2O3 (thulium oxide), Yb2O3 (ytterbium oxide), Lu2O3 (lutetium oxide), Y2O3 (yttrium oxide), AlN (aluminum nitride), HfON (hafnium oxynitride), AlON (aluminum oxynitride), or the like can be used. As in the first embodiment, the rear-surface insulating film 131 may close an upper portion of the annular trench 142. As in the first embodiment, as the rear-surface insulating film 131, a photosensitive insulating film including an organic material having a framework including polyimide, acryl, silicone, and an epoxy group can be used.

In the structure in the second embodiment, the rear-surface insulating film 132 can enhance the insulation property of the annular trench 142. In addition, the durability against mechanical stress can be enhanced. In particular, significant advantages can be attained by closing notching by a film with good coverage. In addition, by introducing the fixed electric charge film, it is possible to reduce the influence of defects at an interface or the front surface that can be the source of noise or leakage. In addition, by arranging different films or rear-surface insulating films 132 with different film thicknesses in the through hole 141 and the annular trench 142, it is also possible to control the balance of mechanical stress.

In the manner described above, since the two layers of the rear-surface insulating films 131 and 132 are stacked one on another on the rear surface according to the second embodiment of the present technology, the insulation property and durability against mechanical stress of the annular trench 142 can be enhanced.

### 3. Third Embodiment

Whereas the annular trench 142 is formed around the circumference of the through hole 141 in the through via 149 in the second embodiment described above, there is a possibility that it becomes difficult to attain a high degree of integration when annular trenches 142 are provided to all through vias. The semiconductor apparatus 100 in this third embodiment is different from that in the second embodiment in that through vias for which annular trenches 142 are formed and through vias for which annular trenches are not formed are mixedly present.

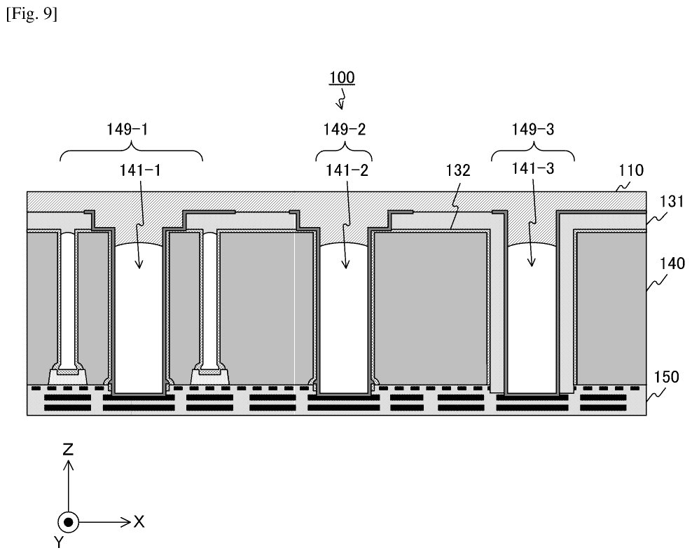

FIG. 9 is a cross-sectional view depicting a configuration example of the semiconductor apparatus 100 in the third embodiment of the present technology. A feature of the third embodiment is that it has a structure with a plurality of through vias. In the semiconductor apparatus 100 of the third embodiment, through vias 149-1, 149-2, and 149-3, for example, are formed.

The through via 149-1 has a structure similar to that in the second embodiment in which an annular trench to isolate the semiconductor substrate 140 is formed and a through wire is arranged inside a through hole 141-1.

The through via 149-2 does not have an annular trench around the circumference of a through hole 141-2, and the rear-surface insulating film 132 insulates the through wire and the semiconductor substrate. In addition, the through via 149-3 has a structure in which the rear-surface insulating film 132 and the rear-surface insulating film 131 are stacked one on another between a side wall of a through hole 141-3 and the semiconductor substrate 140. The structure in FIG. 9 is merely an example, and other combinations can also be adopted.

In the structure of the third embodiment, optimum shapes can be adopted in one die according to the purpose of through vias. For example, the through via 149-1 provided with the annular trench is used in a case where importance is placed on wire delays, and the through via 149-2 or 149-3 without an annular trench is used in a case where importance is placed on a high degree of integration. Thus, a structure that combines signal transfer performance and integration performance can be adopted.

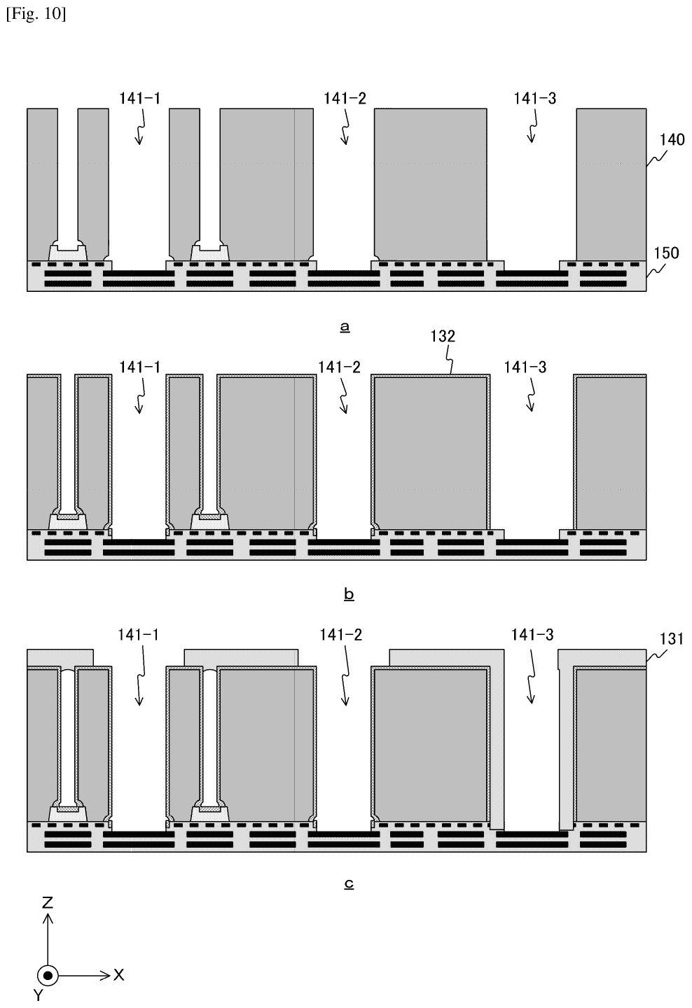

A manufacturing method for the semiconductor apparatus 100 in the third embodiment is depicted in FIG. 10. “a” in FIG. 10 is equivalent to “c” in FIG. 3 in the first embodiment. It should be noted that annular trenches are not formed around the circumference of the through holes 141-2 and 141-3.

Next, as illustrated in “b” in FIG. 10, an inorganic insulating film, for example, an SiO2 film, is formed as the rear-surface insulating film 132 over the entire surface including an annular trench and through holes, by ALD (Atomic Layer Deposition) or PE-CVD (Plasma Enhanced Chemical Vapor Deposition).

Next, as illustrated in “c” in FIG. 10, the photosensitive insulating resin is formed as the rear-surface insulating film 131 over the entire surface, and a part of the annular semiconductor substrate and the photosensitive resin in the through holes are removed by lithography. Film-formation conditions and a lithography mask pattern are adjusted such that the rear-surface insulating film 131 is also formed on a side surface of the through hole 141-3. Further, the entire surface is etched back, and each through hole is connected to a pad on the front-surface side.

Thereafter, as illustrated in “b” or “c” in FIG. 4 in the first embodiment, the through wire 122, the rear-surface redistribution wire 121, and the solder mask 110 are formed, and the structure in FIG. 9 is obtained.

By the manufacturing method described above, it becomes possible to form a plurality of types of through vias simultaneously without adding a manufacturing step to the second embodiment.

In the manner described above, since the through via 149-1 for which the annular trench 142 is formed and the through vias 149-2 and 149-3 without annular trenches are provided according to the third embodiment of the present technology, it is possible to pursue both signal transfer performance and integration performance.

### 4. Fourth Embodiment

Whereas the annular trench 142 is formed around the circumference of the through hole 141 in the through via 149 in the first embodiment described above, it is required to reduce pitches between a plurality of through vias when the through vias are arrayed, in some cases. The semiconductor apparatus 100 in this fourth embodiment is different from that in the first embodiment in that two adjacent through vias share parts of annular trenches.

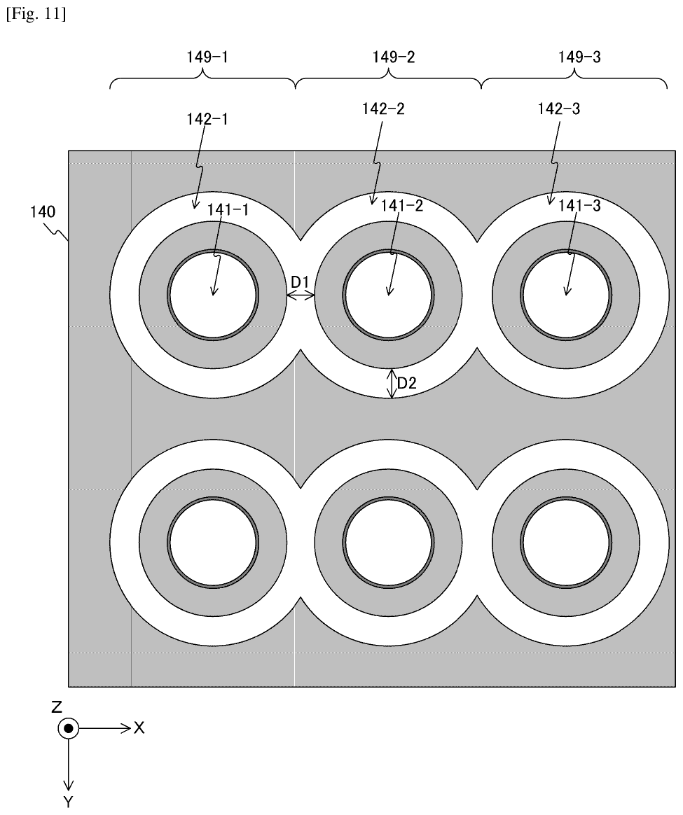

FIG. 11 is an example of a cross-sectional view of the semiconductor apparatus 100 in the fourth embodiment of the present technology seen in the Z-axis direction.

A plurality of through vias such as the through vias 149-1, 149-2, and 149-3 are arrayed in the X-axis direction and the Y-axis direction. Annular trenches such as annular trenches 142-1, 142-2 and 142-3 are formed around the circumference of respective through holes of the through vias. Two adjacent through vias arrayed in the X-axis direction share parts of annular trenches. For example, the through via 149-1 and the through via 149-2 share parts of the annular trench 142-1 and the annular trench 142-2. As a result, the pitch between the through vias can be reduced.

Note that, whereas through vias arrayed in the X-axis direction share parts of their annular trenches in FIG. 11, through vias arrayed in the Y-axis direction can also share parts of their annular trenches.

In addition, a width D1 of the portions shared by the annular trenches 142-1 and 142-2 can be made substantially the same as a width D2 of unshared portions. If the dimensions of shared portions are different from the dimensions of other parts in a case where annular trenches are shared, this causes a problem that the entrance amount of the rear-surface insulating film 131 varies when the insulating film is formed, for example, but the variation is reduced by making the widths approximately the same as depicted in FIG. 11.

Note that the second or third embodiment can be applied to the fourth embodiment.

In the manner described above, since two adjacent through vias share parts of annular trenches according to the fourth embodiment of the present technology, the pitch between the through vias can be made shorter than in a case where the two adjacent through vias do not share the parts.

### 5. Fifth Embodiment

Whereas the rear-surface redistribution wire 121 covers the inner side of the annular trench 142 in the first embodiment described above, the wiring reliability of this configuration is insufficient in some cases. The semiconductor apparatus 100 in this fifth embodiment is different from that in the first embodiment in that the rear-surface redistribution wire 121 covers the entire annular trench 142.

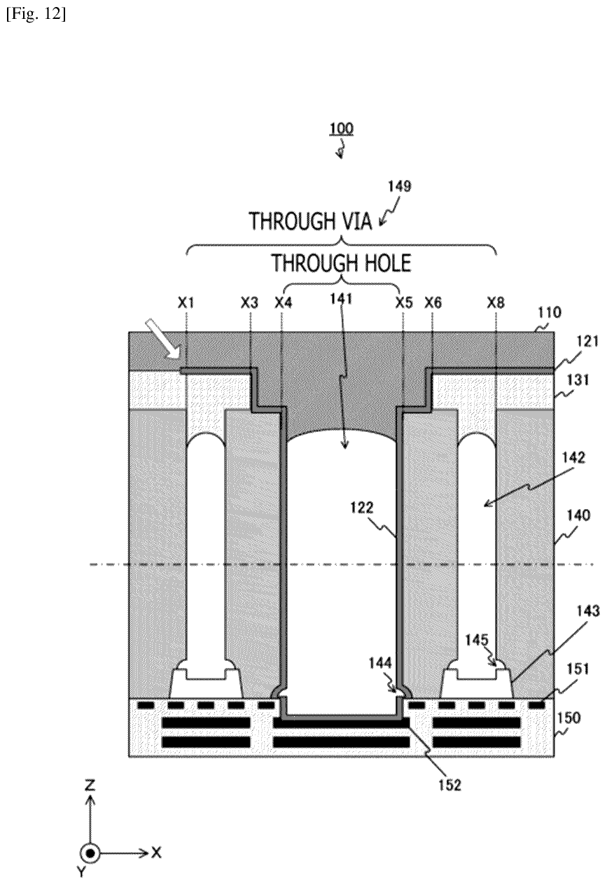

FIG. 12 is a cross-sectional view depicting a configuration example of the semiconductor apparatus 100 in the fifth embodiment of the present technology.

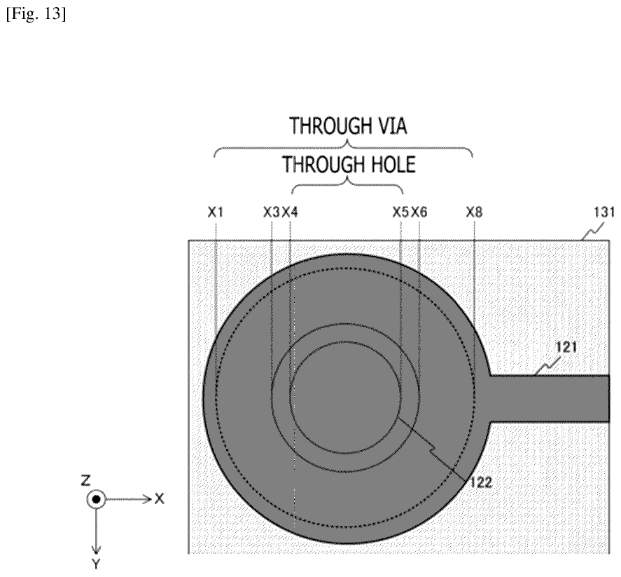

FIG. 13 is an example of a top view of the semiconductor apparatus 100 in the fifth embodiment of the present technology. FIG. 13 depicts a top view of the semiconductor apparatus 100 before being covered with the solder mask 110.

A feature of the fifth embodiment is that the rear-surface redistribution wire 121 facing the through wire 122 is formed in such a manner as to cover the entire annular trench 142. In FIG. 12 and FIG. 13, the area from the coordinate X1 to the coordinate X8 corresponds to the outer circumference of the through via 149, that is, the outer circumference of the annular trench 142. As illustrated in FIG. 13, the outer circumference of the rear-surface redistribution wire 121 is larger than the outer circumference of the annular trench 142.

At the upper portion of the annular trench 142, it is likely that stress is applied to the rear-surface redistribution wire 121 since the rigidity of the semiconductor substrate 140 is low. Because of this, it is likely that the wiring reliability deteriorates, but high wiring reliability is obtained in the fifth embodiment since a thin wire does not traverse the annular trench 142.

Note that each of the first, second, and third embodiments can be applied to the fifth embodiment.

In the manner described above, since the rear-surface redistribution wire 121 covers the entire annular trench 142 according to the fifth embodiment of the present technology, the wiring reliability is enhanced.

### 6. Sixth Embodiment

Whereas the rear-surface redistribution wire 121 is formed linearly from the circumference of the through hole 141 in the first embodiment described above, the width of the rear-surface redistribution wire 121 may not be constant. The semiconductor apparatus 100 in this sixth embodiment is different from that in the first embodiment in that the width of the rear-surface redistribution wire 121 at a portion traversing the upper portion of the annular trench 142 is made thicker.

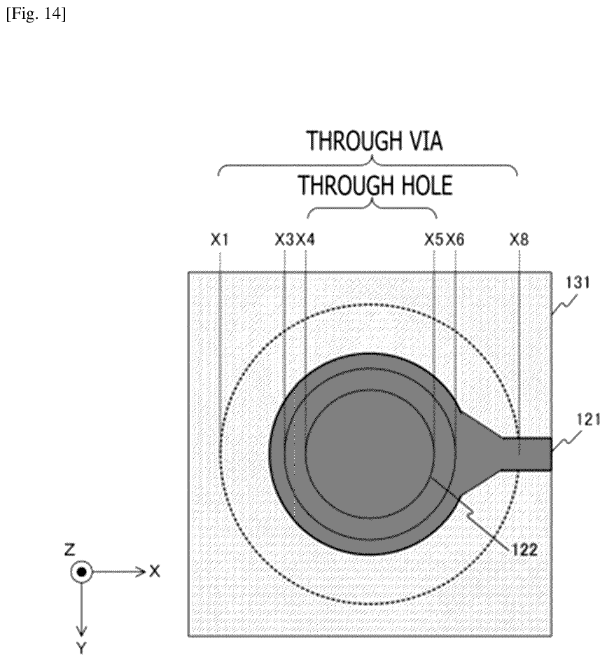

FIG. 14 is an example of a top view of the semiconductor apparatus 100 in the sixth embodiment of the present technology. FIG. 14 depicts a top view of the semiconductor apparatus 100 before being covered with the solder mask 110. The rear-surface redistribution wire 121 traverses the upper portion of the annular trench 142 in an area between the coordinate X6 and the coordinate X8, and the width of the upper portion of the annular trench 142 is thicker than the width of other portions of the rear-surface redistribution wire 121.

At the upper portion of the annular trench 142, it is likely that stress is applied to the rear-surface redistribution wire 121 since the rigidity of the semiconductor substrate 140 is low. Because of this, it is likely that the wiring reliability deteriorates, but high wiring reliability is obtained in the sixth embodiment by making the wire traversing the annular trench 142 thicker. In addition, since the area size of the rear-surface redistribution wire 121 is smaller than that in the fifth embodiment, this is advantageous for a high degree of integration.

Note that each of the first to fourth embodiments can be applied to the sixth embodiment.

In the manner described above, since the width of the rear-surface redistribution wire 121 at the portion traversing the upper portion of the annular trench 142 is made thicker according to the sixth embodiment of the present technology, the wiring reliability can be enhanced.

### 7. Seventh Embodiment

Whereas the entire opening of the rear-surface insulating film 131 is covered in the first embodiment described above, the yield of this structure is insufficient in some cases. The semiconductor apparatus 100 in the seventh embodiment is different from that in the first embodiment in that the inner side of the opening is covered.

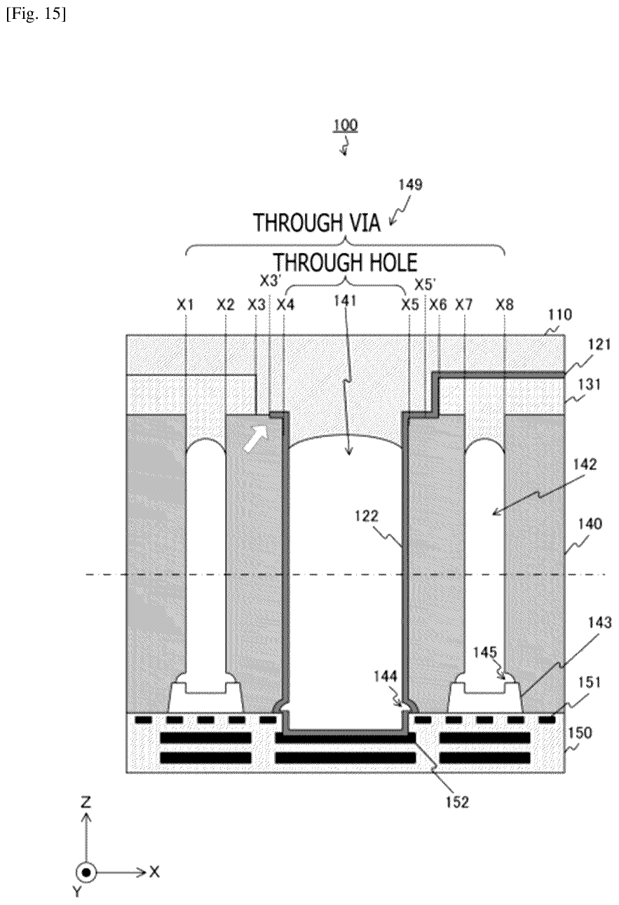

FIG. 15 is a cross-sectional view depicting a configuration example of the semiconductor apparatus 100 in the seventh embodiment of the present technology.

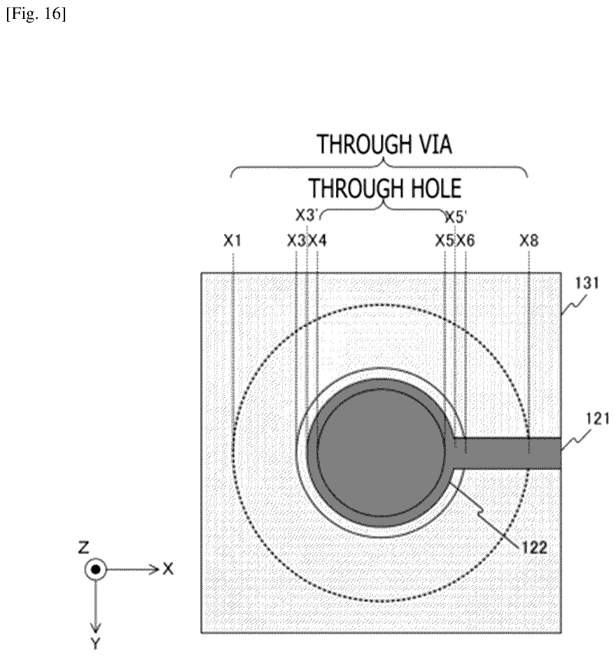

FIG. 16 is an example of a top view of the semiconductor apparatus 100 in the seventh embodiment of the present technology. FIG. 16 depicts a top view of the semiconductor apparatus 100 before being covered with the solder mask 110.

In the seventh embodiment, the rear-surface redistribution wire 121 around the circumference of the through hole 141 covers the rear surface of the inner side of the opening of the rear-surface insulating film 131. The area from the coordinate X3 to the coordinate X6 in FIG. 15 and FIG. 16 corresponds to the diameter of the opening formed through the rear-surface insulating film 131. A coordinate between the coordinate X3 and the coordinate X4 of an end of the through hole 141 is defined as X3′. In addition, a coordinate between the coordinate X5 of an end of the through hole 141 and the coordinate X6 is defined as X5′. The inner side of the opening from the coordinate X3′ to the coordinate X5′ is covered with the rear-surface redistribution wire 121.

Since a material with large stress is typically used for the rear-surface redistribution wire 121, the reliability of the through via 149 can be enhanced by reducing the area size of the rear-surface redistribution wire 121 as much as possible. On the other hand, there is a concern over deterioration of the yield since the exposure precision of lithography deteriorates at portions near the step (the coordinates X3 and X6) of the rear-surface insulating film 131. According to the structure illustrated in FIG. 15 and FIG. 16, it becomes possible to pursue both reduction of the stress and high yield by performing patterning in such a manner as not to be performed over the rear-surface insulating film 131 in advance.

Note that each of the first to fourth embodiments can be applied to the seventh embodiment.

In the manner described above, since the inner side of the rear-surface insulating film 131 is covered with the rear-surface redistribution wire 121 according to the seventh embodiment of the present technology, it becomes possible to pursue both reduction of stress and high yield.

### 8. Eighth Embodiment

Whereas the annular trench 142 is formed around the circumference of the through hole 141 in the through via 149 in the first embodiment described above, an external connection terminal, a circuit, and the like can be connected to the through via 149. The semiconductor apparatus 100 in this eighth embodiment is different from that in the first embodiment in that an external connection terminal, a photoelectric conversion layer, and the like are added to the semiconductor apparatus 100 to cause the semiconductor apparatus 100 to function as a solid-state imaging apparatus.

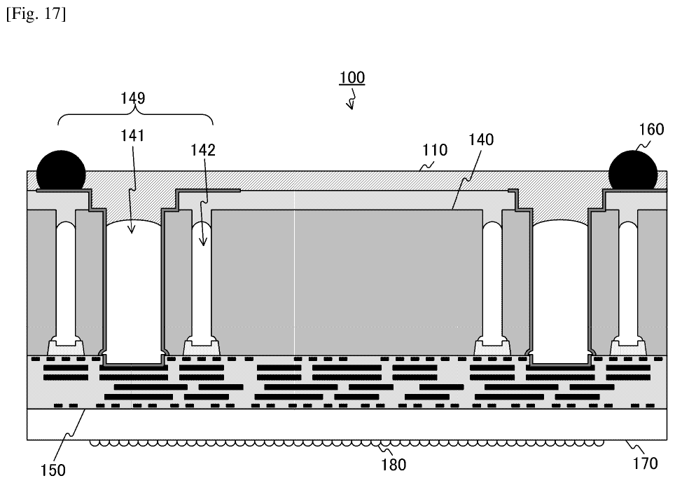

FIG. 17 is a cross-sectional view depicting a configuration example of the semiconductor apparatus 100 in the eighth embodiment of the present technology. This eighth embodiment is an example in which the structure of the through via 149 of the first embodiment is adopted for a backside-illumination solid-state imaging apparatus.

An external connection terminal 160 is connected to the through via 149 via the rear-surface redistribution wire 121. In addition, a photoelectric conversion layer 170 including a semiconductor substrate including silicon or the like, a group III-V substrate including GaAs (gallium nitride) or the like, an organic material, or a stack of layers of these, for example, is formed on the front-surface side via the wiring layer 150.

Further, a light-condensing structure such as an on-chip lens 180 is arranged on the lower-surface side of the photoelectric conversion layer 170 via an antireflection film (not depicted) or the like. Also in a solid-state imaging element, for example, an interface circuit needs to perform high-speed signal transfer with the outside, and performance higher than that of structures in the existing technology can be attained by adopting the low-capacity, high-reliability through via 149 according to an embodiment of the present disclosure.

Note that each of the second to seventh embodiments can be applied to the eighth embodiment.

In the manner described above, since the external connection terminal 160 and the photoelectric conversion layer 170 are formed according to the eighth embodiment of the present technology, the semiconductor apparatus 100 can be caused to function as a solid-state imaging apparatus.

### 9. Ninth Embodiment

Whereas the through via 149 is formed in the semiconductor substrate 140 in the first embodiment described above, there is a possibility that, when a measure is taken to lower the parasitic capacitance, a crack or peeling occurs at a bottom surface of the through hole 141 due to film stress of a conductive film (through wire 122). The semiconductor apparatus 100 in this ninth embodiment is different from that in the first embodiment in that a reinforcement film is formed around the circumference of the through hole 141.

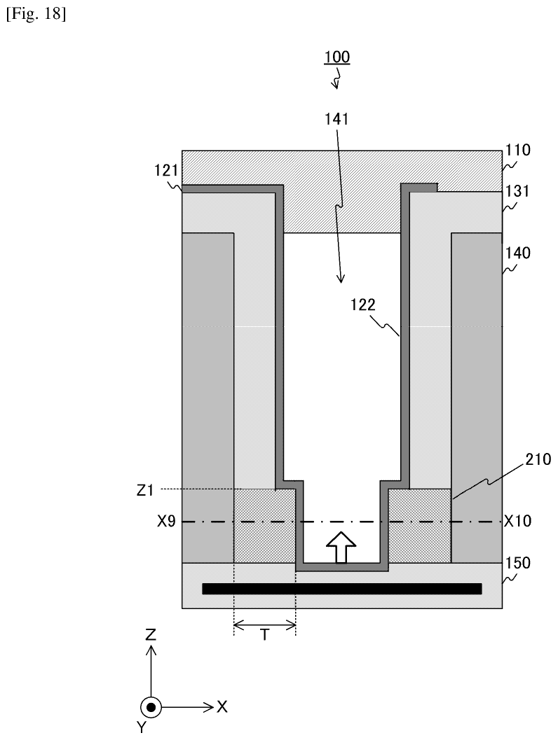

FIG. 18 is a cross-sectional view depicting a configuration example of the semiconductor apparatus 100 in the ninth embodiment of the present technology. The semiconductor apparatus 100 in this ninth embodiment is different from that in the first embodiment in that it further includes a reinforcement film 210. It is supposed in FIG. 18 that the annular trench 142 is not formed around the circumference of the through hole 141.

In addition, in the ninth embodiment, the through hole 141 has a step at a predetermined depth position Z1 when seen in the Y-axis direction or the X-axis direction. In addition, as the rear-surface insulating film 131, a material with a low dielectric constant such as a low-k film or resin is used. This rear-surface insulating film 131 covers, in addition to the upper surface (i.e., the rear surface) of the semiconductor substrate 140, the circumference of the through hole 141 in the area from the upper surface of the semiconductor substrate 140 to the depth position Z1. This rear-surface insulating film 131 with a low dielectric constant can reduce the parasitic capacitance of the through via 149 or the rear-surface redistribution wire 121. It should be noted that, in a case where the reinforcement film 210 is not provided in this configuration, there is a possibility that a crack or peeling occurs to the bottom surface of the through hole 141 due to film stress of the conductive film (through wire 122).

In addition, as the reinforcement film 210, an inorganic insulating film including SiO (silicon oxide), SiN (silicon nitride), SiON (silicon oxynitride), SiC (silicon carbide), or the like is used. This reinforcement film 210 covers the circumference of the through hole 141 in the area from the depth position Z1 to the wiring layer 150. The outer circumference of the reinforcement film 210 is in contact with the base material (silicon, etc.) of the semiconductor substrate 140.

As illustrated in FIG. 18, by forming the reinforcement film 210 at the lower end of the through hole 141, it is possible to suppress a crack or peeling of the bottom surface of the through hole 141 caused by film stress of the conductive film and the fragility of the rear-surface insulating film 131. An outline arrow in FIG. 18 represents the vector of a deformation that occurs at Cu due to the film stress.

As a thickness T of the reinforcement film 210 in the X-axis direction or the Y-axis direction increases, the degree of dispersion of the film stress can be increased to increase the likelihood of suppression of a crack or peeling. For example, the thickness T is adjusted to be equal to or larger than 5 micrometers (μm). In addition, in a case where the outer circumference of the reinforcement film 210 is in contact with the base material (silicon, etc.) of the semiconductor substrate 140 as illustrated in FIG. 18, the advantage in terms of reinforcement can be increased as compared with a case where the outer circumference of the reinforcement film 210 is not in contact with the base material of the semiconductor substrate 140.

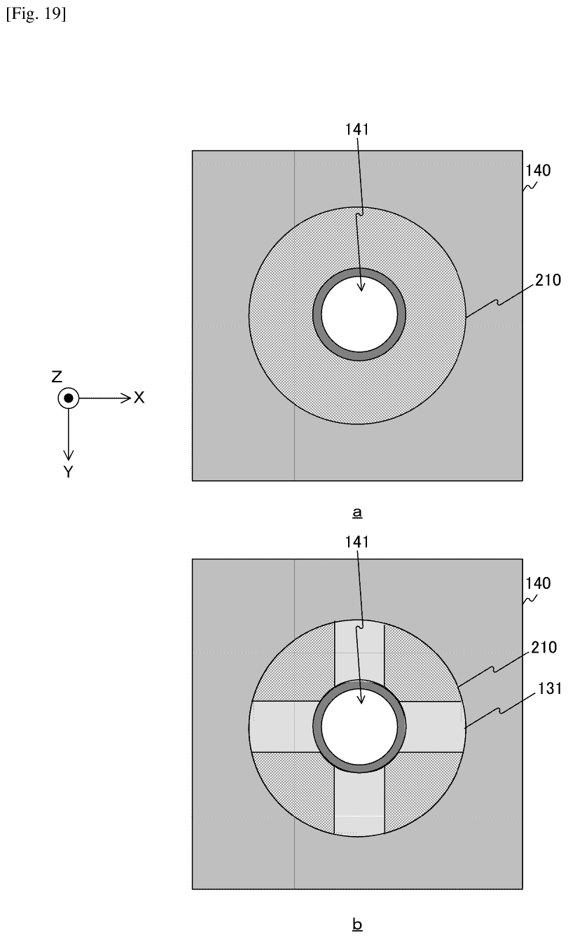

FIG. 19 depicts cross-sectional views of the semiconductor apparatus 100 in the ninth embodiment of the present technology seen in the Z-axis direction. “a” and “b” in FIG. 19 depict cross-sectional views when seen in the Z-axis direction, taken along a line segment X9-X10 in FIG. 18.

As illustrated in “a” in FIG. 19, the cross-sectional shape of the through hole 141 is a circular shape when seen in the Z-axis direction, and the reinforcement film 210 covers the entire circumference of the through hole 141.

Note that, in other possible configurations, the reinforcement film 210 covers parts of the circumference of the through hole 141 as illustrated in “b” in FIG. 19. Hence, the parasitic capacitance can be reduced more than in a case where the entire circumference is covered.

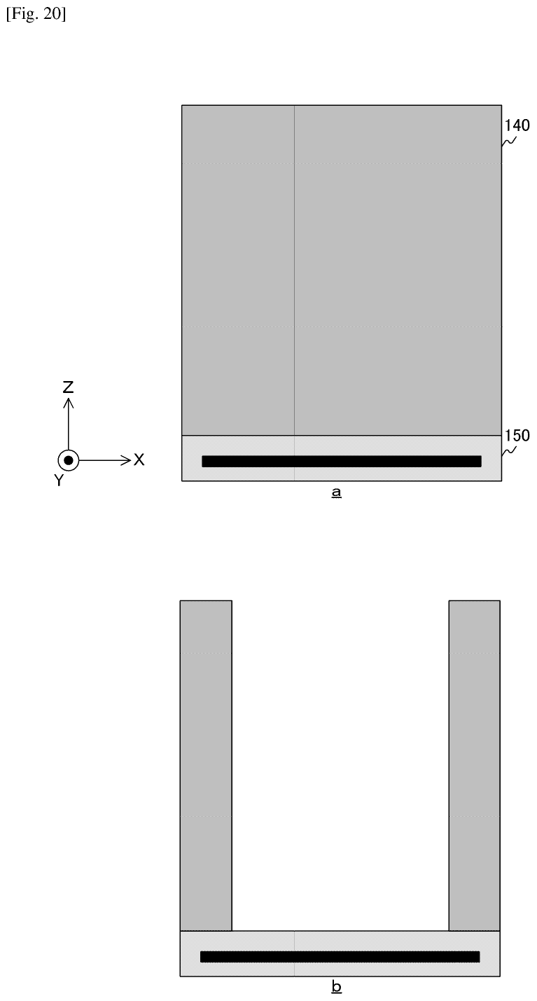

Next, a first manufacturing method for the semiconductor apparatus 100 in the ninth embodiment of the present technology is depicted in FIG. 20 to FIG. 23.

As illustrated in “a” in FIG. 20, the wiring layer 150 is formed on the front surface of the semiconductor substrate 140. Then, as illustrated in “b” in FIG. 20, an opening is formed in the semiconductor substrate 140.

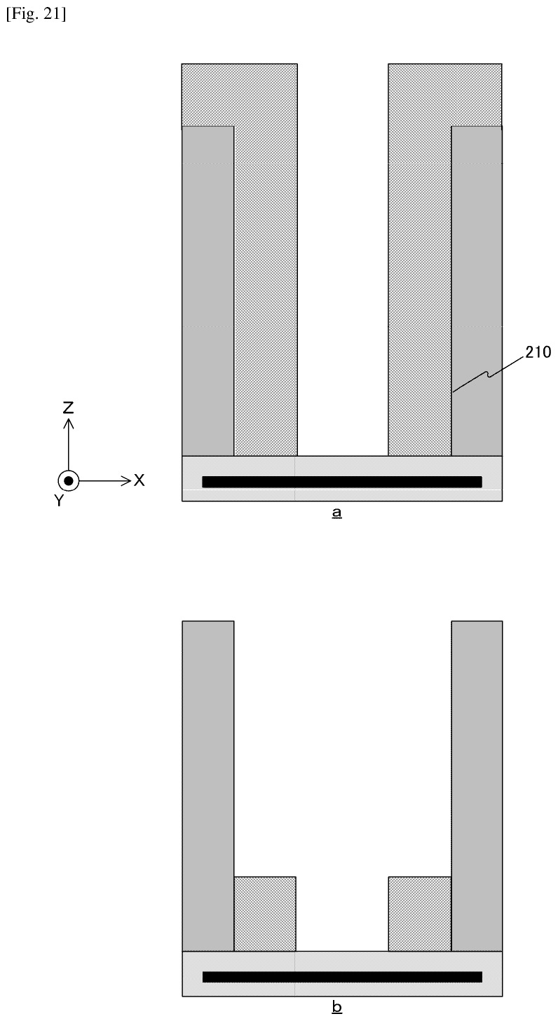

Next, as illustrated in “a” in FIG. 21, the reinforcement film 210 is formed. Then, as illustrated in “b” in FIG. 21, the reinforcement film 210 is etched back while its lower portion in the through hole is left unremoved.

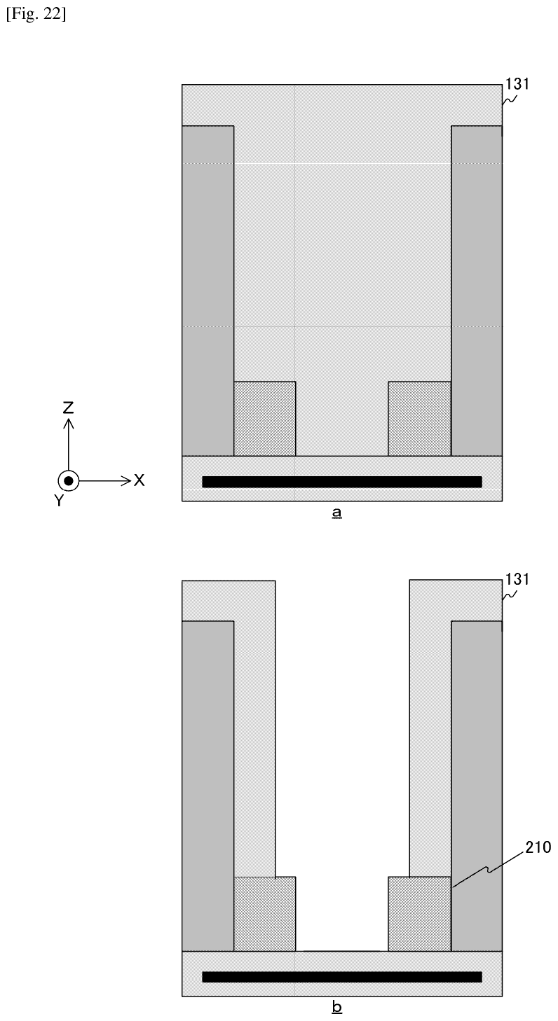

Next, as illustrated in “a” in FIG. 22, the rear-surface insulating film 131 with a low dielectric constant is formed. Then, as illustrated in “b” in FIG. 22, an opening is formed in the rear-surface insulating film 131 such that a step occurs.

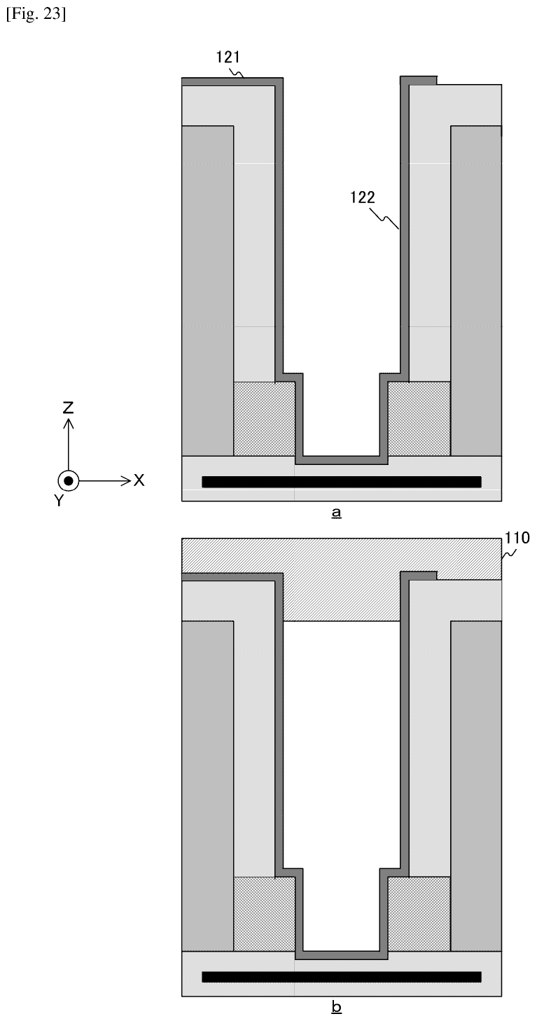

Next, as illustrated in “a” in FIG. 23, the conductive film (the rear-surface redistribution wire 121 and the through wire 122) is formed. Then, as illustrated in “b” in FIG. 23, a coating of the solder mask 110 is applied.

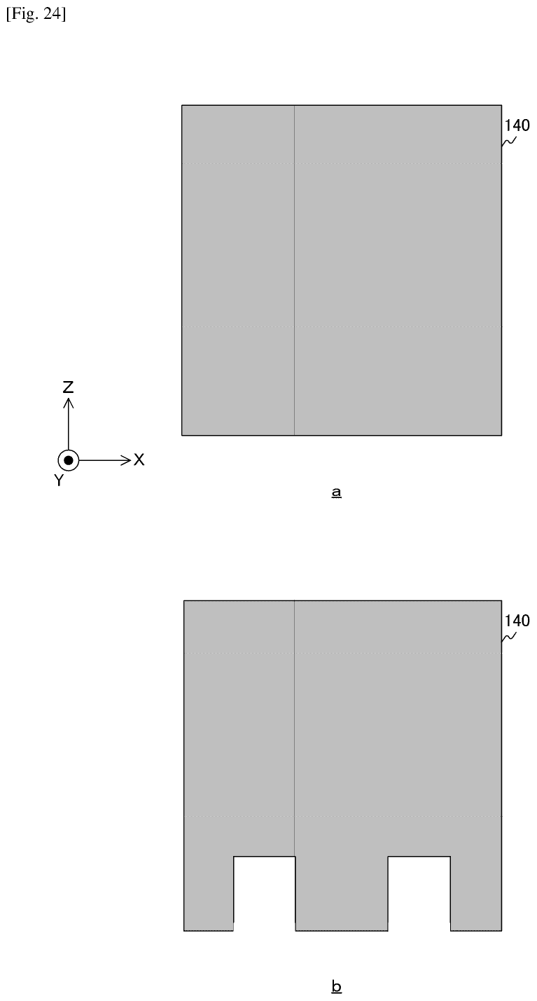

The manufacturing method of the ninth embodiment is not limited to the first manufacturing method described above. A second manufacturing method is depicted in FIG. 24 to FIG. 27.

As illustrated in “a” in FIG. 24, the semiconductor substrate 140 on which the wiring layer 150 has not yet been formed is placed with its front-surface side being positioned on the upper side. Then, as illustrated in “b” in FIG. 24, a trench is dug on its front-surface side.

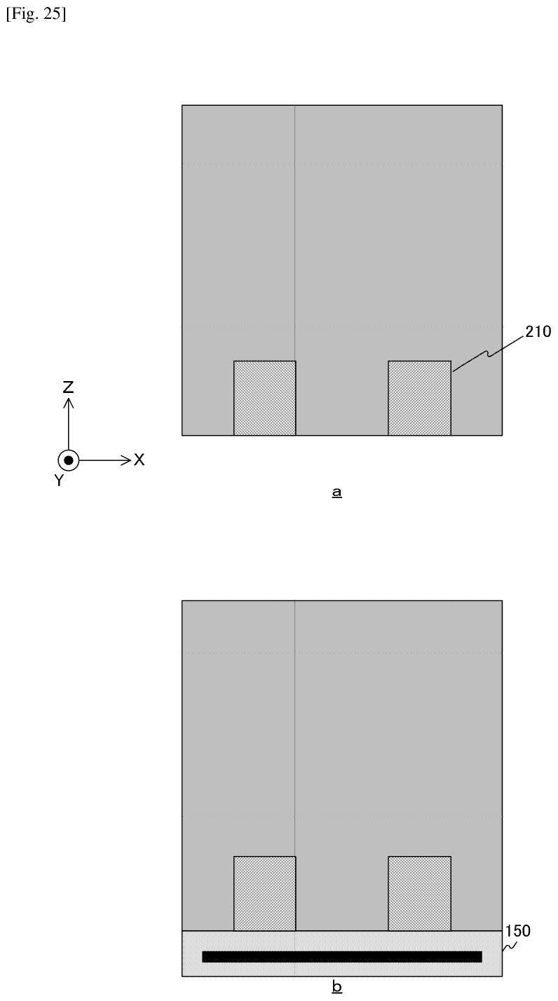

Next, as illustrated in “a” in FIG. 25, the reinforcement film 210 is formed in the trench, and STI is obtained. Then, as illustrated in “b” in FIG. 25, the wiring layer 150 is formed.

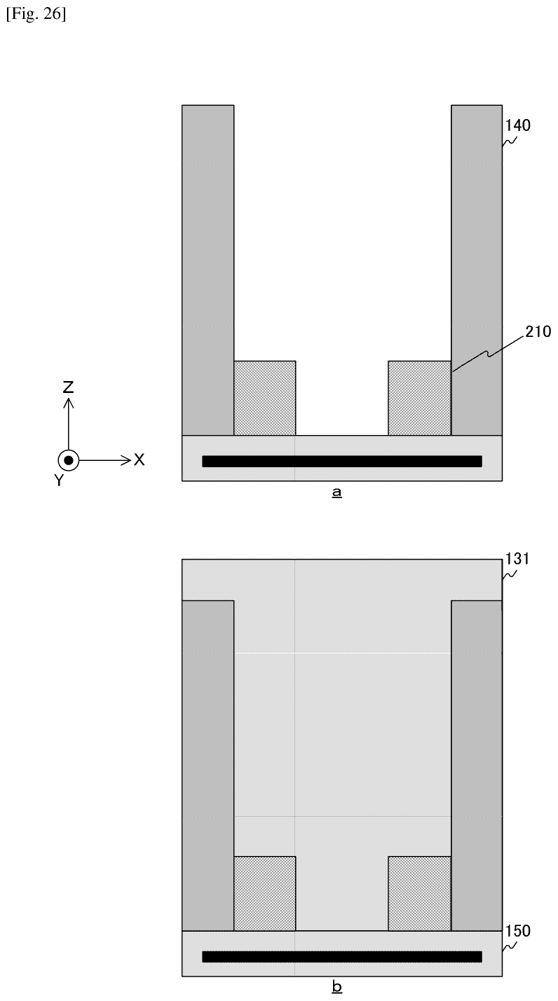

Next, as illustrated in “a” in FIG. 26, an opening is formed in the semiconductor substrate 140, and as illustrated in “b” in FIG. 26, the rear-surface insulating film 131 with a low dielectric constant is formed.

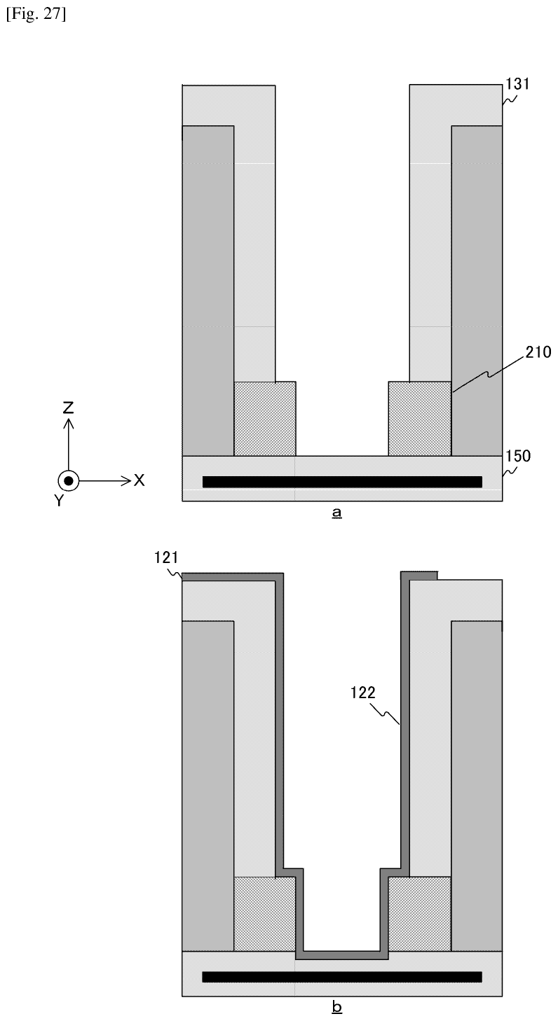

Next, as illustrated in “a” in FIG. 27, an opening is formed in the rear-surface insulating film 131, and as illustrated in “b” in FIG. 27, the conductive film is formed. Then, a coating of the solder mask 110 (not depicted) is applied.

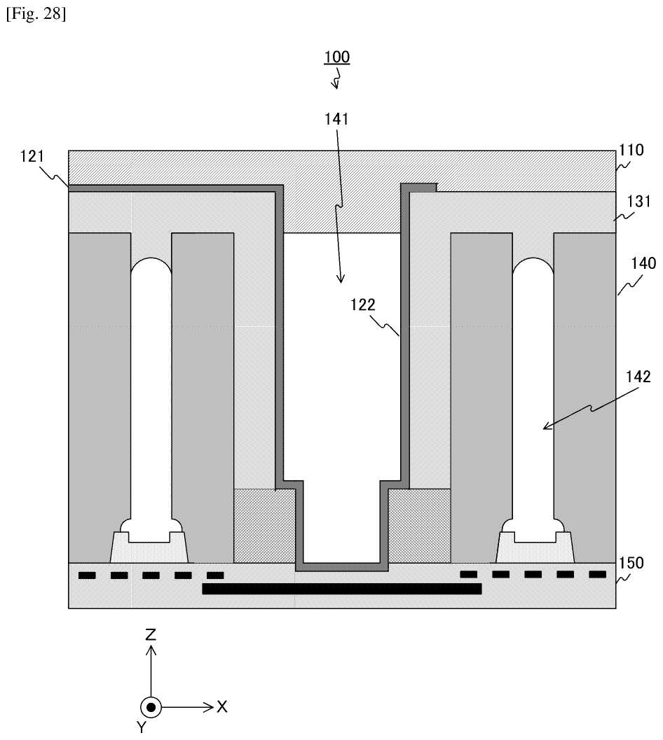

Note that, whereas the annular trench 142 is not arranged in FIG. 18, the annular trench 142 can also further be arranged as illustrated in FIG. 28. In addition, each of the first to eighth embodiments can be applied to the ninth embodiment.

In the manner described above, since the circumference of the through hole 141 in the area from the depth position Z1 to the wiring layer 150 is covered with the reinforcement film 210 according to the ninth embodiment of the present technology, a crack and peeling can be suppressed.

### First Modification Example

Whereas the through hole 141 is provided with a step in the ninth embodiment described above, a corner of the step gets rounded undesirably when the reinforcement film 210 is etched back, in some cases. The semiconductor apparatus 100 in this first modification example of the ninth embodiment is different from that in the ninth embodiment in that the cross-sectional shape of the through hole 141 has a curved tapered shape.

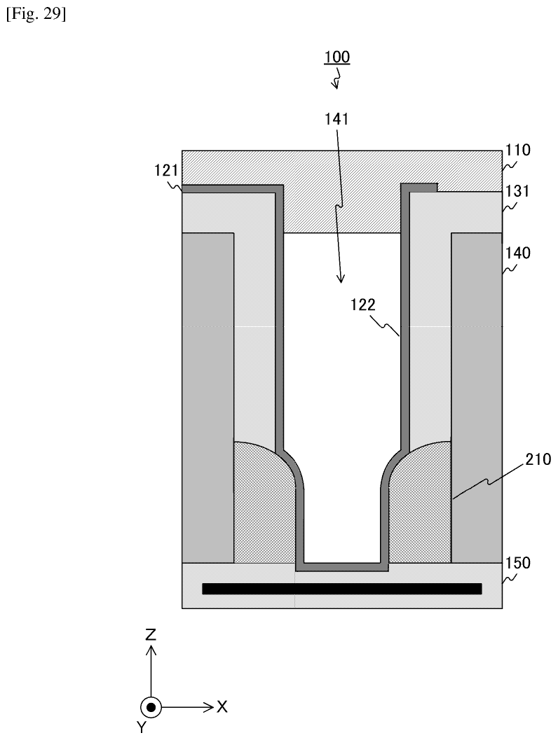

FIG. 29 is a cross-sectional view depicting a configuration example of the semiconductor apparatus 100 in the first modification example of the ninth embodiment of the present technology. The semiconductor apparatus 100 in this first modification example of the ninth embodiment is different from that in the ninth embodiment in that the cross-sectional shapes of the through hole 141 and the reinforcement film 210 seen in the X-axis direction or the Y-axis direction each have a curved tapered shape. This makes it easier to adjust the cross-sectional shapes at a time of etch-back.

Note that each of the first to eighth embodiments can be applied to the first modification example of the ninth embodiment.

In the manner described above, since the cross-sectional shapes of the through hole 141 and the reinforcement film 210 each have a curved tapered shape according to the first modification example of the ninth embodiment of the present technology, it becomes easier to adjust the cross-sectional shapes at a time of etch-back.

### Second Modification Example

Whereas the reinforcement film 210 is formed such that the outer circumference of the reinforcement film 210 is in contact with the base material of the semiconductor substrate 140 in the ninth embodiment described above, there is a possibility that the parasitic capacitance increases as the thickness of the reinforcement film 210 increases. The semiconductor apparatus 100 in this second modification example of the ninth embodiment is different from that in the ninth embodiment in that the rear-surface insulating film 131 covers the circumference of the through hole 141 and the circumference of the reinforcement film 210.

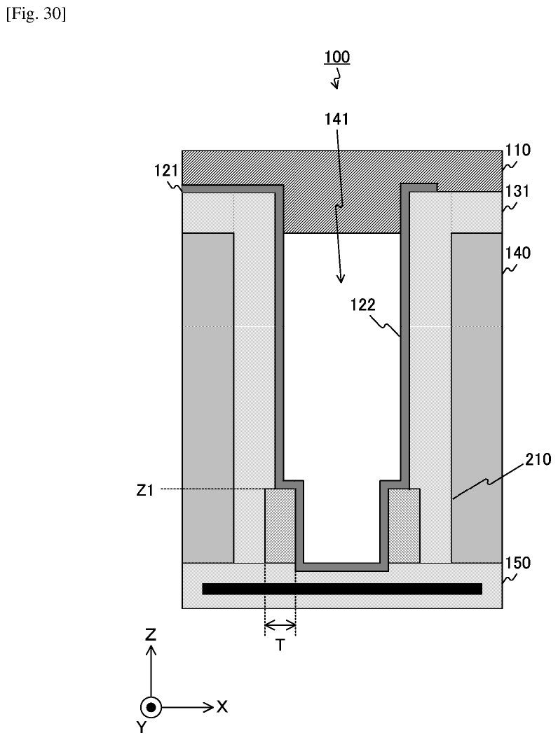

FIG. 30 is a cross-sectional view depicting a configuration example of the semiconductor apparatus 100 in the second modification example of the ninth embodiment of the present technology. The semiconductor apparatus 100 in this second modification example of the ninth embodiment is different from that in the ninth embodiment in that the rear-surface insulating film 131 also covers the circumference of the reinforcement film 210, in addition to the circumference of the through hole 141.

As illustrated in FIG. 30, in a case where the reinforcement film 210 is not in contact with the base material of the semiconductor substrate 140, an optimum value of the thickness T of the reinforcement film 210 is within a certain range. If the thickness T is too small, the advantage in terms of reinforcement is insufficient. On the other hand, if the thickness T is too large, there is a possibility that the whole reinforcement film 210 is lifted and peeled off, resulting in a mere change of the peeling position, undesirably. In addition, there is a possibility that the parasitic capacitance increases. For example, the thickness T is preferably adjusted to be in the range of 5 to 10 micrometers (μm).

Note that each of the first to eighth embodiments can be applied to the second modification example of the ninth embodiment.

In the manner described above, since the rear-surface insulating film 131 covers the circumference of the through hole 141 and the circumference of the reinforcement film 210 according to the second modification example of the ninth embodiment of the present technology, the thickness of the reinforcement film 210 can be reduced to reduce the parasitic capacitance.

### Third Modification Example

Whereas the through hole 141 is provided with a step in the ninth embodiment described above, a step can also be provided to the base material of the semiconductor substrate 140 instead of the through hole 141. The semiconductor apparatus 100 in this third modification example of the ninth embodiment is different from that in the ninth embodiment in that the base material of the semiconductor substrate 140 has a step.

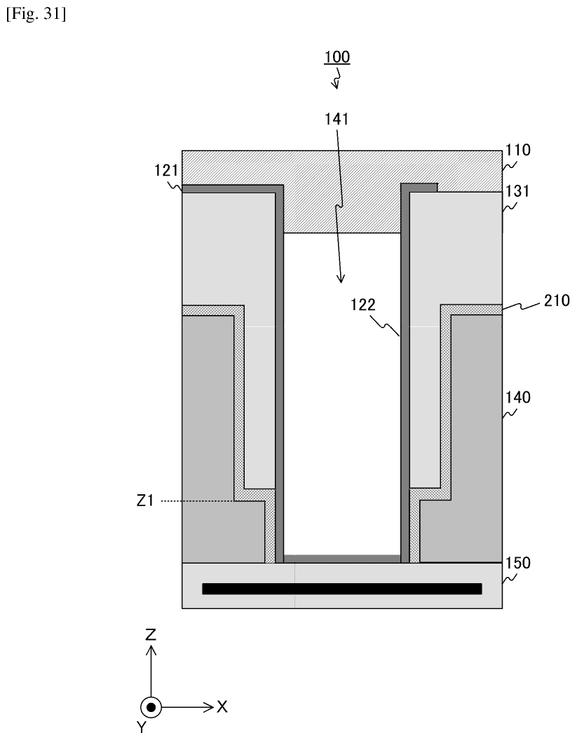

FIG. 31 is a cross-sectional view depicting a configuration example of the semiconductor apparatus 100 in the third modification example of the ninth embodiment of the present technology. The semiconductor apparatus 100 in this third modification example of the ninth embodiment is different from that in the ninth embodiment in that the through hole 141 does not have a step, but instead the base material of the semiconductor substrate 140 has a step at the depth position Z1.

The rear-surface insulating film 131 covers the through hole 141 in the area from the rear surface to the depth position Z1. In addition, the reinforcement film 210 covers the through hole 141 in the area from the depth position Z1 to the wiring layer 150. In addition, the reinforcement film 210 is formed along the base material of the semiconductor substrate 140, and is positioned between the base material and the rear-surface insulating film 131 at the portion higher than the depth position Z1.

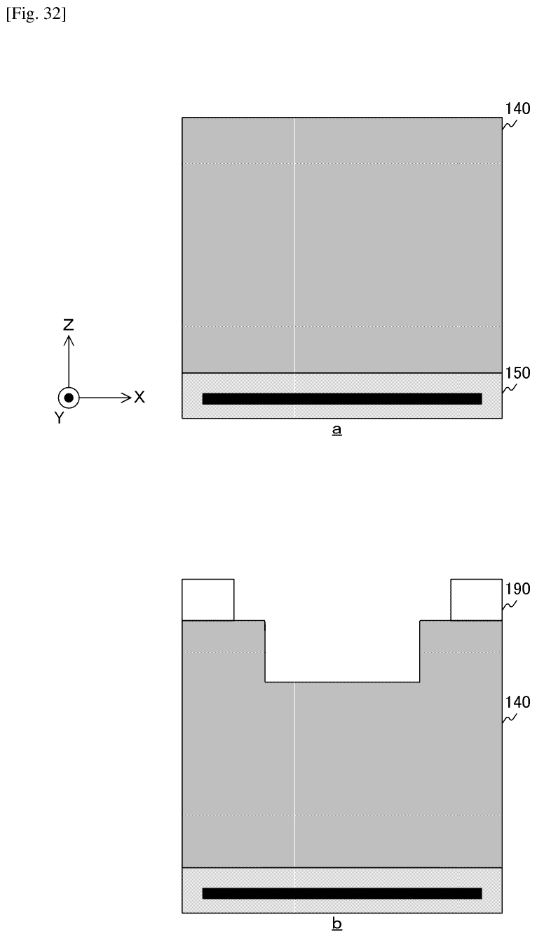

Next, a manufacturing method for the semiconductor apparatus 100 in the third modification example of the ninth embodiment of the present technology is depicted in FIG. 32 to FIG. 35.

As illustrated in “a” in FIG. 32, the wiring layer 150 is formed on the front surface of the semiconductor substrate 140. Then, as illustrated in “b” in FIG. 32, an opening is formed in the semiconductor substrate 140, and a coating of the resist mask 190 is applied to portions other than a portion where a step is desired to be provided.

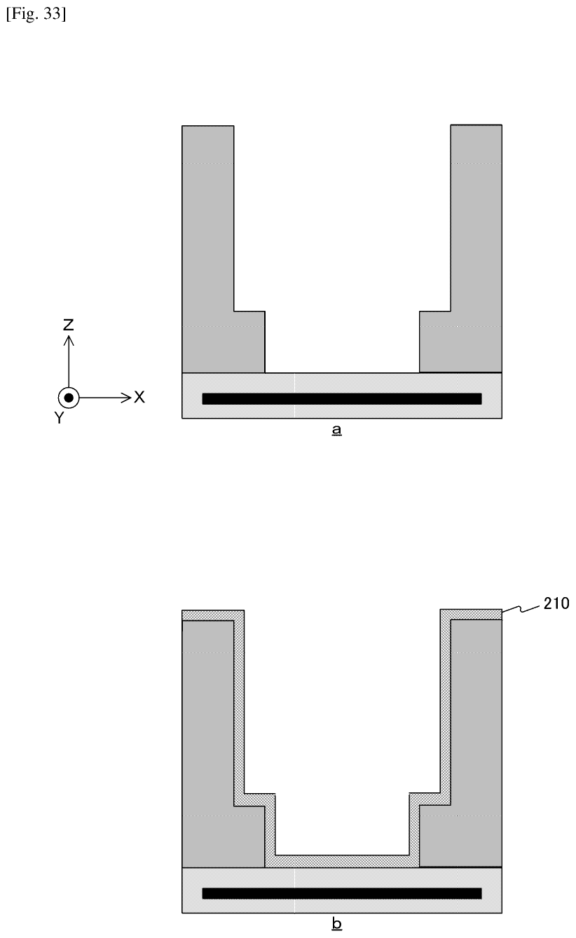

Next, as illustrated in “a” in FIG. 33, the step is formed at the opening of the base material, and the resist mask 190 is removed. Then, as illustrated in “b” in FIG. 33, the reinforcement film 210 is formed.

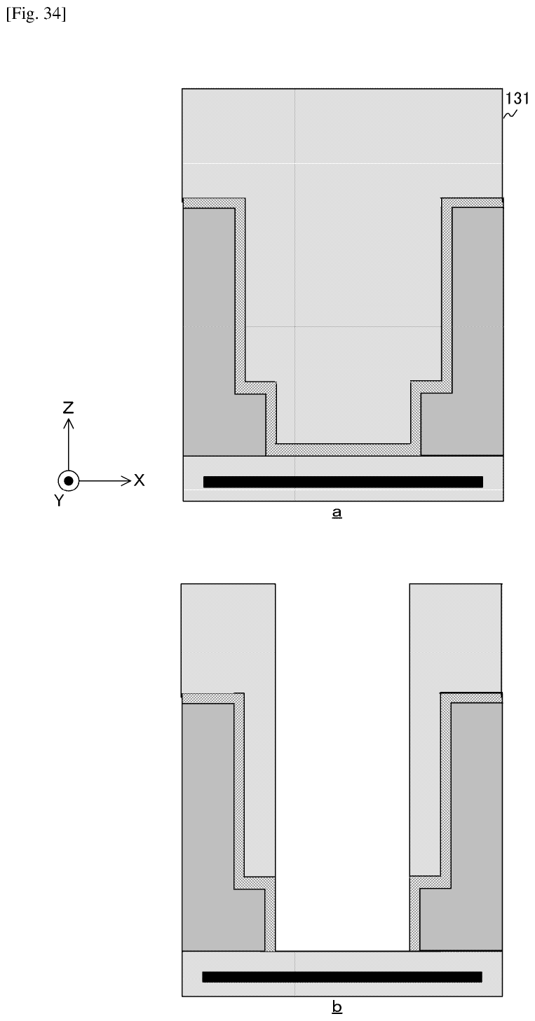

Next, as illustrated in “a” in FIG. 34, the rear-surface insulating film 131 is formed, and as illustrated in “b” in FIG. 34, an opening is formed in the rear-surface insulating film 131.

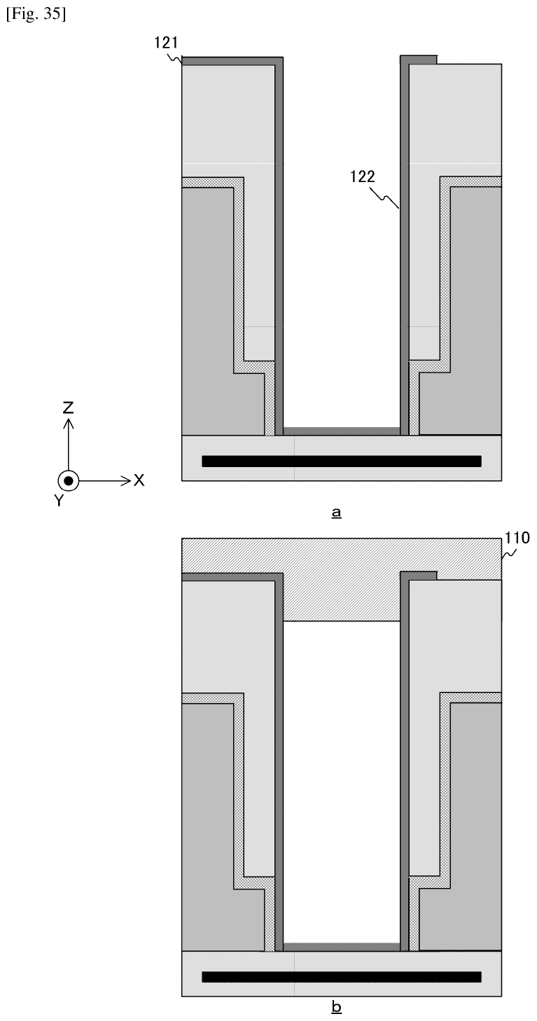

Next, as illustrated in “a” in FIG. 35, the conductive film (the rear-surface redistribution wire 121 and the through wire 122) is formed. Then, as illustrated in “b” in FIG. 35, a coating of the solder mask 110 is applied.

Note that each of the first to eighth embodiments can be applied to the third modification example of the ninth embodiment.

In the manner described above, since the base material of the semiconductor substrate 140 is provided with a step according to the third modification example of the ninth embodiment of the present technology, it becomes unnecessary to provide a step to the through hole 141.

### Fourth Modification Example

Whereas the cross-sectional shape of the through hole 141 when seen in the Z-axis direction is a circular shape in the ninth embodiment described above, it can also be a rectangular shape. The semiconductor apparatus 100 in this fourth modification example of the ninth embodiment is different from that in the ninth embodiment in that the cross-sectional shape of the through hole 141 is a rectangular shape.

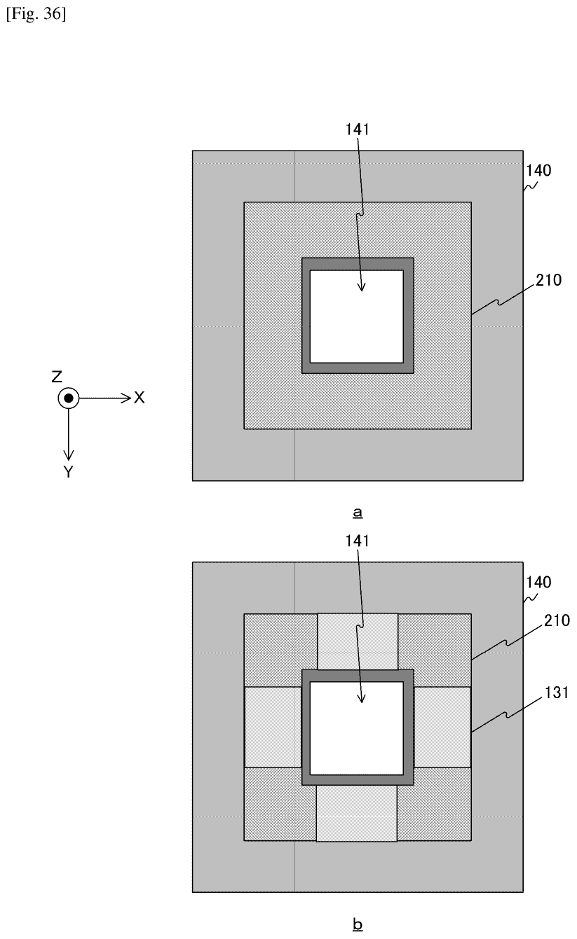

FIG. 36 depicts cross-sectional views of the semiconductor apparatus 100 in the fourth modification example of the ninth embodiment of the present technology seen in the Z-axis direction. “a” and “b” in FIG. 36 depict cross-sectional views when seen in the Z-axis direction, taken along the line segment X9-X10 in FIG. 18.

As illustrated in “a” in FIG. 36, the cross-sectional shape of the through hole 141 is a rectangular shape when seen in the Z-axis direction, and the reinforcement film 210 covers the entire circumference of the through hole 141.

Note that, in other possible configurations, the reinforcement film 210 covers parts of the circumference of the through hole 141 as illustrated in “b” in FIG. 36. Hence, the parasitic capacitance can be reduced more than in a case where the entire circumference is covered.

Note that each of the first to eighth embodiments can be applied to the fourth modification example of the ninth embodiment.

In the manner described above, according to the fourth modification example of the ninth embodiment of the present technology, a crack and peeling in the semiconductor apparatus 100 in which the cross-sectional shape of the through hole 141 is a rectangular shape can be suppressed.

### Fifth Modification Example

Whereas the cross-sectional shape of the through hole 141 when seen in the Z-axis direction is a circular shape in the ninth embodiment described above, it can also be a non-rectangular polygonal shape (hexagonal shape). The semiconductor apparatus 100 in this fifth modification example of the ninth embodiment is different from that in the ninth embodiment in that the cross-sectional shape of the through hole 141 is a hexagonal shape.

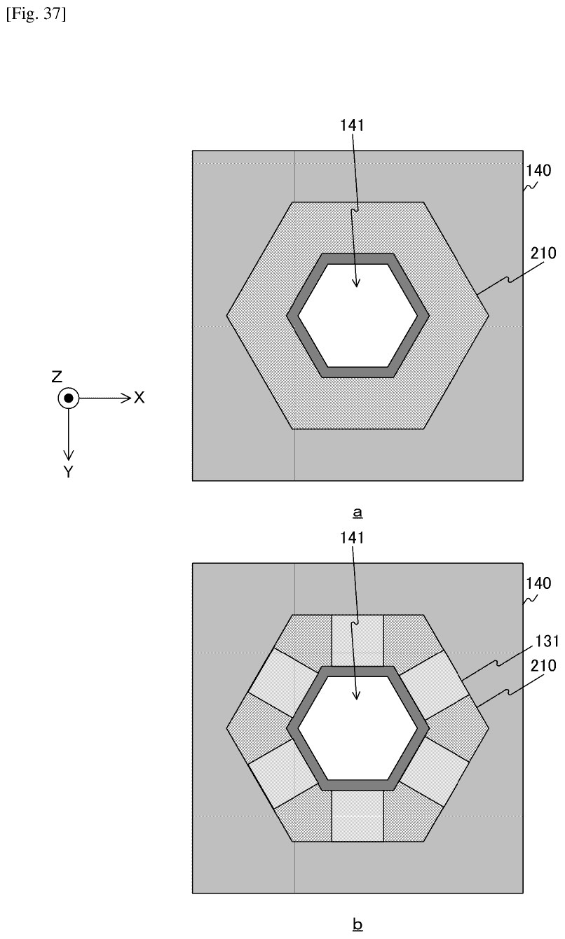

FIG. 37 depicts cross-sectional views of the semiconductor apparatus 100 in the fifth modification example of the ninth embodiment of the present technology seen in the Z-axis direction. “a” and “b” in FIG. 37 depict cross-sectional views when seen in the Z-axis direction, taken along the line segment X9-X10 in FIG. 18.

As illustrated in “a” in FIG. 37, the cross-sectional shape of the through hole 141 is a non-rectangular polygonal shape (hexagonal shape, etc.) when seen in the Z-axis direction, and the reinforcement film 210 covers the entire circumference of the through hole 141. Note that, whereas the cross-sectional shape is a hexagonal shape in FIG. 37, it may be a polygonal shape other than a hexagonal shape.

In addition, in other possible configurations, the reinforcement film 210 covers parts of the circumference of the through hole 141 as illustrated in “b” in FIG. 37. Hence, the parasitic capacitance can be reduced more than in a case where the entire circumference is covered.

In addition, each of the first to eighth embodiments can be applied to the fifth modification example of the ninth embodiment.

In the manner described above, according to the fifth modification example of the ninth embodiment of the present technology, a crack and peeling in the semiconductor apparatus 100 in which the cross-sectional shape of the through hole 141 is a hexagonal shape can be suppressed.

### 10. Tenth Embodiment

Whereas the annular trench 142 is formed around the circumference of the through hole 141 in the first embodiment described above, there is a possibility that the semiconductor substrate 140 is peeled off due to shrinkage of the rear-surface insulating film 131 at an upper portion at a time of annealing. The semiconductor apparatus 100 in this tenth embodiment is different from that in the first embodiment in that a protective member is provided to a lower portion of the annular trench 142 to suppress peeling.

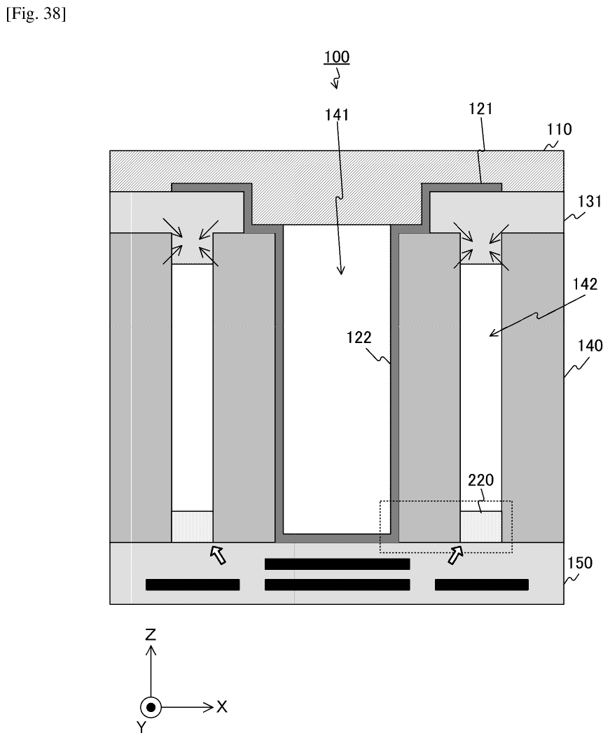

FIG. 38 is a cross-sectional view depicting a configuration example of the semiconductor apparatus 100 in the tenth embodiment of the present technology. The semiconductor apparatus 100 in this tenth embodiment is different from that in the first embodiment in that a protective member 220 is arranged adjacent to the wiring layer 150 in the annular trench 142. As the protective member 220, an insulating resin is used, for example. This resin material may be the same as or different from that of the rear-surface insulating film 131.

When annealing is performed in a manufacturing step, the rear-surface insulating film 131 having entered the upper portion of the annular trench 142 shrinks. Black arrows in FIG. 38 represent directions of the shrinkage. Due to the shrinkage, stress to cause the semiconductor substrate 140 to be peeled off is generated, and the stress is concentrated in particular at an inner-circumference-side corner of the bottom of the annular trench 142. Outline arrows in FIG. 38 represent directions of the stress.

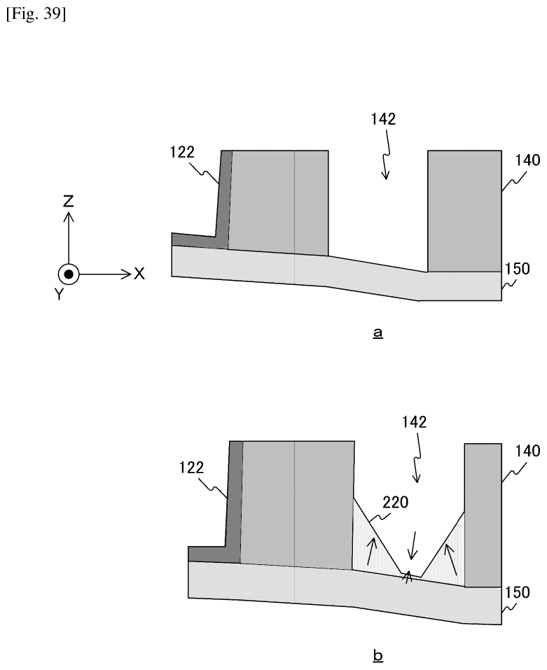

FIG. 39 is a view illustrating some advantages of the semiconductor apparatus in the tenth embodiment of the present technology. “a” in FIG. 39 depicts an enlarged view of a portion in FIG. 38 enclosed by a dotted line in a case where the protective member 220 is not provided. “b” in FIG. 39 depicts an enlarged view in a case where the protective member 220 is provided.

By making the annular trench 142 hollow, the dielectric constant can be lowered, and high-speed transfer can be realized. It should be noted that, in a case where the protective member 220 is not provided as illustrated in “a” in FIG. 39, there is a possibility that the semiconductor substrate 140 or the wiring layer 150 deforms and the semiconductor substrate 140 is peeled off locally. Note that the degrees of deformation are represented exaggeratingly by a hundred-fold or more in “a”and “b”in FIG. 39.

On the other hand, in a case where the protective member 220 is provided as illustrated in “b” in FIG. 39, the protective member 220 shrinks, and deformation of the semiconductor substrate 140 and the wiring layer 150 is suppressed owing to the shrinkage. Arrows in “b” in FIG. 39 represent directions of the shrinkage. As a result, local peeling is suppressed. For example, by making the film thickness of the protective member 220 equal to or larger than 5 micrometers (μm), peeling can be suppressed sufficiently. Accordingly, it is possible to pursue both high-speed transfer owing to the hollow annular trench 142 and suppression of peeling.

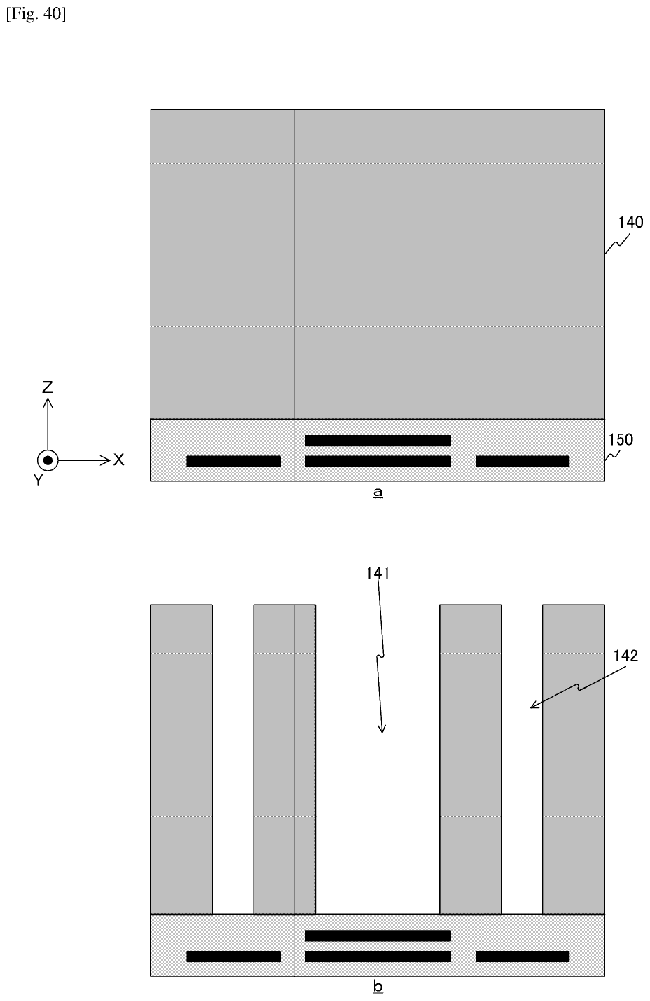

Next, a manufacturing method for the semiconductor apparatus 100 in the first embodiment of the present technology is depicted in FIG. 40 to FIG. 42.

As illustrated in “a” in FIG. 40, the wiring layer 150 is formed on the front surface of the semiconductor substrate 140. Then, as illustrated in “b” in FIG. 40, the through hole 141 and the annular trench 142 are formed by dry etching. Note that the through hole 141 and the annular trench 142 may be formed simultaneously in one step or may be formed separately in two steps.

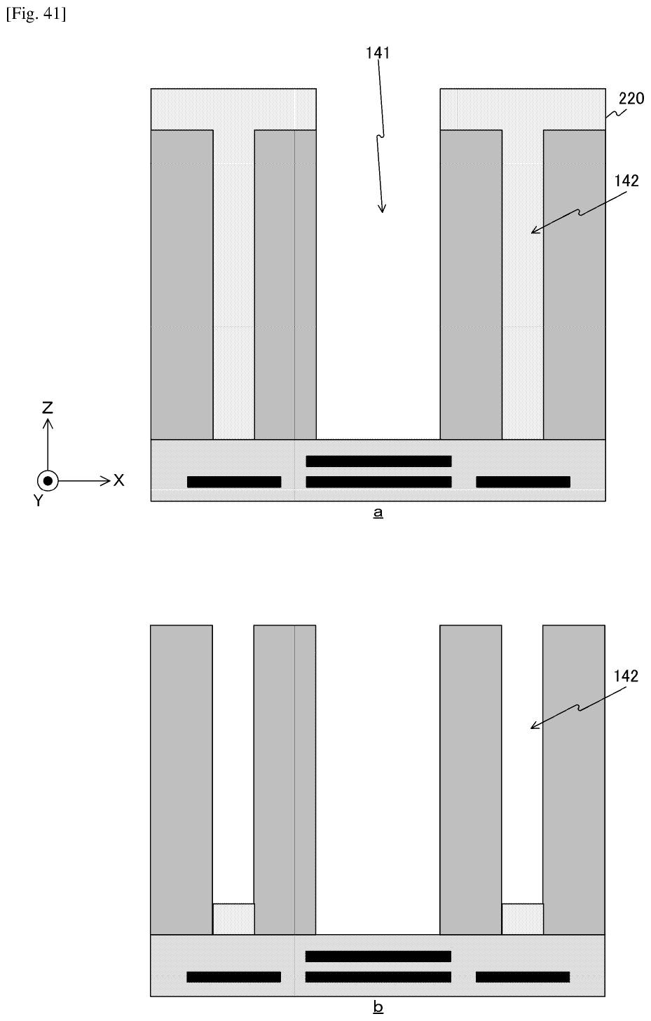

Next, a coating of the photosensitive protective member 220 is applied as illustrated in “a”in FIG. 41, and the portion of the through hole 141 is removed by lithography.

Then, as illustrated in “b” in FIG. 41, etch-back is performed such that the protective member 220 is kept unremoved only at the bottom of the annular trench 142.

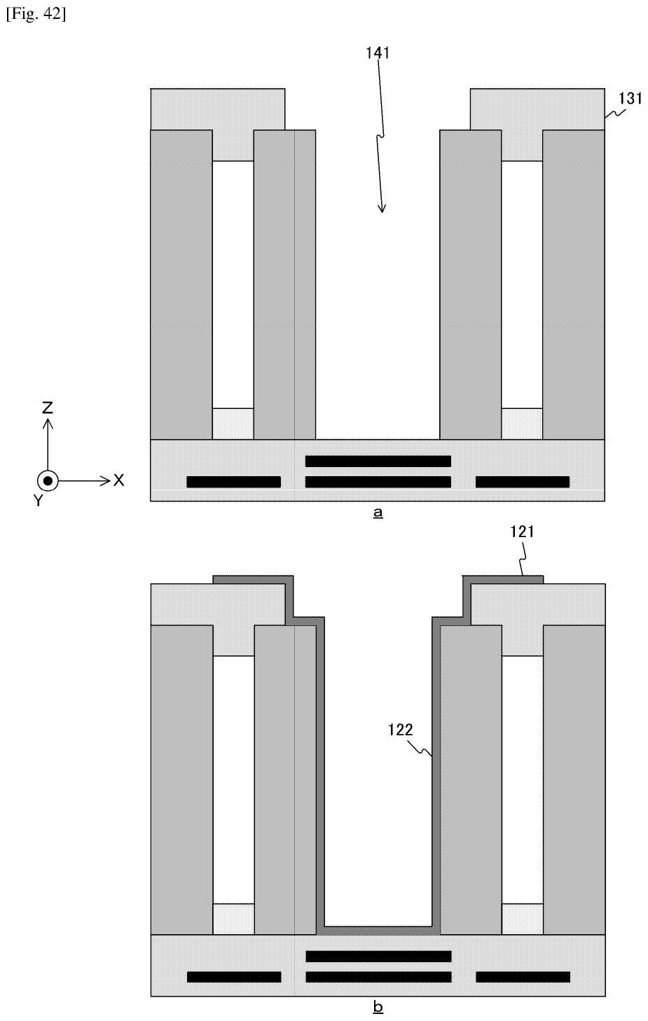

Next, as illustrated in “a” in FIG. 42, the photosensitive rear-surface insulating film 131 is formed, and is removed from within the through hole 141 and a part of the circumference of the through hole 141 by lithography. Then, as illustrated in “b” in FIG. 42, the rear-surface redistribution wire 121 and the through wire 122 are formed simultaneously. Then, the solder mask 110 (not depicted) is formed, and the semiconductor apparatus 100 in FIG. 38 is obtained.

Note that, whereas the protective member 220 is formed in such a manner as to cover the entire bottom surface of the annular trench 142 in FIG. 38, this configuration is not the sole example.

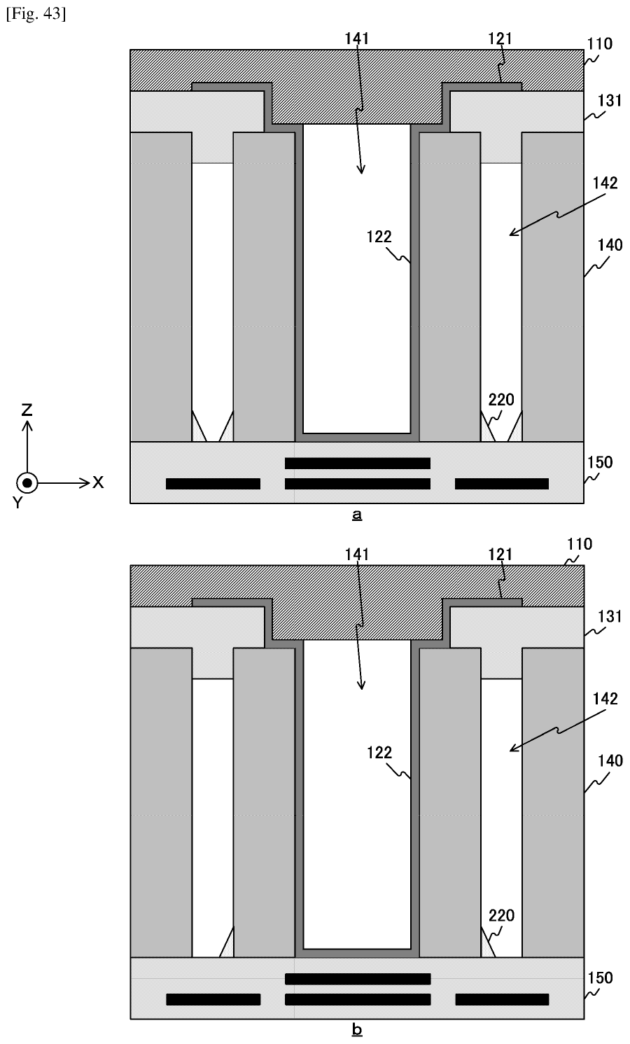

As illustrated in “a” in FIG. 43, the protective member 220 can also be arranged in such a manner as to cover an inner-circumference-side corner and an outer-circumference-side corner of the annular trench 142, leaving a part of the bottom surface of the annular trench 142 uncovered. Since the etch-back amount is particularly large at the central section of the annular trench 142, the protective member 220 can be left unremoved only at the corners by adjusting the total amount of the etch-back at a time of the etch-back.

In addition, the protective member 220 can also be arranged in such a manner as to cover only the inner-circumference-side corner as illustrated in “b” in FIG. 43. The dielectric constant of resin used as the protective member 220 is typically higher than the dielectric constant of air. Because of this, by leaving the resin unremoved only at the corner(s) as illustrated in “a” and “b” in FIG. 43, the overall volume of the resin is reduced, the dielectric constant can be lowered by a corresponding degree, and this is advantageous for high-speed transfer.

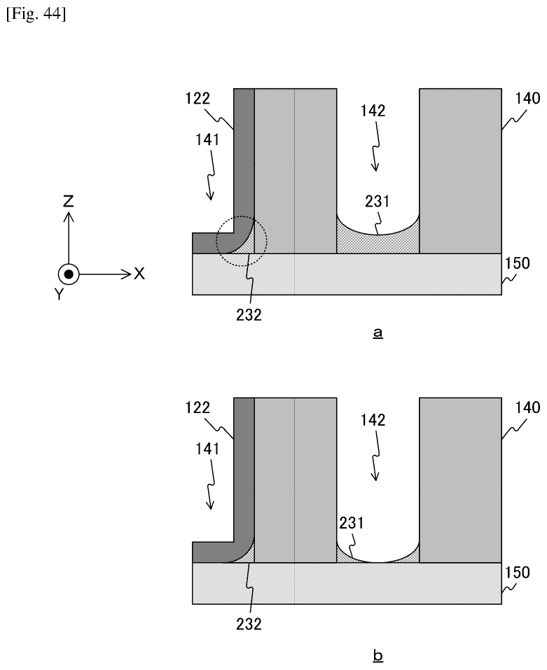

In addition, whereas resin is used as the protective member 220 in FIG. 38, an insulating inorganic film can also be used instead of resin, as illustrated in FIG. 44. Particularly, an advantage in terms of stress reduction equivalent to that obtained by resin can be attained if a tensile film is used. Stress reduction equivalent to resin is difficult to be attained if a compressive film is used, but since an inorganic film is hard, an advantage in terms of deformation suppression can be attained, and this is considered to be effective as a peeling suppressing measure.

For example, an inorganic film is formed by ALD (Atomic layer deposition), and the inorganic film in the through hole 141 and the annular trench 142 is thereafter removed by etch-back. The inorganic film remaining at corners in the through hole 141 is used as a protective member 232, and the inorganic film remaining in the annular trench 142 is used as a protective member 231. Note that the protective member 231 is an example of a first protective member described in the claims, and the protective member 232 is an example of a second protective member described in the claims.

As illustrated in “a” in FIG. 44, the inorganic film (the protective member 232) is kept unremoved also at corners of the through hole 141, but since corners of the through wire 122 including Cu or the like are rounded, this produces an advantage in terms of mitigation of stress immediately below the through hole 141. In addition, since etch-back proceeds from the central section also in the annular trench 142, the remaining protective member 231 has a shape which is recessed toward the lower side (i.e., toward the wiring layer 150). Since the corners are covered even in such a shape, the advantage in terms of peeling suppression is not influenced. In addition, the volume of the protective member 231 decreases by an amount corresponding to the recess, the dielectric constant can be lowered by a corresponding degree, and this is advantageous for high-speed transfer.

Depending on the degree of etch-back, a part of the bottom surface of the annular trench 142 is exposed as illustrated in “b” in FIG. 44, and there is a possibility that the protective member 231 remains only at the corners. Since the corners are rounded even in this case, this produces an advantage in terms of peeling suppression.

Note that each of the first to ninth embodiments can be applied to the tenth embodiment.

In the manner described above, since the protective member 220 is arranged adjacent to the wiring layer 150 in the annular trench 142 according to the tenth embodiment of the present technology, peeling can be suppressed.

### First Modification Example

Whereas peeling is suppressed by arranging the protective member 220 in the annular trench 142 in the tenth embodiment described above, this configuration requires addition of a step of forming the protective member 220. The semiconductor apparatus 100 in this first modification example of the tenth embodiment is different from that in the tenth embodiment in that the protective member 220 is unnecessary.

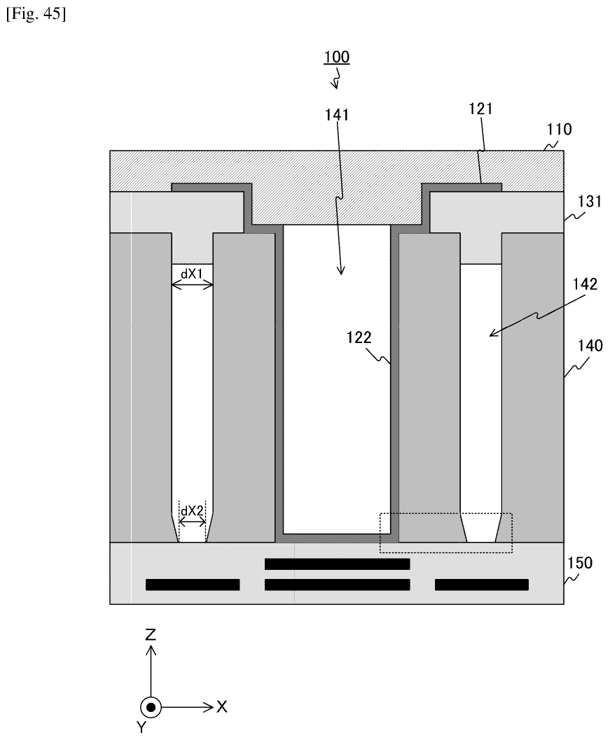

FIG. 45 is a cross-sectional view depicting a configuration example of the semiconductor apparatus 100 in the first modification example of the tenth embodiment of the present technology. In the semiconductor apparatus 100 in this first modification example of the tenth embodiment, the protective member 220 is not formed. Instead, a width d×2 of the annular trench 142 on the side of the wiring layer 150 is adjusted in such a manner as to be narrower than a width d×1 of the annular trench 142 on the side of the rear-surface insulating film 131. For example, the lower portion of the cross-sectional shape of the annular trench 142 has a tapered shape that shrinks toward the wiring layer 150.

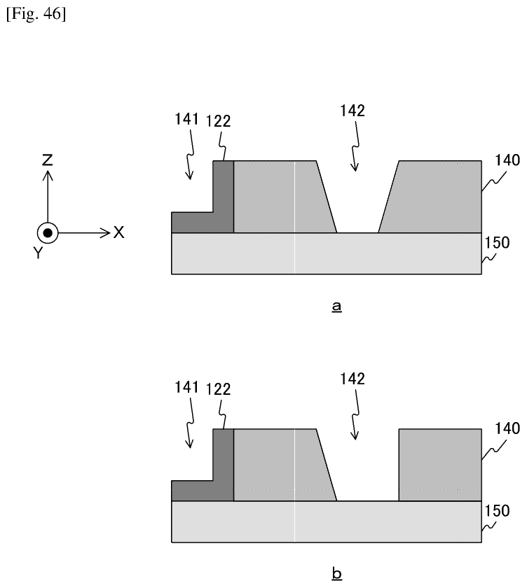

FIG. 46 depicts examples of enlarged views of the semiconductor apparatus in the first modification example of the tenth embodiment of the present technology. “a” in FIG. 46 depicts an enlarged view of a portion enclosed by a dotted line in FIG. 45.

As illustrated in “a” in FIG. 46, the annular trench 142 is tapered on both the inner-circumference side and the outer-circumference side. Note that, in other possible configurations, the annular trench 142 is tapered only on the inner-circumference side as illustrated in “b” in FIG. 46. By forming a tapered shape as illustrated in “a” and “b” in FIG. 46, it is possible to suppress deformation and prevent peeling.

Note that each of the first to ninth embodiments can be applied to the first modification example of the tenth embodiment.

In the manner described above, since the cross-sectional shape of the annular trench 142 has a tapered shape according to the first modification example of the tenth embodiment of the present technology, the protective member 220 is unnecessary.

### Second Modification Example

Whereas peeling is suppressed by arranging the protective member 220 in the annular trench 142 in the tenth embodiment described above, this configuration requires addition of a step of forming the protective member 220. The semiconductor apparatus 100 in this second modification example of the tenth embodiment is different from that in the tenth embodiment in that the protective member 220 is unnecessary.

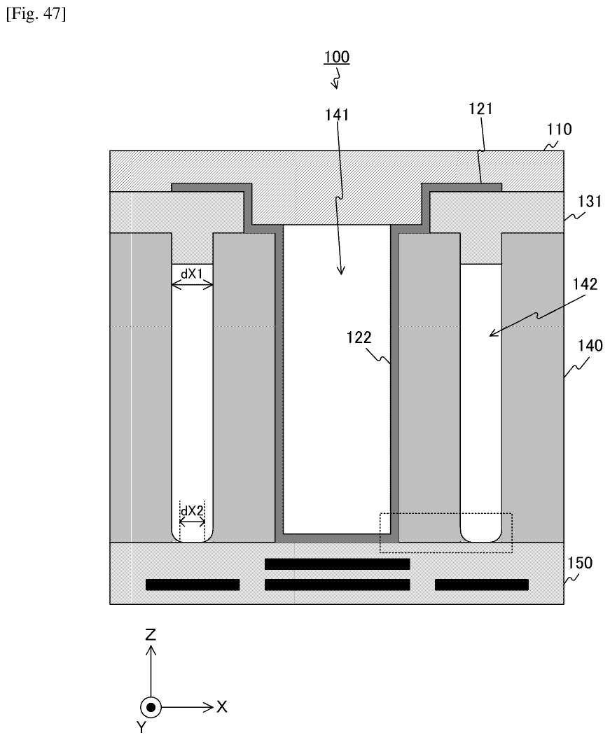

FIG. 47 is a cross-sectional view depicting a configuration example of the semiconductor apparatus 100 in the second modification example of the tenth embodiment of the present technology. In the semiconductor apparatus 100 in this second modification example of the tenth embodiment, the protective member 220 is not formed. Instead, the width d×2 of the annular trench 142 on the side of the wiring layer 150 is adjusted in such a manner as to be narrower than the width d×1 of the annular trench 142 on the side of the rear-surface insulating film 131. For example, corners of the bottom of the annular trench 142 are adjusted in such a manner as to have rounded shapes.

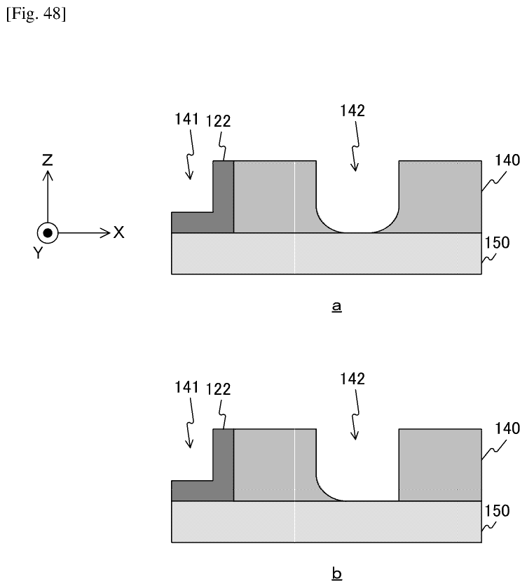

FIG. 48 depicts examples of enlarged views of the semiconductor apparatus in the second modification example of the tenth embodiment of the present technology. “a” in FIG. 48 depicts an enlarged view of a portion enclosed by a dotted line in FIG. 47.

As illustrated in “a” in FIG. 48, in the first modification example of the tenth embodiment, both the inner-circumference-side corner and the outer-circumference-side corner of the annular trench 142 are rounded. Note that, in other possible configurations, only the inner-circumference-side corner is rounded as illustrated in “b” in FIG. 48. By forming what is generally called a rounded corner shape as illustrated in “a”and “b”in FIG. 48, it is possible to suppress deformation and prevent peeling.

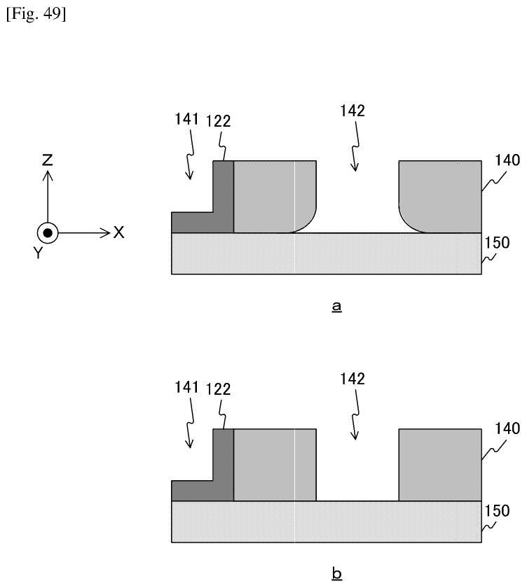

In contrast to this, in a case where notches are formed at the corners as illustrated in “a” in FIG. 49, it becomes likely for the wiring layer 150 to be peeled off undesirably due to stress concentrated at the corners. In addition, even in a case where there are no notches at the corners as illustrated in “b” in FIG. 49, an advantage in terms of peeling suppression is difficult to be attained unless the corners are rounded.

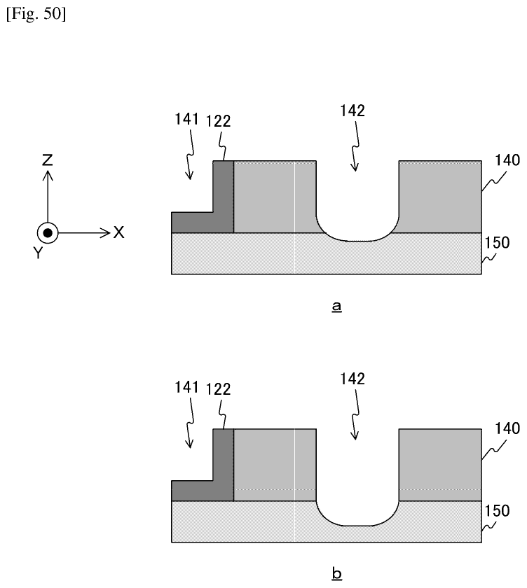

Note that, whereas the corners do not reach the wiring layer 150 in FIG. 47, etching can also be performed such that the corners straddle the boundary between the semiconductor substrate 140 and the wiring layer 150 as illustrated in “a” in FIG. 50. In addition, etching can also be performed such that the corners are positioned in the wiring layer 150 as illustrated in “b” in FIG. 50.

Note that each of the first to ninth embodiments can be applied to the second modification example of the tenth embodiment.

In the manner described above, since the corners of the annular trench 142 are rounded according to the second modification example of the tenth embodiment of the present technology, the protective member 220 is unnecessary.

### 11. Eleventh Embodiment

Whereas the annular trench 142 is formed around the circumference of the through hole 141 in the first embodiment described above, in this case, the base material (silicon, etc.) of the semiconductor substrate 140 remains in a ring shape between the through hole 141 and the annular trench 142. This configuration requires a layout of a pattern for ensuring that there is a sufficient width of the cavity in the annular trench 142 in order to attain a high withstand voltage of the rear-surface redistribution wire 121, ensuring that there is a sufficient ring width of the ring-shaped silicon in order to suppress peeling of the silicon, and so on. Accordingly, this causes a problem that it becomes difficult to attain a high degree of integration of the pattern. The semiconductor apparatus 100 in this eleventh embodiment is different from that in the first embodiment in that an area between the through hole 141 and the annular trench 142 is depleted.

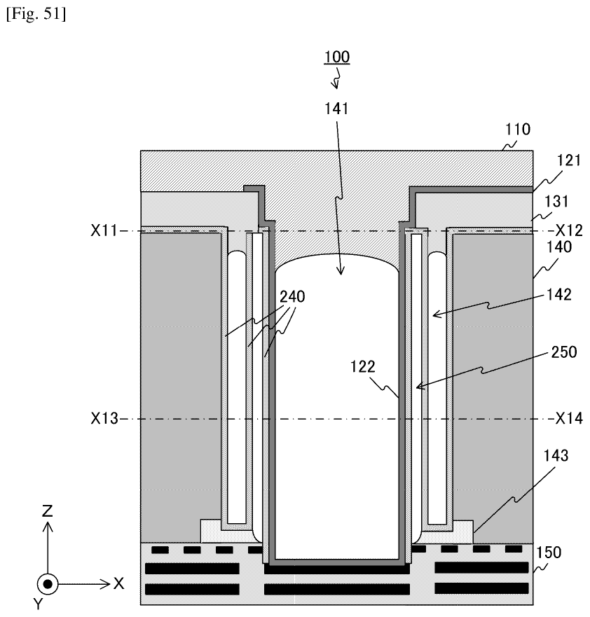

FIG. 51 is a cross-sectional view depicting a configuration example of the semiconductor apparatus 100 in the eleventh embodiment of the present technology. The semiconductor apparatus 100 in this eleventh embodiment is different from that in the first embodiment in that an insulating film 240 is formed around the outer circumference of the annular trench 142 and is formed between the through hole 141 and the annular trench 142. In addition, the semiconductor apparatus 100 in the eleventh embodiment is different from that in the first embodiment in that a depletion layer 250 is formed between the through hole 141 and the annular trench 142 and in the insulating film 240. As the insulating film 240, SiO2 is used, for example.

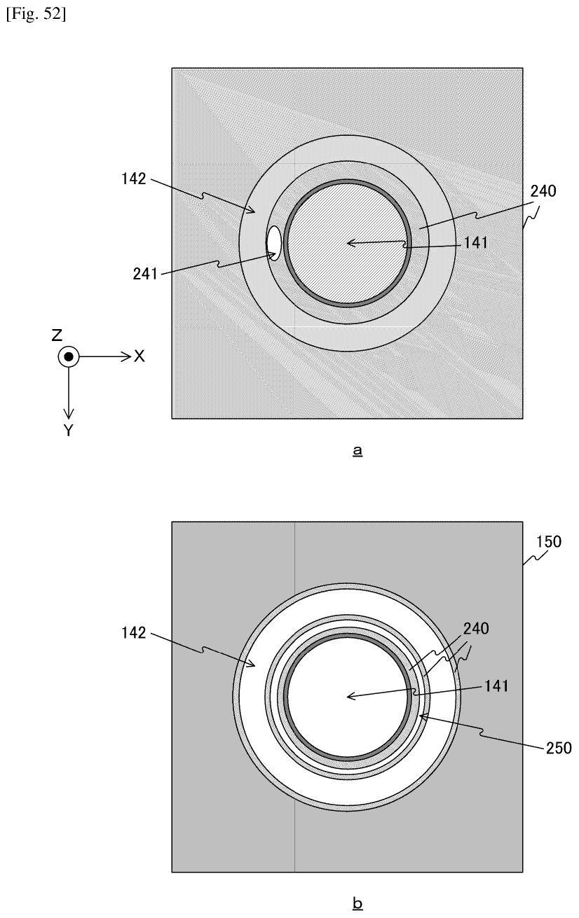

FIG. 52 depicts examples of cross-sectional views of the semiconductor apparatus 100 in the eleventh embodiment of the present technology when seen in another direction. “a” in FIG. 52 depicts a cross-sectional view seen in the Z-axis direction, taken along a line segment X11-X12 in FIG. 51. “b” in FIG. 52 depicts a cross-sectional view seen in the Z-axis direction, taken along a line segment X13-X14 in FIG. 51.

As illustrated in “a” in FIG. 52, an opening is formed in the insulating film 240 at the upper end of the annular trench 142, and a circular or oval hole 241 is formed. Note that the hole 241 is an example of an opening described in the claims.

In addition, as illustrated in “b” in FIG. 52, the insulating film 240 between the annular trench 142 and the through hole 141 is completely depleted, and the depletion layer 250 is formed. Owing to the structure in which the portion which is the ring-shaped silicon in the first embodiment is completely depleted, it is possible to reduce the outer diameter of the annular trench 142 while ensuring that there is a sufficient insulation width between the through wire 122 and the semiconductor substrate 140. In addition, since a metal wire in the wiring layer 150 is not exposed through the bottom of the ring-shaped depletion layer 250, a pattern collapse such as film peeling or corrosion of the metal wire is suppressed. As a result, it is possible to attain a high degree of integration of the high-withstand-voltage, low-capacity through via 149, and enhancement of the device reliability can be expected.

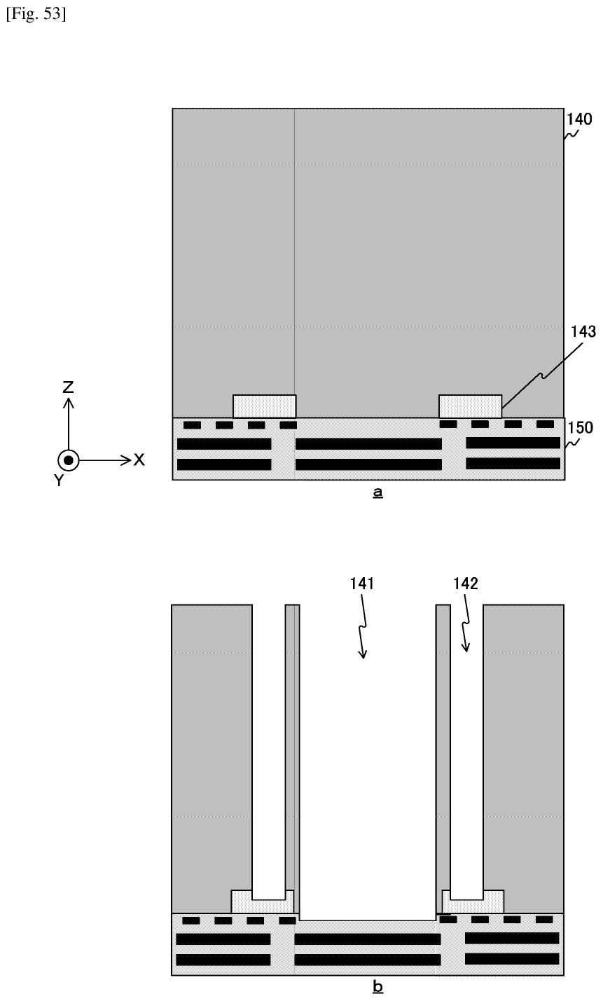

Next, a manufacturing method for the semiconductor apparatus 100 in the eleventh embodiment of the present technology is depicted in FIG. 53 to FIG. 56.

As illustrated in “a” in FIG. 53, the semiconductor substrate 140 on which a circuit is created is bonded onto a support substrate including the wiring layer 150. A grinder apparatus reduces the thickness of the semiconductor substrate 140 by polishing until its thickness becomes approximately 80 micrometers (μm). The support substrate may be a silicon substrate or may be a glass substrate.

Next, as illustrated in “b” in FIG. 53, the through hole 141 and the annular trench 142 are formed. First, a resist pattern of the through hole 141 and the annular trench 142 is created by lithography. For example, the diameter of the through hole 141 is set to 40 micrometers (μm), and the width of ring-shaped silicon between the through hole 141 and the annular trench 142 is set to 2 micrometers (μm). In addition, the width of the annular trench 142 is set to 5 micrometers (μm). At this time, it is better if the element isolation region 143 (STI) is present at the bottom of the annular trench 142, and it is desirable if there is no STI at the bottom of the through hole 141. Then, dry etching of the silicon is performed with the use of the resist as a mask. For example, a perpendicular shape can be obtained by SF6 (silicon hexafluoride) or C4F8 (octafluorocyclobutane) gas.

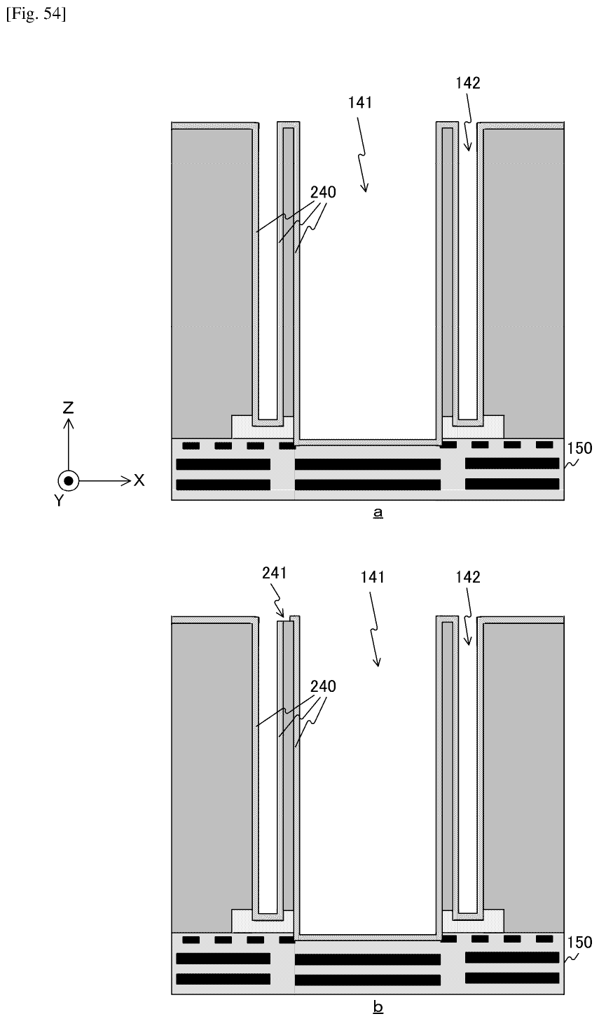

Next, the insulating film 240 is formed by CVD as illustrated in “a” in FIG. 54. For example, by forming a film of TEOS (Tetra Eth Oxy Silane) with a thickness of 1 micrometer (μm) on a flat portion, a film with a thickness of 0.5 to 0.7 micrometers (μm) is formed on side walls and bottoms of the through hole 141 and the annular trench 142. Note that the insulating film 240 may include SiN (silicon nitride) or silicon oxynitride (SiON), other than SiO2. In addition, the film formation can also be performed by ALD.

Next, an opening is formed at a part of the insulating film 240 at the upper end of the annular trench 142 by lithography and dry etching, and one hole 241 is formed as illustrated in “b” in FIG. 54.

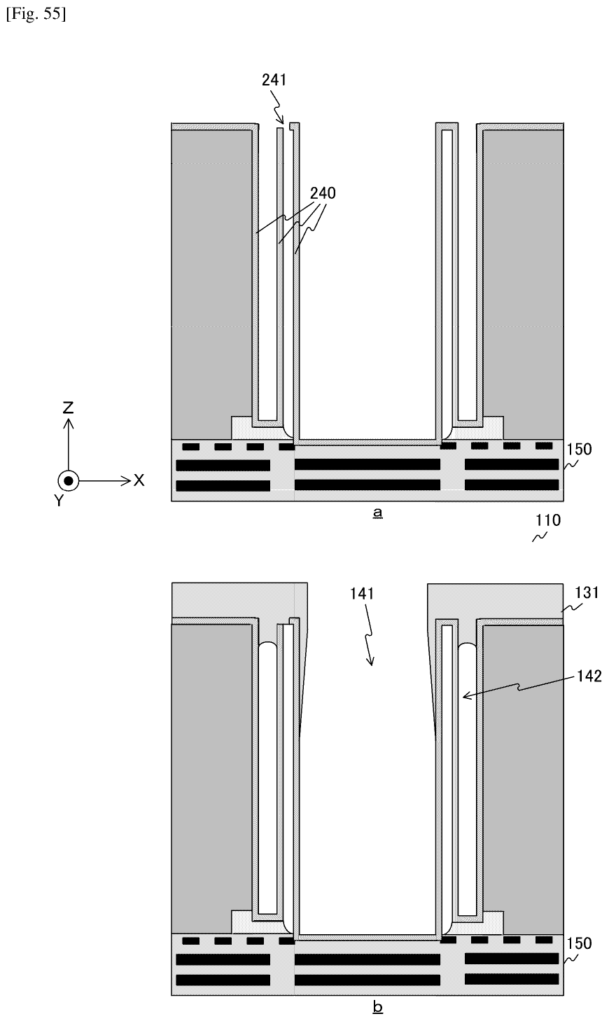

Next, as illustrated in “a” in FIG. 55, by chemical dry etching using SF6 gas, the ring-shaped silicon between the through hole 141 and the annular trench 142 is removed via the hole 241. At this time, the etching selectivity relative to the insulating film 240 is equal to or higher than 500, and the scraped amount of the insulating film 240 when approximately 160 micrometers (μm), which is the half of the circumference of the ring-shaped silicon, is etched is equal to or smaller than 0.3 micrometers (μm). Note that wet etching using, for example, a TMAH (Tetramethyl ammonium hydroxide) solution can also be used for the removal of the silicon. In this case, it is better to form a pattern with a plurality of holes 241, taking into consideration anisotropic etching of silicon orientation.

Next, as illustrated in “b” in FIG. 55, the rear-surface insulating film 131 is formed. For example, a coating of a photosensitive resin material is applied, and patterning is performed on the resin material by lithography according to the through hole 141. At this time, the annular trench 142 is not filled completely with the resin material, but is closed and becomes hollow.

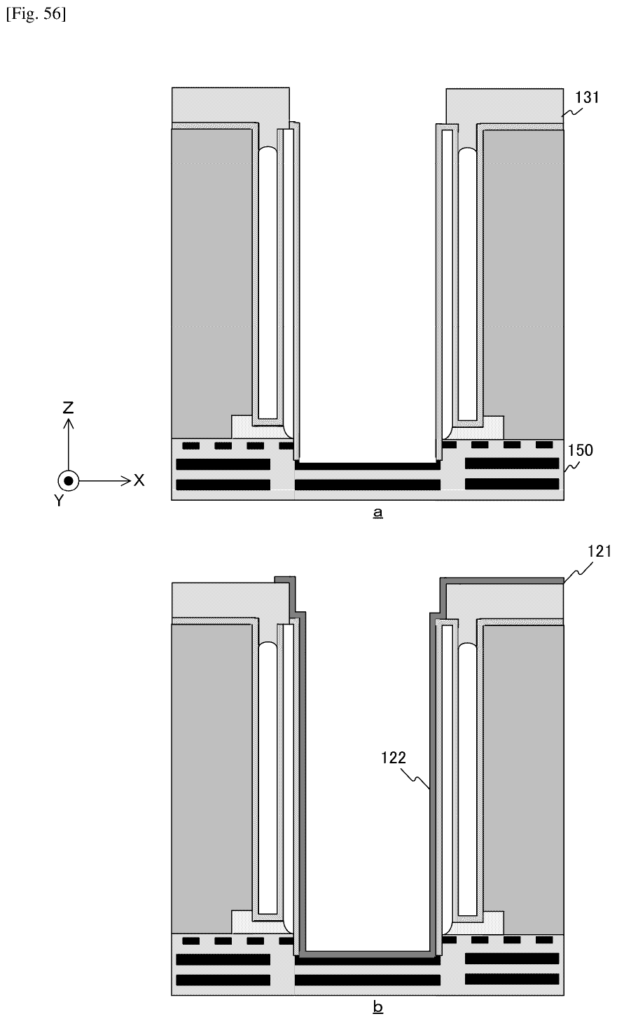

Next, as illustrated in “a” in FIG. 56, the resin material having been subjected to the patterning is used as a mask, the insulating film 240 at the bottom of the through hole 141 and an interlayer film of the wiring layer 150 are removed by dry etching, and a metal wire of the wiring layer 150 is exposed.

Next, as illustrated in “b” in FIG. 56, the rear-surface redistribution wire 121 and the through wire 122 are formed. For example, by a semi-additive method using a resist mask and Cu plating, a Cu wire (the rear-surface redistribution wire 121 and the through wire 122) is formed. Then, the solder mask 110 (not depicted) is formed.

Note that each of the first to tenth embodiments can be applied to the eleventh embodiment.

In the manner described above, since the depletion layer 250 is formed in the insulating film 240 between the through hole 141 and the annular trench 142 according to the eleventh embodiment of the present technology, the device reliability can be enhanced.

### First Modification Example

Whereas the one hole 241 is formed at the upper end of the annular trench 142 in the eleventh embodiment described above, there is a possibility that removal of the ring-shaped silicon is difficult with the one hole 241. The semiconductor apparatus 100 in this first modification example of the eleventh embodiment is different from that in the eleventh embodiment in that two or more holes 241 are provided.

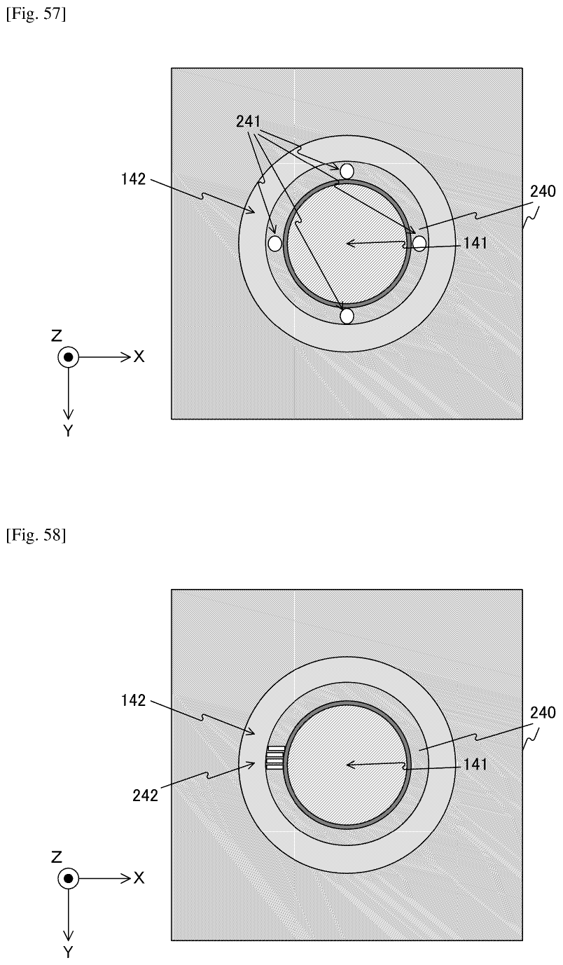

FIG. 57 is an example of a cross-sectional view of the semiconductor apparatus 100 in the first modification example of the eleventh embodiment of the present technology. FIG. 57 depicts a cross-sectional view seen in the Z-axis direction, taken along the line segment X11-X12 in FIG. 51.

As illustrated in FIG. 57, in the first modification example of the eleventh embodiment, two or more holes 241 are formed. As a result, removal of the ring-shaped silicon becomes easier.

Note that each of the first to ninth embodiments can be applied to the first modification example of the eleventh embodiment.

In the manner described above, since the two or more holes 241 are provided according to the first modification example of the eleventh embodiment of the present technology, removal of the ring-shaped silicon becomes easier.

### Second Modification Example

Whereas the circular or oval hole 241 is formed as an opening at the upper end of the annular trench 142 in the eleventh embodiment described above, the shape of the opening is not limited to a circular or oval shape. The semiconductor apparatus 100 in this second modification example of the eleventh embodiment is different from that in the eleventh embodiment in that slits are formed.

FIG. 58 is an example of a cross-sectional view of the semiconductor apparatus 100 in the second modification example of the eleventh embodiment of the present technology. FIG. 58 depicts a cross-sectional view seen in the Z-axis direction, taken along the line segment X11-X12 in FIG. 51.

As illustrated in FIG. 58, in the second modification example of the eleventh embodiment, instead of the hole 241, one or more breaks are formed as slits 242 along a predetermined direction.

Note that each of the first to ninth embodiments can be applied to the second modification example of the eleventh embodiment.

In the manner described above, since the slits 242 are formed at the upper end of the annular trench 142 according to the second modification example of the eleventh embodiment of the present technology, a ring-shaped trench can be removed via the slits 242.

### 12. Twelfth Embodiment

Whereas the rear-surface insulating film 132 (SiO2, etc.) is formed on the inner wall of the through hole 141 in the second embodiment described above, the shape of silicon at the bottom of the through hole 141 becomes notches or a flaring shape at a time of formation of the through holes 141 in this configuration, in some cases. In this case, the rear-surface insulating film 132 becomes thin at the portions with the notches or the flaring shape, and a problem of withstand voltage failure or reliability deterioration occurs undesirably. The semiconductor apparatus 100 in this twelfth embodiment is different from that in the second embodiment in that formation of notches or a flaring shape is suppressed.

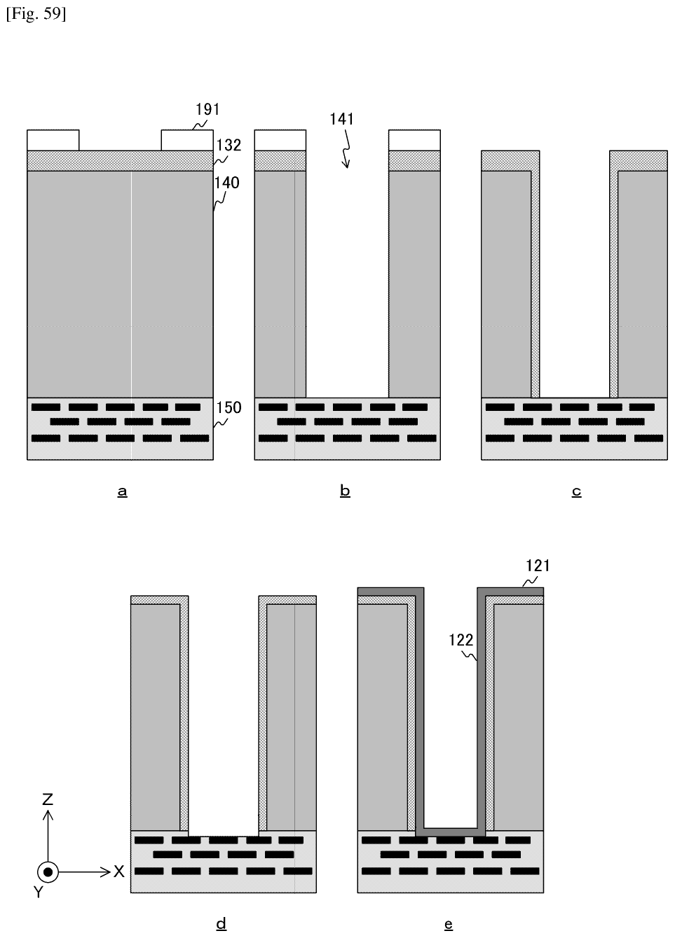

FIG. 59 is a view depicting an example of the second embodiment of the present technology in which an ideal through hole is formed. The annular trench 142 is omitted in FIG. 59. This similarly applies to the subsequent drawings.

As illustrated in “a” in FIG. 59, a photoresist 191 is formed on the upper surface of the rear-surface insulating film 132 except for a portion to be processed. Then, as illustrated in “b” in FIG. 59, the through hole 141 that penetrates the semiconductor substrate 140 is formed. Then, the photoresist 191 is removed, and as illustrated in “c” in FIG. 59, the rear-surface insulating film 132 is formed also on the inner wall of the through hole 141. Next, as illustrated in “d” in FIG. 59, the rear-surface insulating film 132 is etched back. Then, as illustrated in “e” in FIG. 59, a metal wire (the rear-surface redistribution wire 121 and the through wire 122) is formed. In a case where the through hole 141 has an ideal shape as illustrated in FIG. 59, a problem of withstand voltage failure or reliability deterioration does not occur.

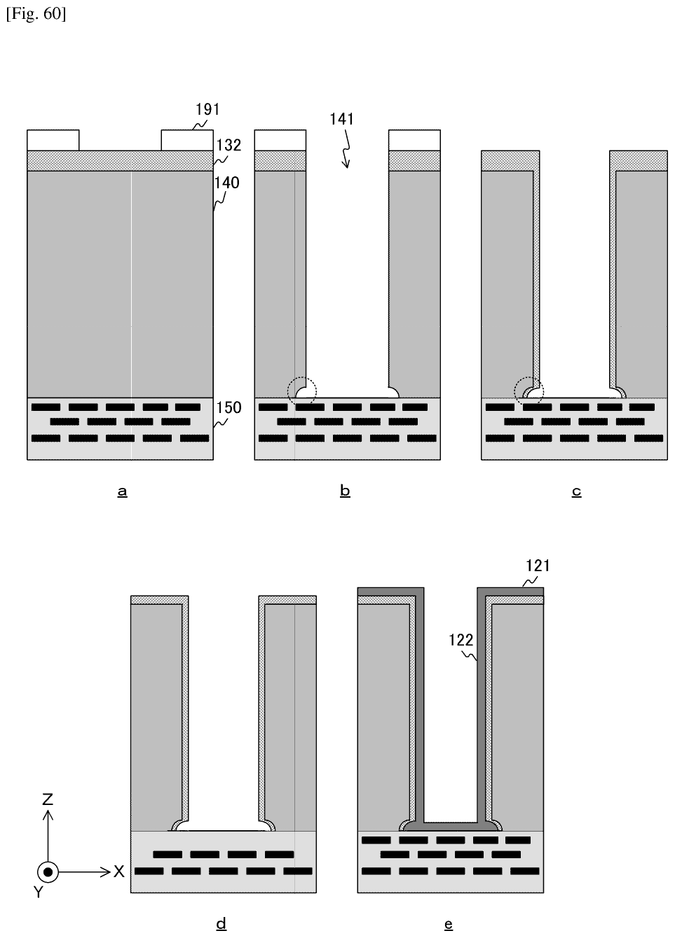

However, as illustrated in FIG. 60, notches occur at the bottom of the through hole 141 in some cases. Silicon processing on the semiconductor substrate 140 is performed until the wiring layer 150 is reached, but when the processing reaches the wiring layer 150, there is no more silicon to be processed. Because of this, as illustrated in a portion enclosed by a dotted line in “b” in FIG. 60, silicon is processed in the lateral direction, and a shape called notch is formed. The rear-surface insulating film 132 formed in “c” in FIG. 60 becomes thin at the portions of the notches. Because of this, a problem of withstand voltage failure or reliability deterioration occurs.

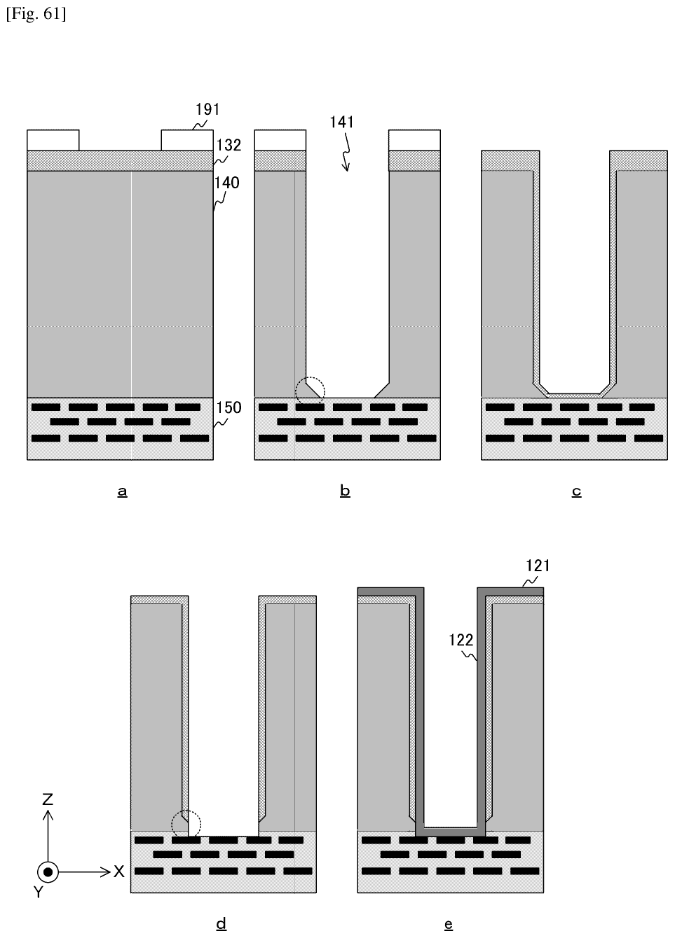

In addition, as illustrated in FIG. 61, the shape of the bottom of the through hole 141 becomes a flaring shape in some cases. In a case where silicon processing is insufficient, the shape of the silicon becomes a flaring shape as illustrated in the portion enclosed by a dotted line in “b” in FIG. 61. In this case, the rear-surface insulating film 132 of a side wall of the silicon becomes thin after etch-back processing in “d” in FIG. 61, and a problem of withstand voltage failure or reliability deterioration occurs.

In particular, in a case where the portions of the through hole 141 and the annular trench 142 are subjected to silicon processing simultaneously, since etching rates of those portions are different, the etching amount of a pattern with a higher etching rate increases, and it becomes more likely for notches to occur.

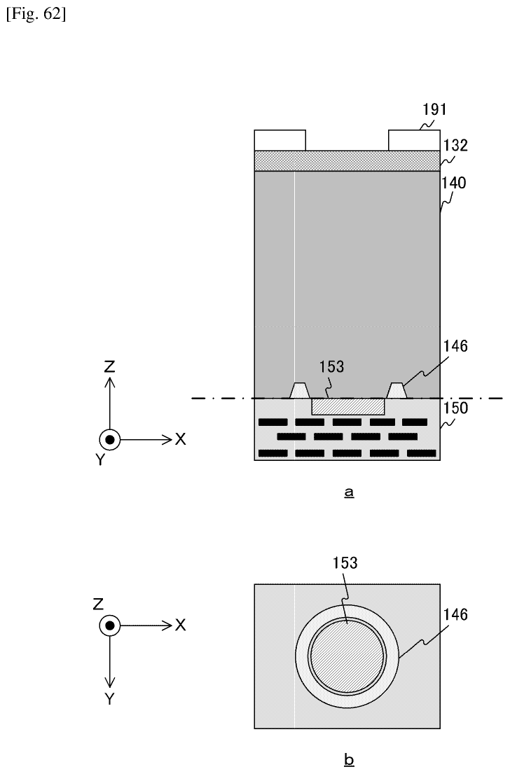

FIG. 62 depicts examples of cross-sectional views of the semiconductor apparatus 100 in the twelfth embodiment of the present technology in which the through hole 141 has not yet been formed. In order to prevent notches or a flaring shape described before, an element isolation region (STI) 146 and a dummy polysilicon 153 are further arranged in the twelfth embodiment. “a” in FIG. 62 is an example of a cross-sectional view of the semiconductor apparatus 100 seen in the Y-axis direction. “b” in FIG. 62 is an example of a cross-sectional view seen in the Z-axis direction, taken along the portion of a dash-dotted line in “a” in FIG. 62. Note that the element isolation region 146 is an example of a first element isolation region described in the claims.

As illustrated in “a” and “b” in FIG. 62, the element isolation region 146 is arranged in a ring shape around the circumference of a region which is in the semiconductor substrate 140 and which is to be the bottom of the through hole 141. In addition, the dummy polysilicon 153 is arranged in a region which is in the wiring layer 150 and which is to be the bottom of the through hole 141 when the silicon processing reaches the wiring layer 150. As illustrated in “b” in FIG. 62, the dummy polysilicon 153 has a circular shape when seen in the Z-axis direction, and its diameter is smaller than the internal diameter of the element isolation region 146.

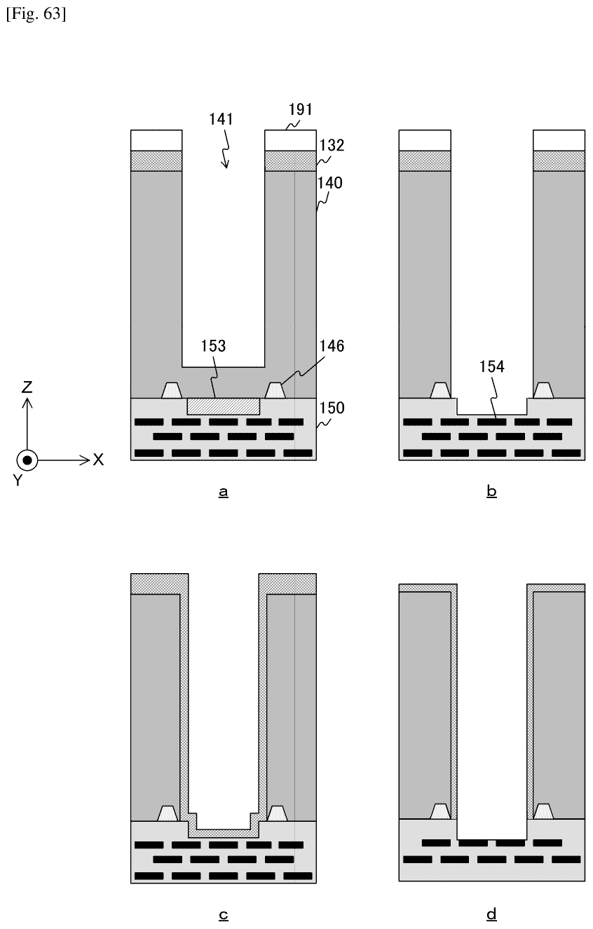

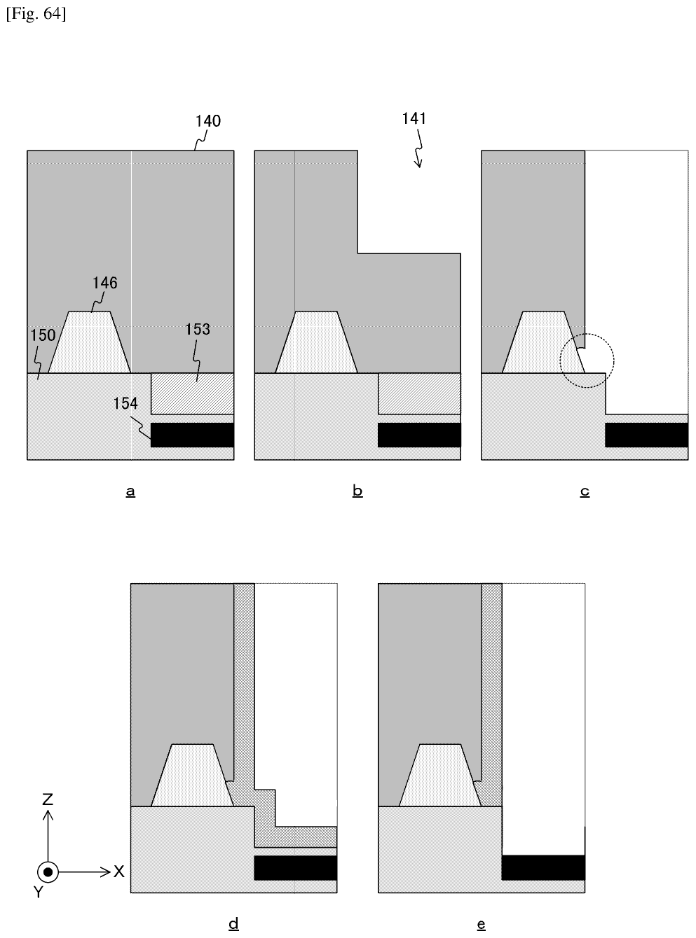

FIG. 63 is a view for explaining a manufacturing method for the semiconductor apparatus 100 until etch-back in the twelfth embodiment of the present technology. As illustrated in “a” in FIG. 63, silicon processing is started for the semiconductor apparatus 100 of being in the state depicted in FIG. 62. “a” in FIG. 63 depicts the state in the middle of the processing.

Then, as illustrated in “b” in FIG. 63, the silicon processing continues until the dummy polysilicon 153 is removed, and an insulating film in the wiring layer 150 remaining at an upper portion of a Cu wire 154 in the wiring layer 150 becomes thin. After the silicon processing, as illustrated in “c” in FIG. 63, the rear-surface insulating film 132 is formed in such a manner as to cover a side wall and the bottom surface of the through hole 141. Next, as illustrated in “d” in FIG. 63, the insulating film is processed by etch-back until the Cu wire 154 is exposed. In “d” in FIG. 63, processing needs to be performed by an amount corresponding to the total of the film thickness of the insulating film at the upper portion of the Cu wire 154 remaining in “b” in FIG. 63 and the film thickness of the rear-surface insulating film 132 formed in “c” in FIG. 63. Note that procedures of and after the placement of the through wire 122 are omitted in FIG. 63.

The arrangement of the element isolation region 146 can suppress formation of notches or a flaring shape, and can enhance the withstand voltage and reliability. In addition, since the insulating film at the upper portion of the Cu wire 154 has become thin owing to the dummy polysilicon 153, the insulating film processing amount for exposing the Cu wire 154 can be reduced. As a result, the processing amount of the rear-surface insulating film 132 on the side wall of the through hole 141 also decreases, and the withstand voltage and reliability can be enhanced.

Note that, whereas both the element isolation region 146 and the dummy polysilicon 153 are arranged, it is also possible to arrange only the element isolation region 146. In addition, whereas the annular trench 142 (not depicted) is formed around the circumference of the through hole 141, in other possible configurations, the annular trench 142 is not formed.

FIG. 64 depicts enlarged views of a portion near the element isolation region 146 in the twelfth embodiment of the present technology. “a” in FIG. 64 is an enlarged view of FIG. 62, and “b,” “c,” “d,” and “e” in FIG. 64 are enlarged views of “a,” “b,” “c,” and “d” in FIG. 63. Although a micro notch occurs in some cases as illustrated in a portion enclosed by a dotted line in “c” in FIG. 64, expansion of the notch is suppressed by the element isolation region 146. In addition, the dummy polysilicon 153 is processed deeper than portions surrounding it, and the arrangement position of the dummy polysilicon 153 becomes a position of contact with metal (through wire 122) by self-alignment.

In the manner described above, since the ring-shaped element isolation region 146 and the dummy polysilicon 153 are arranged according to the twelfth embodiment of the present technology, formation of notches or a flaring shape can be suppressed, and the withstand voltage and reliability can be enhanced.

### First Modification Example

Whereas the dummy polysilicon 153 having a circular shape when seen in the Z-axis direction is arranged in the twelfth embodiment described above, the shape of the dummy polysilicon 153 is not limited to this shape. The semiconductor apparatus 100 in this first modification example of the twelfth embodiment is different from that in the twelfth embodiment in that the shape of the dummy polysilicon 153 is changed.

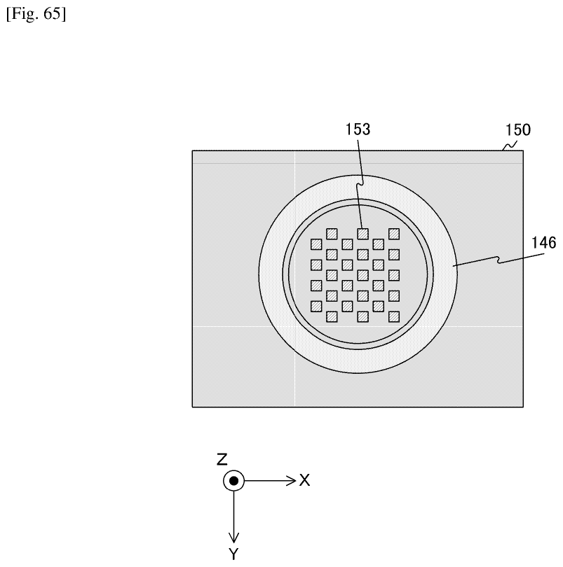

FIG. 65 is an example of a cross-sectional view of the semiconductor apparatus 100 in the first modification example of the twelfth embodiment of the present technology. FIG. 65 is an example of a cross-sectional view seen in the Z-axis direction. The shape of the dummy polysilicon 153 is not limited to a circular shape, and the dummy polysilicon 153 can be formed in various patterns. For example, the dummy polysilicon 153 is formed in such a manner as to have a dot pattern.

In the manner described above, the dummy polysilicon 153 can be formed in various types of patterns other than a circular shape according to the first modification example of the twelfth embodiment of the present technology.

### Second Modification Example

Whereas the dummy polysilicon 153 having a circular shape when seen in the Z-axis direction is arranged in the twelfth embodiment described above, the shape of the dummy polysilicon 153 is not limited to this shape. The semiconductor apparatus 100 in this second modification example of the twelfth embodiment is different from that in the twelfth embodiment in that the shape of the dummy polysilicon 153 is changed.

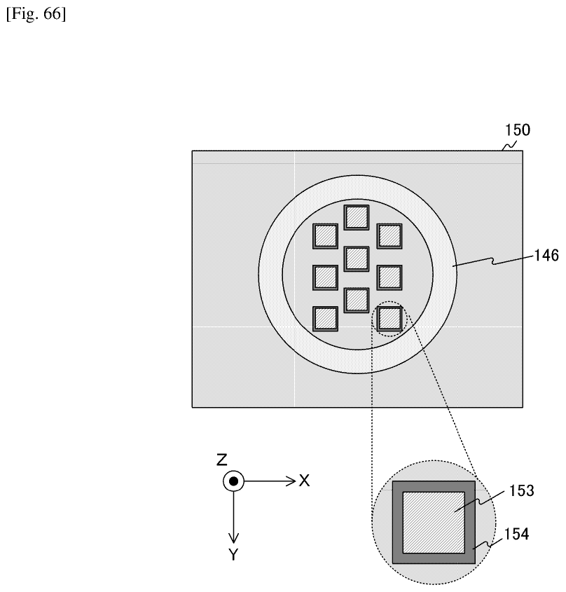

FIG. 66 is an example of a cross-sectional view of the semiconductor apparatus 100 in the second modification example of the twelfth embodiment of the present technology. FIG. 66 is an example of a cross-sectional view seen in the Z-axis direction. The pattern of the dummy polysilicon 153 is, for example, a dot pattern, and each dot-shaped piece of the dummy polysilicon 153 is arranged in a region corresponding to the Cu wire 154. The area size of each piece of the dummy polysilicon 153 is smaller than the corresponding Cu wire 154. As a result, the portion of the Cu wire 154 can be formed as an opening by self-alignment at a time of etch-back.

In the manner described above, since the dot-patterned dummy polysilicon 153 is arranged in regions corresponding to the Cu wire 154 according to the second modification example of the twelfth embodiment of the present technology, the portions of the Cu wire 154 can be formed as openings by self-alignment at a time of etch-back.

### 13. Thirteenth Embodiment

Whereas the annular trench 142 is formed around the circumference of the through hole 141 in the first embodiment described above, in this case, the base material (silicon, etc.) of the semiconductor substrate 140 remains in a ring shape between the through hole 141 and the annular trench 142. This configuration requires a layout of a pattern for ensuring that there is a sufficient width of the cavity in the annular trench 142 in order to attain a high withstand voltage of the rear-surface redistribution wire 121, ensuring that there is a sufficient ring width of the ring-shaped silicon in order to suppress peeling of the silicon, and so on. Accordingly, this causes a problem that it becomes difficult to attain a high degree of integration of the pattern. The semiconductor apparatus 100 in this thirteenth embodiment is different from that in the first embodiment in that a low-k material is arranged between the through hole 141 and the annular trench 142.

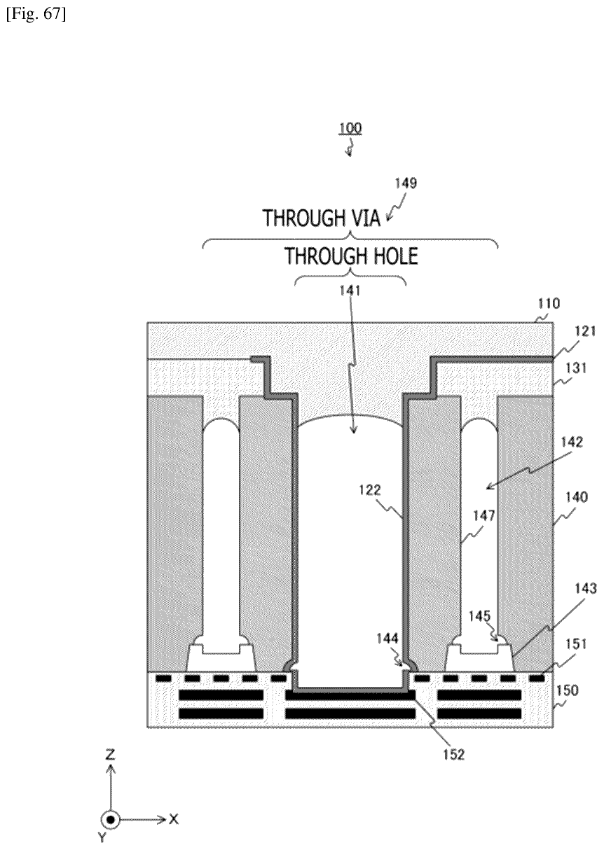

FIG. 67 is a cross-sectional view depicting a configuration example of the semiconductor apparatus 100 in the thirteenth embodiment of the present technology. The semiconductor apparatus 100 in this thirteenth embodiment is different from that in the first embodiment in that a ring-shaped low-k material 147 is arranged between the through hole 141 and the annular trench 142.

The low-k material 149 is a material having a dielectric constant lower than that of the base material (silicon, etc.) of the semiconductor substrate 140. As this low-k material 149, SiO2 (silicon dioxide), SiOC (carbon-containing silicon nitride), or the like is used. By arranging the low-k material 149 between the through hole 141 and the annular trench 142, the dielectric constant can be lowered as compared with the first embodiment in which silicon is arranged, and also a measure against peeling of ring-shaped silicon around the circumference of the through hole 141 becomes unnecessary. As a result, it becomes easier to attain a high degree of integration.

Note that, whereas the rear surface of the semiconductor substrate 140 and the annular trench 142 are covered with the rear-surface insulating film 131 and the rear-surface insulating film 131 is covered with the solder mask 110 in FIG. 67, in other possible configurations as described later, the rear-surface insulating film 131 is not used.

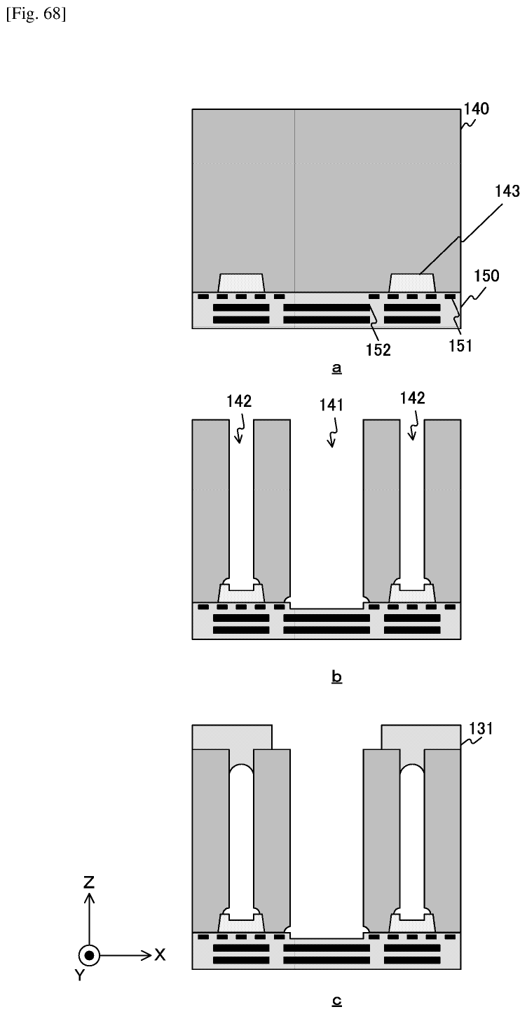

Next, a manufacturing method for the semiconductor apparatus 100 in the thirteenth embodiment of the present technology is depicted in FIG. 68 to FIG. 70.

First, as illustrated in “a” in FIG. 68, on the front-surface side of the semiconductor substrate 140, the pad 152 is formed at a position corresponding to the through wire 122 to be formed later, and the element isolation region 143 is formed at a position corresponding to the annular trench 142. In addition, the dummy gate 151 is formed at the position corresponding to the annular trench 142.

Next, as illustrated in “b” in FIG. 68, the through hole 141 and the annular trench 142 are formed by dry etching. Since conditions related to etching rates and occurrence of notches are likely to have a trade-off relation, it may be necessary to adopt conditions on a case-by-case basis depending on necessities. Note that it is also possible to process the annular trench 142 after processing the through hole 141 and hardening its side surface.

Next, as illustrated in “c” in FIG. 68, a film of a photosensitive insulating resin is formed as the rear-surface insulating film 131 over the entire surface, the photosensitive resin around the through hole 141 and in the through hole 141 is thereafter removed by lithography, and annealing is performed to form permanent resin.

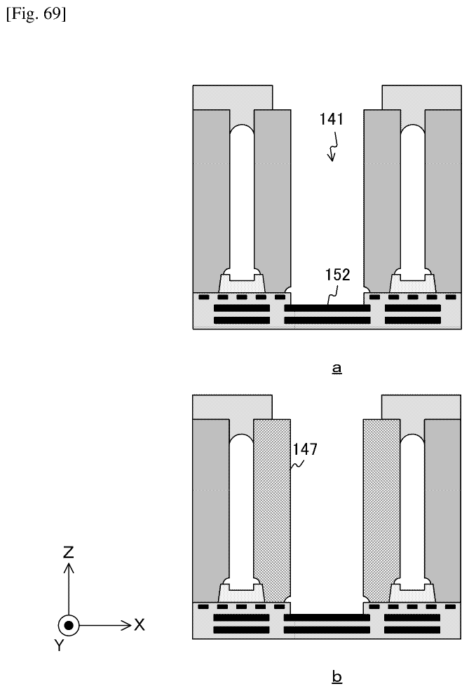

Then, as illustrated in “a” in FIG. 69, the entire surface is etched back, and the through hole 141 is connected to the pad 152 on the front-surface side. Next, as illustrated in “b” in FIG. 69, the low-k material 149 is formed by injection of oxygen ions.

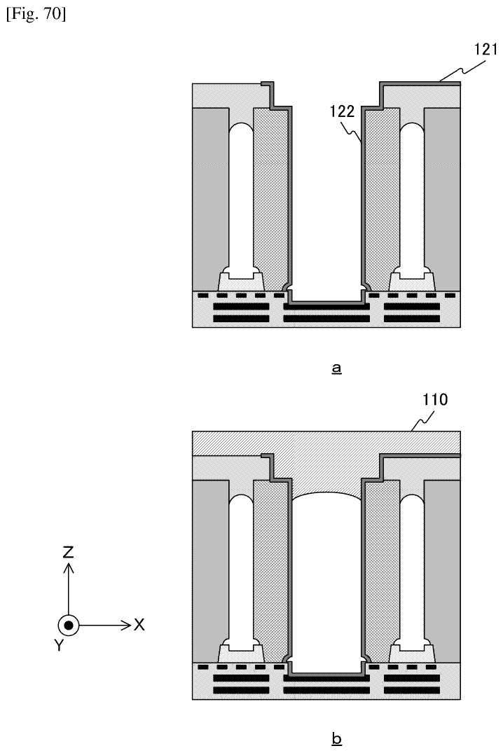

Then, as illustrated in “a” in FIG. 70, the rear-surface redistribution wire 121 and the through wire 122 are formed simultaneously by a semi-additive method. Next, as illustrated in “b”in FIG. 70, the solder mask 110 is formed.

In the manner described above, since the ring-shaped low-k material 149 is arranged between the through hole 141 and the annular trench 142 according to the thirteenth embodiment of the present technology, the dielectric constant is lowered, a measure against peeling of silicon becomes unnecessary, and it becomes easier to attain a high degree of integration.

### Modification Example

Whereas the rear surface of the semiconductor substrate 140 and the annular trench 142 are covered with the rear-surface insulating film 131 in the thirteenth embodiment described above, the rear surface can also be covered with the low-k material 149 instead of the rear-surface insulating film 131. The semiconductor apparatus 100 in this modification example of the thirteenth embodiment is different from that in the thirteenth embodiment in that the rear surface of the semiconductor substrate 140 is covered with the low-k material 149.

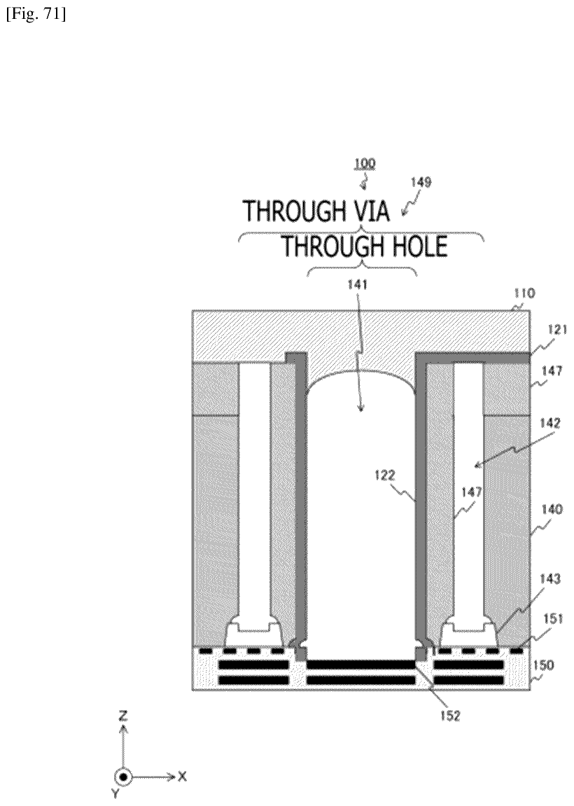

FIG. 71 is a cross-sectional view depicting a configuration example of the semiconductor apparatus 100 in the modification example of the thirteenth embodiment of the present technology. In this modification example of the thirteenth embodiment, the rear-surface insulating film 131 is not provided, but instead, the rear surface of the semiconductor substrate 140 is covered with the low-k material 149. In addition, the low-k material 149 covering the rear surface and the upper end of the annular trench 142 are covered with the solder mask 110.

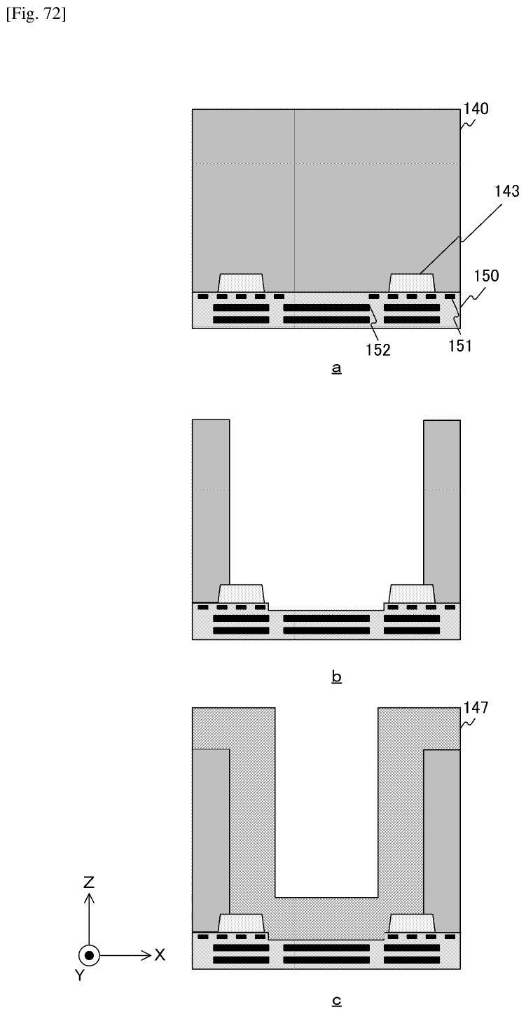

Next, a manufacturing method for the semiconductor apparatus 100 in the modification example of the thirteenth embodiment of the present technology is depicted in FIG. 72 to FIG. 74.

First, as illustrated in “a” in FIG. 72, on the front-surface side of the semiconductor substrate 140, the pad 152 is formed at a position corresponding to the through wire 122 to be formed later, and the element isolation region 143 is formed at a position corresponding to the annular trench 142. In addition, the dummy gate 151 is formed at the position corresponding to the annular trench 142.

Next, as illustrated in “b” in FIG. 72, a through hole with a diameter which is approximately the same as the diameter of the annular trench 142 is formed by dry etching. Then, a film of the low-k material 149 is formed as illustrated in “c” in FIG. 72.

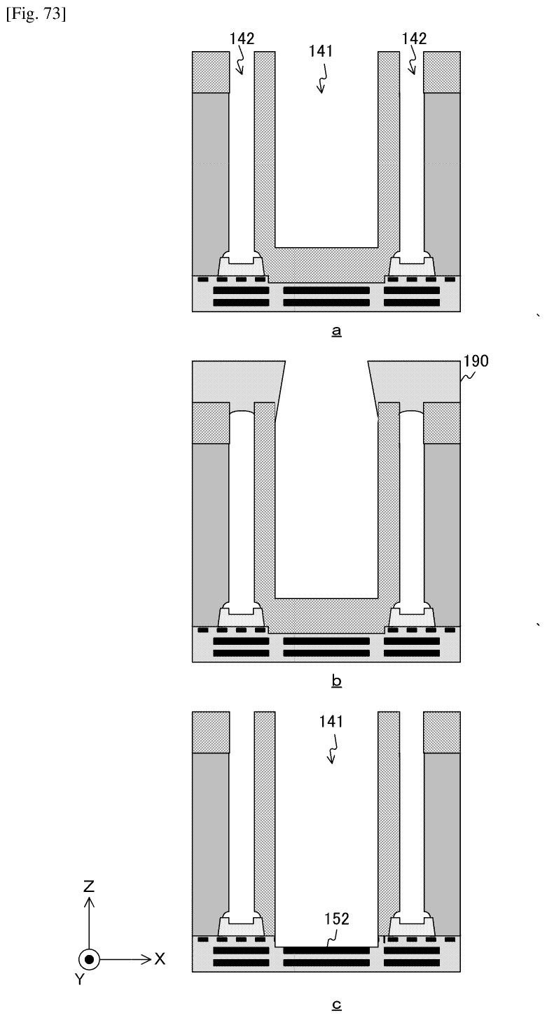

Then, as illustrated in “a” in FIG. 73, the through hole 141 and the annular trench 142 are formed by dry etching of the low-k material 149 in the through hole. Next, as illustrated in “b” in FIG. 73, a coating of the resist mask 190 is applied except for the through hole 141, and, as illustrated in “c” in FIG. 73, the through hole 141 is connected to the pad 152 on the front-surface side by etch-back.

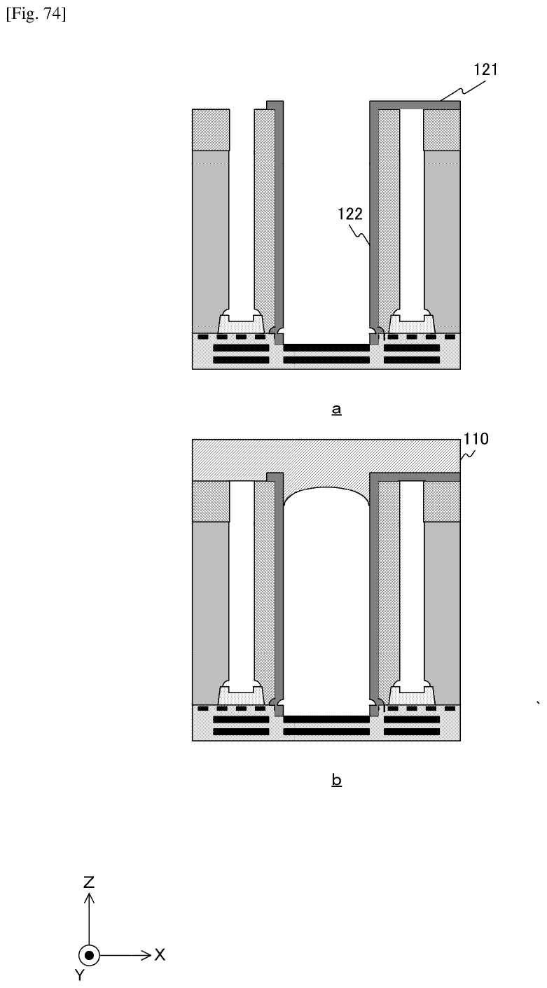

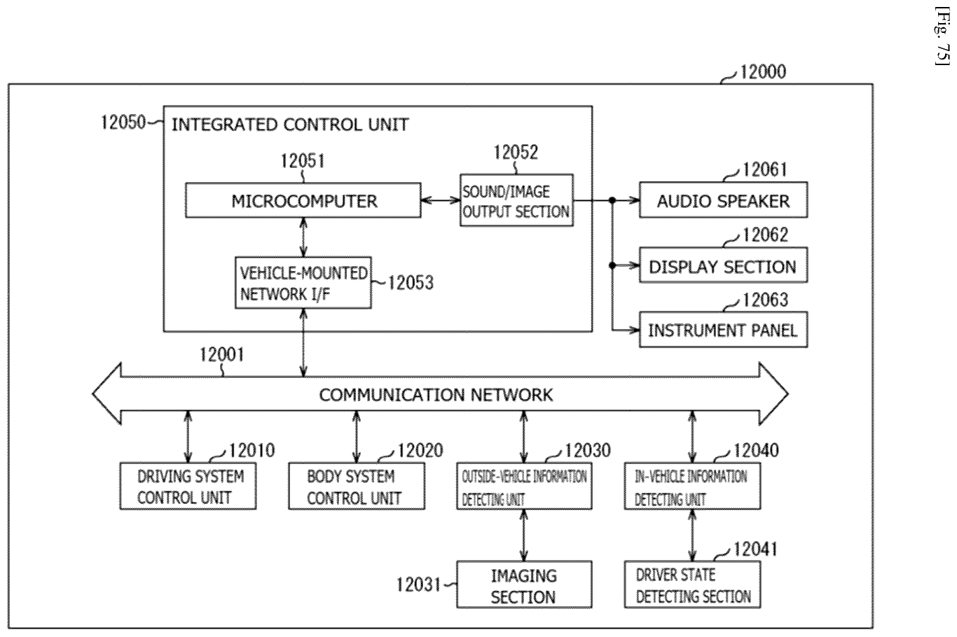

Then, as illustrated in “a” in FIG. 74, the rear-surface redistribution wire 121 and the through wire 122 are formed simultaneously by a semi-additive method. Next, as illustrated in “b” in FIG. 74, the solder mask 110 is formed.

In the manner described above, since the rear surface of the semiconductor substrate 140 is covered with the low-k material 149 according to the modification example of the thirteenth embodiment of the present technology, a step of forming the rear-surface insulating film 131 becomes unnecessary.

### 14. Example of Application to Mobile Body

The technology (present technology) according to the present disclosure can be applied to various products. For example, the technology according to the present disclosure may be realized as an apparatus mounted on a mobile body of any type such as a car, an electric car, a hybrid electric car, a motorcycle, a bicycle, a personal mobility, an airplane, a drone, a ship, or a robot.

FIG. 75 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 75, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 75, an audio speaker 12061, a display section 12062, and an instrument panel 12063 are illustrated as the output device. The display section 12062 may, for example, include at least one of an on-board display and a head-up display.

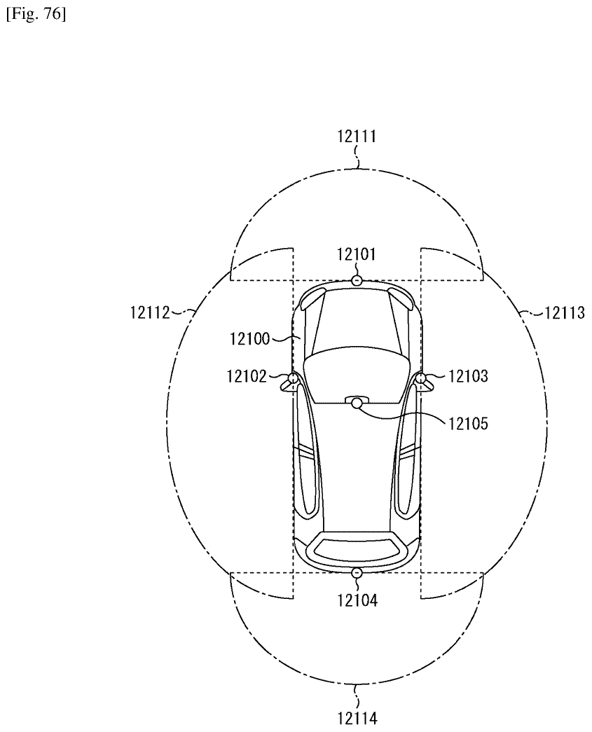

FIG. 76 is a diagram depicting an example of the installation position of the imaging section 12031.

In FIG. 76, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper, or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 76 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been explained thus far. The technology according to the present disclosure can be applied to, for example, the imaging section 12031 in the configuration explained above. Specifically, the semiconductor apparatus 100 in FIG. 1 can be applied to the imaging section 12031. By applying the technology according to the present disclosure to the imaging section 12031, it becomes possible to increase the yield of the semiconductor apparatus 100 and enhance the reliability of the vehicle control system.

Note that the embodiments described above are depicted as examples for embodying the present technology, and matters in the embodiments and matters specifying the present disclosure in the claims respectively have corresponding relations. Similarly, matters specifying the present disclosure in the claims and matters in the embodiments of the present technology that are given names which are identical to those of the matters specifying the present disclosure have corresponding relations. It should be noted that the present technology is not limited to the embodiments, and can be embodied by making various modifications to the embodiments within the scope not departing from the gist thereof.

Note that advantages described in the present specification are illustrated merely as examples and are not the sole examples, and there may also be other advantages.

Note that the present technology can also adopt the following configurations.
(1)

A semiconductor apparatus including:
a semiconductor substrate having a front surface on which a wiring layer is formed;
a through hole that penetrates the semiconductor substrate;
a through wire formed along a side surface of the through hole; and
an annular trench that surrounds a circumference of the through hole when seen in a direction perpendicular to a rear surface of the semiconductor substrate which is on a side opposite to the front surface and that has formed therein a cavity when seen in a direction parallel to the rear surface.
(2)

The semiconductor apparatus according to (1) described above, further including:
a rear-surface insulating film that covers the rear surface of the semiconductor substrate which is on the side opposite to the front surface, in which
the rear-surface insulating film includes first and second rear-surface insulating films that are stacked one on another, and
the second rear-surface insulating film covers the rear surface and a side wall of at least one of the through hole and the annular trench.
(3)

The semiconductor apparatus according to (2) described above, further including:
a first element isolation region formed around a circumference of a bottom of the through hole.
(4)

The semiconductor apparatus according to (2) described above, in which the second rear-surface insulating film includes a fixed electric charge film.
(5)

The semiconductor apparatus according to any one of (1) to (4) described above, in which
the through hole includes first and second through holes,
the annular trench is formed around a circumference of the first through hole, and
the annular trench is not formed around a circumference of the second through hole.
(6)

The semiconductor apparatus according to (1) described above, in which
the through hole includes first and second through holes that are arrayed adjacent to each other in the direction parallel to the rear surface,
the annular trench includes a first annular trench formed around a circumference of the first through hole and a second annular trench formed around a circumference of the second through hole, and
the first annular trench shares a part thereof with the second annular trench.
(7)

The semiconductor apparatus according to (6) described above, in which a width of the portion shared by the first and second annular trenches is substantially the same as a width of unshared portions.
(8)

The semiconductor apparatus according to any one of (1) to (7) described above, further including:
a rear-surface insulating film that covers the rear surface of the semiconductor substrate which is on the side opposite to the front surface; and
a rear-surface redistribution wire formed along the circumference of the through hole on the rear surface and the rear-surface insulating film.
(9)

The semiconductor apparatus according to (8) described above, in which an outer circumference of the rear-surface redistribution wire formed around the circumference of the through hole is larger than an outer circumference of the annular trench.
(10)

The semiconductor apparatus according to (8) described above, in which a width of a portion of the rear-surface redistribution wire that traverses the annular trench is wider than a width of other portions of the rear-surface redistribution wire.
(11)

The semiconductor apparatus according to (8) described above, in which
an opening whose outer circumference is larger than the through hole is formed on the rear-surface insulating film, and
the rear-surface redistribution wire around the circumference of the through hole covers the rear surface positioned on an inner side of the opening.
(12)

The semiconductor apparatus according to any one of (1) to (11) described above, further including:
an on-chip lens;
a photoelectric converting section; and
an external terminal.
(13)

The semiconductor apparatus according to any one of (1) to (12) described above, further including:
a rear-surface insulating film that covers the rear surface of the semiconductor substrate which is on the side opposite to the front surface, in which
an end of the rear-surface insulating film has a tapered shape.
(14)

The semiconductor apparatus according to any one of (1) to (13) described above, in which a diameter of the through hole is 1.5 to 4.0 times a width of the annular trench.
(15)

The semiconductor apparatus according to (14) described above, in which the diameter of the through hole is 2.0 to 3.0 times the width of the annular trench.
(16)

The semiconductor apparatus according to any one of (1) to (15) described above, further including:
a solder mask that covers the insulating film and the through hole, in which
a cavity closed by the solder mask is formed inside the through hole when seen in the direction parallel to the rear surface.
(17)

The semiconductor apparatus according to (16) described above, further including:
a low-k material that is formed between the through hole and the annular trench and has a dielectric constant lower than a dielectric constant of the semiconductor substrate.
(18)

The semiconductor apparatus according to (17) described above, further including:
a rear-surface insulating film that covers the annular trench and the rear surface of the semiconductor substrate which is on the side opposite to the front surface, in which
the solder mask further covers the rear-surface insulating film.
(19)

The semiconductor apparatus according to (17) described above, in which
the low-k material covers the rear surface of the semiconductor substrate which is on the side opposite to the front surface, and
the solder mask further covers the low-k material and the annular trench.
(20)

The semiconductor apparatus according to any one of (1) to (19) described above, further including:
a second element isolation region formed between the wiring layer and the annular trench.
(21)

The semiconductor apparatus according to any one of (1) to (20) described above, in which the wiring layer includes a dummy gate formed between the through hole and the annular trench.
(22)

The semiconductor apparatus according to any one of (1) to (21) described above, further including:
a rear-surface insulating film that covers the rear surface of the semiconductor substrate which is on the side opposite to the front surface; and
a reinforcement film that is adjacent to the wiring layer and covers the circumference of the through hole.
(23)

The semiconductor apparatus according to (22) described above, in which
the through hole has a step at a predetermined depth position when seen in the direction parallel to the rear surface,
the rear-surface insulating film covers the circumference of the through hole in an area from the rear surface to the depth position,
the reinforcement film covers the circumference of the through hole in an area from the depth position to the wiring layer, and
the reinforcement film is formed between a base material of the semiconductor substrate and the through hole when seen in the perpendicular direction.
(24)

The semiconductor apparatus according to (22) described above, in which a cross-sectional shape of each of the through hole and the reinforcement film seen in the parallel direction has a curved tapered shape.
(25)

The semiconductor apparatus according to (22) described above, in which
the through hole has a step at a predetermined depth position when seen in the direction parallel to the rear surface,
the reinforcement film covers the circumference of the through hole in an area from the depth position to the wiring layer, and
the rear-surface insulating film covers the circumference of the through hole and a circumference of the reinforcement film.
(26)

The semiconductor apparatus according to any one of (22) to (25) described above, in which a shape of the through hole is a circular or polygonal shape when seen in the perpendicular direction.
(27)

The semiconductor apparatus according to any one of (22) to (26) described above, in which the reinforcement film covers an entire circumference of the through hole when seen in the perpendicular direction.
(28)

The semiconductor apparatus according to any one of (22) to (26) described above, in which the reinforcement film covers a part of the circumference of the through hole when seen in the perpendicular direction.
(29)

The semiconductor apparatus according to (22) described above, in which
a base material of the semiconductor substrate has a step at a predetermined depth position when seen in the direction parallel to the rear surface,
the rear-surface insulating film covers the circumference of the through hole in an area from the rear surface to the depth position, and
the reinforcement film covers the circumference of the through hole in an area from the depth position to the wiring layer.
(30)

The semiconductor apparatus according to any one of (1) to (29) described above, further including:
a first protective member arranged adjacent to the wiring layer in the annular trench.
(31)

The semiconductor apparatus according to (30) described above, in which the first protective member is an insulating resin or an inorganic film.
(32)

The semiconductor apparatus according to (30) or (31) described above, in which a shape of the first protective member is recessed toward the wiring layer when seen in the direction parallel to the rear surface.
(33)

The semiconductor apparatus according to any one of (30) to (32) described above, in which the first protective member covers both an inner-circumference-side corner and an outer-circumference-side corner of the annular trench.
(34)

The semiconductor apparatus according to any one of (30) to (32) described above, in which the first protective member covers only an inner-circumference-side corner of the annular trench.
(35)

The semiconductor apparatus according to any one of (30) to (34) described above, further including:
a second protective member arranged adjacent to the wiring layer in the through hole.
(36)

The semiconductor apparatus according to (1) described above, further including:
a rear-surface insulating film that covers the rear surface of the semiconductor substrate which is on the side opposite to the front surface, in which
a width of the annular trench on a side of the wiring layer is narrower than a width of the annular trench on a side of the rear-surface insulating film.
(37)

The semiconductor apparatus according to (36) described above, in which a cross-sectional shape of the annular trench when seen in the direction parallel to the rear surface has a tapered shape.
(38)

The semiconductor apparatus according to (36) described above, in which a corner of the annular trench when seen in the direction parallel to the rear surface is rounded.
(39)

The semiconductor apparatus according to (38) described above, in which the corner is positioned in the wiring layer.
(40)

The semiconductor apparatus according to (38) described above, in which the corner straddles a boundary between the semiconductor substrate and the wiring layer.
(41)

The semiconductor apparatus according to any one of (38) to (40) described above, in which, of an inner-circumference-side corner and an outer-circumference-side corner of the annular trench, only the inner-circumference-side corner is rounded.
(42)

The semiconductor apparatus according to any one of (1) to (41) described above, further including:
an insulating film formed between the annular trench and the through hole; and
an annular depletion layer formed in the insulating film.
(43)

The semiconductor apparatus according to (42) described above, in which the insulating film has a predetermined number of openings formed at an end of the depletion layer.
(44)

The semiconductor apparatus according to (43) described above, holes as the openings are formed at the end.
(45)

The semiconductor apparatus according to (43) described above, in which slits as the openings are formed at the end.
(46)

A method of manufacturing a semiconductor apparatus, including:
an etching procedure of forming, by etching, a through hole that penetrates a semiconductor substrate having a front surface on which a wiring layer is formed and an annular trench that surrounds a circumference of the through hole when seen in a direction perpendicular to a rear surface which is on a side opposite to the front surface; and
a wiring procedure of forming a through wire along a side surface of the through hole.
(47)

The method of manufacturing a semiconductor apparatus according to (46) described above, in which the semiconductor substrate includes a second element isolation region arranged around a circumference of a region that is to be a bottom of the through hole.
(48)

The method of manufacturing a semiconductor apparatus according to (47) described above, in which
the wiring layer includes a dummy polysilicon arranged in the region that is to be the bottom of the through hole, and
the dummy polysilicon is removed in the etching procedure.
(49)

The method of manufacturing a semiconductor apparatus according to (48) described above, in which a pattern of the dummy polysilicon includes a dot pattern.
(50)
The method of manufacturing a semiconductor apparatus according to (49) described above, in which
the wiring layer includes a predetermined number of wires, and
the dummy polysilicon is arranged in a dot pattern at positions each corresponding to one of the wires.
(51)

A semiconductor apparatus comprising:
a semiconductor substrate having a front surface and a rear surface, wherein a wiring layer is disposed on a side of the front surface;
a through hole in the semiconductor substrate;
a through wire along a side surface of the through hole; and
an annular trench that at least partially surrounds the through hole, wherein the annular trench includes a cavity.
(52)

The semiconductor apparatus according to any of one (1) and (51), wherein an opening of a rear-surface insulation film is wider than an opening of the through hole forming a first step.
(53)

The semiconductor apparatus according to any of one (51) to (52), further comprising:
a rear-surface insulating film disposed on a side of the rear surface of the semiconductor substrate,
wherein the rear-surface insulating film includes a first rear-surface insulating film and a second rear-surface insulating film that are stacked, and
wherein the second rear-surface insulating film is disposed on the rear surface and a side wall of at least one of the through hole and the annular trench.
(54)

The semiconductor apparatus according to (53), further comprising:
a first element isolation region that surrounds a bottom of the through hole.
(55)

The semiconductor apparatus according to any of one (51) to (54), wherein the second rear-surface insulating film includes a fixed electric charge film.
(56)

The semiconductor apparatus according to any of one (51) to (55), wherein the through hole includes a first through hole and a second through hole,
wherein the annular trench surrounds the first through hole, and
wherein the annular trench does not surround the second through hole.
(57)

The semiconductor apparatus according to any of one (51) to (56),
wherein the through hole includes a first through hole and a second through hole,
wherein the annular trench includes a first annular trench that surrounds the first through hole and a second annular trench that surrounds the second through hole, and
wherein the first annular trench shares a portion with the second annular trench.
(58)

The semiconductor apparatus according to (57), wherein a width of the portion shared by the first annular trench and the second annular trench is substantially a same width as a width of unshared portions.
(59)

The semiconductor apparatus according to any of one (51) to (58), further comprising:
a rear-surface insulating film disposed on a side of the rear surface of the semiconductor substrate; and
a rear-surface redistribution wire surrounding the through hole on the rear surface.
(60)

The semiconductor apparatus according to (59),
wherein an outer circumference of the rear-surface redistribution wire is larger than an outer circumference of the annular trench.
(61)

The semiconductor apparatus according to (59),
wherein a width of a portion of the rear-surface redistribution wire that traverses the annular trench is wider than a width of at least one other portion of the rear-surface redistribution wire.
(62)

The semiconductor apparatus according to (59),
wherein the rear-surface insulating film includes an opening having an outer circumference larger than a circumference of the through hole, and
wherein the rear-surface redistribution wire is positioned on an inner side of the opening of the through hole.
(63)

The semiconductor apparatus according to any of one (51) to (62), further comprising:
an on-chip lens;
a photoelectric convertor; and
an external terminal.
(64)

The semiconductor apparatus according to any of one (51) to (63), further comprising:
a rear-surface insulating film disposed on a side of the rear surface of the semiconductor substrate, wherein an end of the rear-surface insulating film has a tapered shape.
(65)

The semiconductor apparatus according to any of one (51) to (64), wherein a diameter of the through hole is 1.5 to 4.0 times a width of the annular trench.
(66)

The semiconductor apparatus according to claim (65), wherein the diameter of the through hole is 2.0 to 3.0 times the width of the annular trench.
(67)

The semiconductor apparatus according to any of one (51) to (66), further comprising:
a solder mask disposed on a top of the through hole, wherein the through hole includes
a cavity under the solder mask.
(68)

The semiconductor apparatus according to (67), further comprising:
a low-k material between the through hole and the annular trench,
wherein the low-k material has a dielectric constant lower than a dielectric constant of the semiconductor substrate.
(69)

The semiconductor apparatus according to (68), further comprising:
a rear-surface insulating film disposed on the annular trench and the rear surface of the semiconductor substrate,
wherein the solder mask is disposed on the rear-surface insulating film.
(70)

The semiconductor apparatus according to (68),
wherein the low-k material is disposed on a side of the rear surface of the semiconductor substrate, and
wherein the solder mask is disposed on the low-k material and the annular trench.
(71)

The semiconductor apparatus according to (54), further comprising:
a second element isolation region between the wiring layer and the annular trench.
(72)

The semiconductor apparatus according to any of one (51) to (71),
wherein the wiring layer includes a dummy gate between the through hole and the annular trench.
(73)

The semiconductor apparatus according to any of one (51) to (72), further comprising:
a rear-surface insulating film disposed on a side of the rear surface of the semiconductor substrate; and
a reinforcement film adjacent to the wiring layer and surrounding a portion of the through hole.
(74)

The semiconductor apparatus according to (73),
wherein the through hole has a step between a predetermined position in a depth direction and a bottom of the through hole,
wherein the rear-surface insulating film surrounds the through hole in an area from the rear surface to the predetermined position,
wherein the reinforcement film surrounds the through hole in an area from the predetermined position to the wiring layer, and
wherein the reinforcement film is between a base material of the semiconductor substrate and the through hole.
(75)

The semiconductor apparatus according to (73),
wherein a cross-sectional shape of the through hole and the reinforcement film has a curved tapered shape.
(76)

The semiconductor apparatus according to (73),
wherein the through hole has a step at a predetermined position in a depth direction,
wherein the reinforcement film surrounds the through hole in an area from the predetermined position to the wiring layer, and
wherein the rear-surface insulating film covers a circumference of the through hole and a circumference of the reinforcement film.
(77)
The semiconductor apparatus according to (73)
wherein the through hole has a circular shape or a polygonal shape.
(78)

The semiconductor apparatus according to (73),
wherein the reinforcement film covers a circumference of the through hole.
(79)

The semiconductor apparatus according to (73),
wherein the reinforcement film surrounds a portion of the through hole.
(80)

The semiconductor apparatus according to (73),
wherein a base material of the semiconductor substrate has a step at a predetermined position in a depth direction in a direction parallel to the rear surface,
wherein the rear-surface insulating film surrounds the through hole in an area from the rear surface to the predetermined position, and
wherein the reinforcement film surrounds the through hole in an area from the predetermined position to the wiring layer.
(81)

The semiconductor apparatus according to any of one (51) to (80), further comprising:
a first protector adjacent to the wiring layer in the annular trench.
(82)

The semiconductor apparatus according to (81),
wherein the first protector is an insulating resin or an inorganic film.
(83)

The semiconductor apparatus according to (81),
wherein a shape of the first protector is recessed toward the wiring layer.
(84)

The semiconductor apparatus according to (81),
wherein the first protector is disposed both on an inner-circumference-side corner and on an outer-circumference-side corner of the annular trench.
(85)

The semiconductor apparatus according to (81),
wherein the first protector is disposed only on an inner-circumference-side corner of the annular trench.
(86)

The semiconductor apparatus according to (81), further comprising:
a second protector adjacent to the wiring layer in the through hole.
(87)

The semiconductor apparatus according to any of one (51) to (86), further comprising:
a rear-surface insulating film disposed on the rear surface of the semiconductor substrate,
wherein a width of the annular trench on a side of the wiring layer is narrower than a width of the annular trench on a side of the rear-surface insulating film.
(88)

The semiconductor apparatus according to (87),
wherein the annular trench has a tapered shape in a cross-sectional view.
(89)

The semiconductor apparatus according to (87),
wherein a corner of the annular trench is rounded in a cross-sectional view.
(90)

The semiconductor apparatus according to (89),
wherein the annular trench penetrates the wiring layer.
(91)

The semiconductor apparatus according to (89),
wherein the corner of the annular trench straddles a boundary between the semiconductor substrate and the wiring layer.
(92)

The semiconductor apparatus according to (89),
wherein, of an inner-circumference-side corner and an outer-circumference-side corner of the annular trench, only the inner-circumference-side corner is rounded.
(93)

The semiconductor apparatus according to any of one (51) to (92), further comprising:
an insulating film between the annular trench and the through hole; and
an annular depletion layer in the insulating film.
(94)

The semiconductor apparatus according to (93),
wherein the insulating film includes a predetermined number of openings at an end of the annular depletion layer.
(95)

The semiconductor apparatus according to (94),
wherein the openings comprise holes.
(96)

The semiconductor apparatus according to (94),
wherein the openings comprise slits.
(97)

A method of manufacturing a semiconductor apparatus, comprising:
forming, by etching, a through hole that penetrates a semiconductor substrate having a front surface on which a wiring layer is formed and an annular trench that surrounds the through hole; and
forming a through wire along a side surface of the through hole.
(98)

The method of manufacturing the semiconductor apparatus according to (97),
wherein the semiconductor substrate includes an element isolation region around a bottom of the through hole.
(99)

The method of manufacturing the semiconductor apparatus according to (98),
wherein the wiring layer includes a dummy polysilicon arranged in the bottom of the through hole, and
wherein the dummy polysilicon is removed in an etching procedure.
(100)

The method of manufacturing the semiconductor apparatus according to (99),
wherein a pattern of the dummy polysilicon includes a dot pattern.
(101)

The method of manufacturing the semiconductor apparatus according to (100),
wherein the wiring layer includes a predetermined number of wires, and
wherein the dummy polysilicon is arranged in the dot pattern at positions each corresponding to one of the predetermined number of wires.

### Reference Signs List

100: Semiconductor apparatus
110: Solder mask
121: Rear-surface redistribution wire
122: Through wire
131, 132: Rear-surface insulating film
140: Semiconductor substrate
141, 141-1, 141-2, 141-3: Through hole
142, 142-1, 142-2, 142-3: Annular trench
143, 146: Element isolation region
144, 145: Notch
147: low-k material
149, 149-1, 149-2, 149-3: Through via
150: Wiring layer
151: Dummy gate
152: Pad
153: Dummy polysilicon
154: Cu wire
160: External connection terminal
170: Photoelectric conversion layer
180: On-chip lens
190: Resist mask
191: Photoresist
210: Reinforcement film
220, 231, 232: Protective member
240: Insulating film
241: Hole
242: Slit
250: Depletion layer

What is claimed is:

1. A semiconductor apparatus, comprising:
a semiconductor substrate having a front surface and a rear surface, wherein a wiring layer is disposed on a side of the front surface;
a through hole in the semiconductor substrate;
a through wire along a side surface of the through hole; and
an annular trench that at least partially surrounds the through hole, wherein the annular trench includes a cavity.

2. The semiconductor apparatus according to claim 1,
wherein an opening of a rear-surface insulation film is wider than an opening of the through hole forming a first step.

3. The semiconductor apparatus according to claim 1, further comprising:
a rear-surface insulating film disposed on a side of the rear surface of the semiconductor substrate,
wherein the rear-surface insulating film includes a first rear-surface insulating film and a second rear-surface insulating film that are stacked, and
wherein the second rear-surface insulating film is disposed on the rear surface and a side wall of at least one of the through hole and the annular trench.

4. The semiconductor apparatus according to claim 3, further comprising:
a first element isolation region that surrounds a bottom of the through hole.

5. The semiconductor apparatus according to claim 3, wherein the second rear-surface insulating film includes a fixed electric charge film.

6. The semiconductor apparatus according to claim 1,
wherein the through hole includes a first through hole and a second through hole,
wherein the annular trench surrounds the first through hole, and
wherein the annular trench does not surround the second through hole.

7. The semiconductor apparatus according to claim 1,
wherein the through hole includes a first through hole and a second through hole,
wherein the annular trench includes a first annular trench that surrounds the first through hole and a second annular trench that surrounds the second through hole, and
wherein the first annular trench shares a portion with the second annular trench.

8. The semiconductor apparatus according to claim 7,
wherein a width of the portion shared by the first annular trench and the second annular trench is substantially a same width as a width of unshared portions.

9. The semiconductor apparatus according to claim 1, further comprising:
a rear-surface insulating film disposed on a side of the rear surface of the semiconductor substrate; and
a rear-surface redistribution wire surrounding the through hole on the rear surface.

10. The semiconductor apparatus according to claim 9,
wherein an outer circumference of the rear-surface redistribution wire is larger than an outer circumference of the annular trench.

11. The semiconductor apparatus according to claim 9,
wherein a width of a portion of the rear-surface redistribution wire that traverses the annular trench is wider than a width of at least one other portion of the rear-surface redistribution wire.

12. The semiconductor apparatus according to claim 9,
wherein the rear-surface insulating film includes an opening having an outer circumference larger than a circumference of the through hole, and
wherein the rear-surface redistribution wire is positioned on an inner side of the opening of the through hole.

13. The semiconductor apparatus according to claim 1, further comprising:
an on-chip lens;
a photoelectric convertor; and
an external terminal.

14. The semiconductor apparatus according to claim 1, further comprising:
a rear-surface insulating film disposed on a side of the rear surface of the semiconductor substrate,
wherein an end of the rear-surface insulating film has a tapered shape.

15. The semiconductor apparatus according to claim 1,
wherein a diameter of the through hole is 1.5 to 4.0 times a width of the annular trench.

16. The semiconductor apparatus according to claim 15,
wherein the diameter of the through hole is 2.0 to 3.0 times the width of the annular trench.

17. The semiconductor apparatus according to claim 1, further comprising:
a solder mask disposed on a top of the through hole, wherein the through hole includes a cavity under the solder mask.

18. The semiconductor apparatus according to claim 17, further comprising:
a low-k material between the through hole and the annular trench,
wherein the low-k material has a dielectric constant lower than a dielectric constant of the semiconductor substrate.

19. The semiconductor apparatus according to claim 18, further comprising:
a rear-surface insulating film disposed on the annular trench and the rear surface of the semiconductor substrate,
wherein the solder mask is disposed on the rear-surface insulating film.

20. The semiconductor apparatus according to claim 18,
wherein the low-k material is disposed on a side of the rear surface of the semiconductor substrate, and
wherein the solder mask is disposed on the low-k material and the annular trench.

21. The semiconductor apparatus according to claim 4, further comprising:
a second element isolation region between the wiring layer and the annular trench.

22. The semiconductor apparatus according to claim 1,
wherein the wiring layer includes a dummy gate between the through hole and the annular trench.

23. The semiconductor apparatus according to claim 1, further comprising:
a rear-surface insulating film disposed on a side of the rear surface of the semiconductor substrate; and
a reinforcement film adjacent to the wiring layer and surrounding a portion of the through hole.

24. The semiconductor apparatus according to claim 23,
wherein the through hole has a step between a predetermined position in a depth direction and a bottom of the through hole,
wherein the rear-surface insulating film surrounds the through hole in an area from the rear surface to the predetermined position,
wherein the reinforcement film surrounds the through hole in an area from the predetermined position to the wiring layer, and
wherein the reinforcement film is between a base material of the semiconductor substrate and the through hole.

25. The semiconductor apparatus according to claim 23,
wherein a cross-sectional shape of the through hole and the reinforcement film has a curved tapered shape.

26. The semiconductor apparatus according to claim 23,
wherein the through hole has a step at a predetermined position in a depth direction,
wherein the reinforcement film surrounds the through hole in an area from the predetermined position to the wiring layer, and
wherein the rear-surface insulating film covers a circumference of the through hole and a circumference of the reinforcement film.

27. The semiconductor apparatus according to claim 23,
wherein the through hole has a circular shape or a polygonal shape.

28. The semiconductor apparatus according to claim 23,
wherein the reinforcement film covers a circumference of the through hole.

29. The semiconductor apparatus according to claim 23,
wherein the reinforcement film surrounds a portion of the through hole.

30. The semiconductor apparatus according to claim 23,
wherein a base material of the semiconductor substrate has a step at a predetermined position in a depth direction in a direction parallel to the rear surface,
wherein the rear-surface insulating film surrounds the through hole in an area from the rear surface to the predetermined position, and
wherein the reinforcement film surrounds the through hole in an area from the predetermined position to the wiring layer.

31. The semiconductor apparatus according to claim 1, further comprising:
a first protector adjacent to the wiring layer in the annular trench.

32. The semiconductor apparatus according to claim 31,
wherein the first protector is an insulating resin or an inorganic film.

33. The semiconductor apparatus according to claim 31,
wherein a shape of the first protector is recessed toward the wiring layer.

34. The semiconductor apparatus according to claim 31,
wherein the first protector is disposed both on an inner-circumference-side corner and on an outer-circumference-side corner of the annular trench.

35. The semiconductor apparatus according to claim 31,
wherein the first protector is disposed only on an inner-circumference-side corner of the annular trench.

36. The semiconductor apparatus according to claim 31, further comprising:
a second protector adjacent to the wiring layer in the through hole.

37. The semiconductor apparatus according to claim 1, further comprising:
a rear-surface insulating film disposed on the rear surface of the semiconductor substrate,
wherein a width of the annular trench on a side of the wiring layer is narrower than a width of the annular trench on a side of the rear-surface insulating film.

38. The semiconductor apparatus according to claim 37,
wherein the annular trench has a tapered shape in a cross-sectional view.

39. The semiconductor apparatus according to claim 37,
wherein a corner of the annular trench is rounded in a cross-sectional view.

40. The semiconductor apparatus according to claim 39,
wherein the annular trench penetrates the wiring layer.

41. The semiconductor apparatus according to claim 39,
wherein the corner of the annular trench straddles a boundary between the semiconductor substrate and the wiring layer.

42. The semiconductor apparatus according to claim 39,
wherein, of an inner-circumference-side corner and an outer-circumference-side corner of the annular trench, only the inner-circumference-side corner is rounded.

43. The semiconductor apparatus according to claim 1, further comprising:
an insulating film between the annular trench and the through hole; and
an annular depletion layer in the insulating film.

44. The semiconductor apparatus according to claim 43,
wherein the insulating film includes a predetermined number of openings at an end of the annular depletion layer.

45. The semiconductor apparatus according to claim 44,
wherein the openings comprise holes.

46. The semiconductor apparatus according to claim 44,
wherein the openings comprise slits.

47. A method of manufacturing a semiconductor apparatus, comprising:
forming, by etching, a through hole that penetrates a semiconductor substrate having a front surface on which a wiring layer is formed and an annular trench that surrounds the through hole; and
forming a through wire along a side surface of the through hole.

48. The method of manufacturing the semiconductor apparatus according to claim 47,
wherein the semiconductor substrate includes an element isolation region around a bottom of the through hole.

49. The method of manufacturing the semiconductor apparatus according to claim 48,
wherein the wiring layer includes a dummy polysilicon arranged in the bottom of the through hole, and
wherein the dummy polysilicon is removed in an etching procedure.

50. The method of manufacturing the semiconductor apparatus according to claim 49,
wherein a pattern of the dummy polysilicon includes a dot pattern.

51. The method of manufacturing the semiconductor apparatus according to claim 50,
wherein the wiring layer includes a predetermined number of wires, and
wherein the dummy polysilicon is arranged in the dot pattern at positions each corresponding to one of the predetermined number of wires.
